(19) United States
(12) Patent Application Publication
(10) Pub. No.: US 2024/0188404 A1
(43) Pub. Date: Jun. 6, 2024

(54) Display Apparatus

(71) Applicant: Semiconductor Energy Laboratory Co., Ltd., Kanagawa-ken (JP)

(72) Inventors: Shunpei Yamazaki, Setagaya, Tokyo (JP); Kenichi OKAZAKI, Atsugi, Kanagawa (JP); Koji KUSUNOKI, Isehara, Kanagawa (JP); Hideaki KUWABARA, Atsugi, Kanagawa (JP); Yoshiaki OIKAWA, Atsugi, Kanagawa (JP)

(73) Assignee: Semiconductor Energy Laboratory Co., Ltd., Kanagawa-ken (JP)

(21) Appl. No.: 18/285,529

(22) PCT Filed: Mar. 29, 2022
(86) PCT No.: PCT/IB2022/052863

§ 371 Date: Oct. 4, 2023

(30) Foreign Application Priority Data
Apr. 8, 2021 (JP) 2021-066108
Apr. 22, 2021 (JP) 2021-072764

(51) Int. Cl. H10K 59/95; H10K 102/00

(52) U.S. Cl. CPC H10K 59/95; H10K 2102/311

(57) ABSTRACT

A display apparatus with a novel structure is provided. The display apparatus includes a display surface, a flexible non-rectangular substrate over which part of the display surface is formed, and a light-emitting device formed over the flexible substrate. The light-emitting device includes pixel regions formed in a matrix. The display surface has a convex or concave region when part of the flexible non-rectangular substrate is bent. A novel light-emitting apparatus, a novel display apparatus, a novel input/output apparatus, or a novel semiconductor apparatus can be achieved. The display apparatus enables the degree of design flexibility of a display apparatus to be increased and design of the display apparatus to be improved.

### TECHNICAL FIELD

One embodiment of the present invention relates to a display apparatus, an electronic device, or a semiconductor apparatus.

Note that one embodiment of the present invention is not limited to the above technical field. The technical field of one embodiment of the invention disclosed in this specification relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor apparatus, a display apparatus, a light-emitting apparatus, a power storage device, a memory device, a driving method thereof, and a manufacturing method thereof.

Note that semiconductor apparatuses in this specification mean all devices that can function by utilizing semiconductor characteristics, and an electro-optical device, a semiconductor circuit, and an electronic device are all semiconductor apparatuses.

### BACKGROUND ART

Development is advanced to replace part of an instrument display in an automobile with a liquid crystal display apparatus. Development is also advanced to use an organic light-emitting display apparatus in part of an instrument display. Approaches to assisting vehicle drivers are taken by using an in-vehicle display so that the vehicle drivers utilize more information (information on the vehicle's surroundings, traffic information, or geographic information).

In the future, there is a possibility that a large number of cameras or sensors will be installed inside and outside a car and thus a large number of displays will be needed.

Patent Document 1 discloses a structure in which a display portion is provided around a driver's seat of a car and a structure in which a display panel having a curved surface is provided in a car.

Patent Document 2 discloses a structure in which a display panel having a curved portion is provided using a plurality of light-emitting panels.

Patent Document 3 discloses a dual-emission display apparatus that is installed in a vehicle.

### [Reference]

### [Patent Document]

[Patent Document 1] Japanese Published Patent Application No. 2003-229548

[Patent Document 2] Japanese Published Patent Application No. 2015-207556

[Patent Document 3] Japanese Published Patent Application No. 2005-67367

### SUMMARY OF THE INVENTION

### Problems to be Solved by the Invention

An object of one embodiment of the present invention is to provide a novel light-emitting apparatus that is highly convenient or reliable. Another object is to provide a novel display apparatus that is highly convenient or reliable. Another object is to provide a novel input/output apparatus that is highly convenient or reliable. Another object is to provide a novel light-emitting apparatus, a novel display apparatus, a novel input/output apparatus, or a novel semiconductor apparatus.

Light-emitting devices (also referred to as EL devices or EL elements) utilizing electroluminescence (hereinafter referred to as EL) that are used in organic light-emitting display apparatuses have features such as ease of reduction in thickness and weight, high-speed response to input signals, and driving with a constant DC voltage power source, and are used in display apparatuses.

In order to form a full-color display panel, an EL device has a structure in which light-emitting layers in light-emitting devices of different colors (here, blue (B), green (G), and red (R)) are separately formed or the light-emitting layers are separately patterned with use of an evaporation apparatus and a fine metal mask. In the case of such a structure, there is a problem that it is difficult to separately form light-emitting layers in light-emitting devices with use of a metal mask because of an increase in substrate size. In the case of the structure in which light-emitting layers in light-emitting devices are separately formed with use of a metal mask, there is a problem that it is difficult to manufacture a panel with high resolution (e.g., 500 ppi or more).

Alternatively, an EL device has a structure in which full-color display is performed by combining white-light-emitting devices and color filters. In the case of such a structure, there is a problem that power consumption is high because light from the light-emitting device is emitted through the color filter.

In view of the above, an object of one embodiment of the present invention is to provide a full-color display apparatus by a more excellent method without using a fine metal mask. Another object of one embodiment of the present invention is to provide a display apparatus with a novel structure in which white-light-emitting devices and color filters are combined.

Note that the description of these objects does not preclude the existence of other objects. Note that one embodiment of the present invention does not have to achieve all these objects. Note that other objects will be apparent from the description of the specification, the drawings, or the claims, and other objects can be derived from the description of the specification, the drawings, or the claims.

### Means for Solving the Problems

One embodiment of the present invention includes at least a framework and a flexible display panel fixed or held to the framework and forms a display surface with a spherical shape or a hemispherical shape by bending.

A structure disclosed in this specification is a display apparatus that includes a display surface, a flexible non-rectangular substrate over which part of the display surface is formed, and a light-emitting apparatus formed over the flexible substrate. The light-emitting apparatus includes pixel regions formed in a matrix. The display surface has a convex or concave region when part of the flexible non-rectangular substrate is bent.

Alternatively, a driver circuit may be provided. The structure is a display apparatus that includes a display surface, a flexible non-rectangular substrate over which part of the display surface is formed, and a light-emitting apparatus formed over the flexible substrate. The light-emitting apparatus includes pixel regions formed in a matrix and a driver circuit electrically connected to the pixel regions. The display surface has a convex or concave region when part of the flexible non-rectangular substrate is bent.

Note that the non-rectangular shape refers to shapes other than rectangles including substantially quadrangles, examples of which include polygons other than quadrangles, circles, ovals, and shapes with partly curved outer peripheries. Such complex shapes can be handled, leading to a high degree of design flexibility and improved design of the display apparatus.

Although the light-emitting apparatuses are formed over one flexible substrate in each of the above structures, one embodiment of the present invention is not particularly limited, and a plurality of flexible substrates may be used. The structure is a display apparatus that includes a display surface, a plurality of flexible non-rectangular substrates over which part of the display surface is formed, and light-emitting apparatuses formed over the respective flexible substrates. Each of the light-emitting apparatuses includes pixel regions formed in a matrix. The pixel regions have convex or concave regions when some of the plurality of flexible non-rectangular substrates are bent. The plurality of flexible non-rectangular substrates include regions where the substrates are connected to each other.

Alternatively, a driver circuit may be provided in the above structure. The structure is a display apparatus that includes a display surface, a plurality of flexible non-rectangular substrates over which part of the display surface is formed, and light-emitting apparatuses formed over the respective flexible substrates. Each of the light-emitting apparatuses includes pixel regions formed in a matrix and a driver circuit electrically connected to the pixel regions. The pixel regions have convex or concave regions when some of the plurality of flexible non-rectangular substrates are bent. The plurality of flexible non-rectangular substrates include regions where the substrates are connected to each other.

In each of the above structures, the display surface of the display apparatus may have a curved surface. A curved display panel has a larger area than a flat display panel and thus can display a lot of information.

Alternatively, in each of the above structures, the display surface of the display apparatus may have a spherical surface, a substantially spherical surface, a hemispherical surface, or a substantially hemispherical surface. The display surface is made to be three-dimensional, whereby the display apparatus is also referred to as a three-dimensional free form display with enriched expression compared with a conventional two-dimensional flat panel.

In this specification, the spherical surface is not necessarily limited to an ideal spherical surface, includes an oval spherical surface or shapes with slightly distorted spherical surfaces, and may be referred to as a substantially spherical surface or a roughly spherical surface. The spherical surface may also be referred to as a spherical shape. Similarly, the hemispherical surface is not necessarily limited to an ideal hemispherical surface, includes an oval hemispherical surface or shapes with slightly distorted hemispherical surfaces, and may be referred to as a substantially hemispherical surface or a roughly hemispherical surface. The hemispherical surface may also be referred to as a dome shape.

A plurality of panels with different shapes are combined to obtain a display panel for components provided in automobiles. Specifically, a display with a curved display surface is installed as an automobile interior component.

A flat surface and a curved surface are combined to form a display surface of a display. In this specification, a display is attached to a curved surface and is fixed with at least part of a display surface curved.

Curved surfaces can be broadly divided into a ruled surface and a double-curved surface. The ruled surface refers to a surface that can be defined as a trajectory of movement of a straight line. The double-curved surface refers to curved surfaces other than the ruled surface. The ruled surface specifically includes a pyramidal surface, a columnar surface, a tangent surface, a one-sheet hyperboloid, and a hyperbolic paraboloid. A curved surface with constant Gaussian curvature may be called a surface of constant curvature. A spherical surface is one in the case where the Gaussian curvature is a positive constant. A spherical surface refers to a surface with a constant radius, but is not particularly limited, and may be an aspherical surface.

A plurality of panels with different surface areas, for example, a panel with a spherical surface and a panel with a curved surface are connected to fix a display panel to a three-dimensional surface, i.e., a surface of a three-dimensional object with use of an adhesive layer. The three-dimensional object refers to an organic object or an inorganic object. Car interior components such as a dashboard and a steering wheel (also called a handle) are given as examples of the organic object. Glass is given as an example of the inorganic object.

For example, a member of a steering wheel is made to have an undulating surface, so that a display panel can be provided on the surface. The display panel is a display panel that includes a smoothly raised convex portion in the center part of the steering wheel and has a curved outline in its end portion. Part of a display surface includes a rounded convex bulge.

In order to install a display panel such that part of the display surface includes a rounded convex bulge, the display panel is preferably semi-fixed (partly fixed) to a member having a curved surface shape to maintain a curved surface shape of the display panel. To maintain the curved surface shape of the display panel, at least part of the curved surface of the display panel is fixed to the member having a curved surface shape. Accordingly, at least part of the curved surface of the display panel is fixed to a three-dimensional surface (also referred to as a 3D surface) of glass or a three-dimensional surface of an organic object.

A structure disclosed in this specification is a display apparatus that includes a display surface, a flexible substrate over which part of the display surface is formed, a member to which the flexible substrate is fixed, and a protective substrate covering the flexible substrate. The display surface has a convex or concave region. The convex or concave region is fixed to the member. The protective substrate is provided along the convex or concave region. Therefore, a curved surface portion of a panel that is fixed to the member with use of an adhesive layer is not movable.

A plurality of flexible substrates may be combined to form a large display screen. The structure is a display apparatus that includes a display surface, a plurality of flexible substrates over which part of the display surface is formed, light-emitting apparatuses formed over the respective flexible substrates, a member to which the plurality of flexible substrates are fixed, and a protective substrate covering the plurality of flexible substrates. The light-emitting apparatus includes a first light-emitting device and a second light-emitting device positioned adjacent to the first light-emitting device. The display surface has a convex or concave region. The convex or concave region is fixed to the member. The plurality of flexible substrates include regions where the substrates are connected to each other.

When part of a display panel has a light-transmitting property, the display panel can be installed on a window (a windshield, a rear window, or a side window) as a see-through display panel for passersby outside the car as well as passengers.

A structure disclosed in this specification is a display apparatus that includes a display surface, a plurality of flexible non-rectangular substrates over which part of the display surface is formed, light-emitting apparatuses formed over the respective flexible substrates. Each of the light-emitting apparatuses includes pixel regions formed in a matrix. The light-emitting apparatus includes a first light-emitting device and a second light-emitting device positioned adjacent to the first light-emitting device. The display surface has a convex or concave region. The plurality of flexible non-rectangular substrates include regions where the substrates are connected to each other.

In each of the above structures, in the case where a driver circuit is provided, the driver circuit may be provided on the rear side of the pixel region. By being provided on the rear side of the pixel region, the driver circuit can be positioned in a region that is not visible to a user.

A light-emitting apparatus may be a first light-emitting device and a second light-emitting device positioned adjacent to the first light-emitting device. The structure is a display apparatus that includes a display surface, a flexible non-rectangular substrate over which part of the display surface is formed, a light-emitting apparatus formed over the flexible substrate. The light-emitting apparatus includes pixel regions formed in a matrix. The light-emitting apparatus includes a first light-emitting device and a second light-emitting device positioned adjacent to the first light-emitting device. The display surface has a convex or concave region when part of the flexible non-rectangular substrate is bent.

A plurality of flexible substrates may be used. The structure is a display apparatus that includes a display surface, a plurality of flexible non-rectangular substrates over which part of the display surface is formed, and light-emitting apparatuses formed over the respective flexible substrates. Each of the light-emitting apparatuses includes pixel regions formed in a matrix. The light-emitting apparatus includes a first light-emitting device and a second light-emitting device positioned adjacent to the first light-emitting device. The pixel regions have convex or concave regions when some of the plurality of flexible non-rectangular substrates are bent. The plurality of flexible non-rectangular substrates include regions where the substrates are connected to each other.

Each of the first light-emitting device and the second light-emitting device in the above structure includes a lower electrode, a first functional layer over the lower electrode, a light-emitting layer over the first functional layer, a second functional layer over the light-emitting layer, and an upper electrode over the second functional electrode. A side surface of the first functional layer and a side surface of the light-emitting layer are aligned or substantially aligned in a cross-sectional view. The side surface of the first functional layer, a side surface of a first light-emitting layer, and a side surface of a second light-emitting layer are aligned or substantially aligned in a cross-sectional view.

A light-emitting device structure for white light emission may be employed. Each of the first light-emitting device and the second light-emitting device includes a lower electrode, a first functional layer over the lower electrode, a light-emitting layer over the first functional layer, a second functional layer over the light-emitting layer, and an upper electrode over the second functional layer.

A structure in which light-emitting devices are stacked may be employed for white light emission. Each of the first light-emitting device and the second light-emitting device includes a lower electrode, a first functional layer over the lower electrode, a first light-emitting layer over the first functional layer, a common layer over the first light-emitting layer, a second light-emitting layer over the common layer, a second functional layer over the second light-emitting layer, and an upper electrode over the second functional layer.

The light-emitting device may have a structure without a hole-transport layer. In that case, the first functional layer includes one or both of a hole-injection layer and a hole-transport layer, and the second functional layer includes one or both of an electron-transport layer and an electron-injection layer.

Without being limited to the white light emission, light emitted from the first light-emitting device and light emitted from the second light-emitting device may have the same color.

The first light-emitting device includes a first lower electrode, a first functional layer over the first lower electrode, a first light-emitting layer over the first functional layer, a second functional layer over the first light-emitting layer, and an upper electrode over the second functional layer. The second light-emitting device includes a second lower electrode, a third functional layer over the second lower electrode, a second light-emitting layer over the third functional layer, and a fourth functional layer over the second light-emitting layer.

The first light-emitting device includes a first lower electrode, a first functional layer over the first lower electrode, a third light-emitting layer over the first functional layer, a first common layer over the third light-emitting layer, a fourth light-emitting layer over the first common layer, a second functional layer over the fourth light-emitting layer, and an upper electrode over the second functional layer. The second light-emitting device includes a second lower electrode, a third functional layer over the second lower electrode, a fifth light-emitting layer over the third functional layer, a third common layer over the fifth light-emitting layer, a sixth light-emitting layer over the third common layer, a fourth functional layer over the sixth light-emitting layer, and an upper electrode over the fourth functional layer.

Each of the first functional layer and the third functional layer includes one or both of a hole-injection layer and a hole-transport layer. Each of the second functional layer and the fourth functional layer includes one or both of an electron-transport layer and an electron-injection layer.

Light emitted from the first light-emitting device and light emitted from the second light-emitting device may be different from each other.

Each of the above structures may include a region with a distance between a side surface of the first light-emitting device and a side surface of the second light-emitting device of less than or equal to 1 μm.

Each of the above structures may include a region with a distance between a side surface of the first light-emitting device and a side surface of the second light-emitting device of less than or equal to 100 nm.

This structure is not limited to a display panel displaying full-color images and may be a lighting apparatus emitting light of a single color or a plurality of colors.

In this specification, a device manufactured using a metal mask or an FMM (fine metal mask) is may be referred to as a device having an MM (metal mask) structure. In this specification, a device manufactured without using a metal mask or an FMM may be referred to as a device having an MML (metal maskless) structure. A display apparatus having an MML structure is manufactured without using a metal mask and thus has higher flexibility in designing the pixel arrangement and the pixel shape than a display apparatus having an FMM structure or an MM structure.

The display apparatus of one embodiment of the present invention can have a structure in which an insulator that covers an end portion of the pixel electrode is not provided, that is, a structure in which an insulator is not provided between the pixel electrode and an EL layer. With such a structure, light can be efficiently extracted from the EL layer, leading to extremely low viewing angle dependence. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction. The display apparatus of one embodiment of the present invention can have improved viewing angle dependence and high image visibility.

In the case where a display apparatus is formed using a fine metal mask (FMM) structure, the pixel arrangement structure is limited in some cases. Here, the FMM structure is described below.

In the FMM structure, a metal mask provided with opening portions (also referred to as an FMM) is set to be opposed to a substrate so that EL can be deposited in a desired region at the time of EL evaporation. Then, the EL is deposited in the desired region by EL evaporation through the FMM. When the size of the substrate at the time of EL evaporation is larger, the size of the FMM is increased and accordingly the weight thereof is also increased. In addition, heat is applied to the FMM at the time of EL evaporation and may change the shape of the FMM. Furthermore, there is a method in which EL evaporation is performed while a certain level of tension is applied to the FMM. Therefore, the weight and strength of the FMM are important parameters.

Therefore, the pixel arrangement structure with an FMM needs to be designed under certain restrictions and the above-described parameters need to be considered. By contrast, the display apparatus of one embodiment of the present invention is manufactured using an MML structure and thus offers an excellent effect such as higher flexibility in the pixel arrangement structure than the FMM structure. This structure is highly compatible with a flexible device, for example; thus, one or both of a pixel and a driver circuit can have a variety of circuit arrangements.

In this specification, a structure in which light-emitting layers in light-emitting devices of different colors (here, blue (B), green (G), and red (R)) are separately formed or separately patterned may be referred to as an SBS (Side By Side) structure. In this specification, a light-emitting device capable of emitting white light may be referred to as a white-light-emitting device. Note that white-light-emitting devices are combined with coloring layers (e.g., color filters), whereby full-color display can be achieved.

Note that in this specification, an EL (Electroluminescence) layer refers to a layer provided between a pair of electrodes in a light-emitting device. Thus, a light-emitting layer containing an organic compound that is a light-emitting substance, which is interposed between electrodes, is one embodiment of the EL layer.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more of light-emitting layers are selected such that their emission colors are complementary to each other. For example, when emission colors of a first light-emitting layer and a second light-emitting layer are complementary colors, a light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the case of a single structure. In the device having a tandem structure, for example, a charge-generation layer is suitably provided between the plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. The light-emitting device having an SBS structure is suitable for the case where the power consumption is required to be low. Meanwhile, the white-light-emitting device is suitable in terms of lower manufacturing cost or higher manufacturing yield because the manufacturing process of the white-light-emitting device is simpler than that of the light-emitting device having an SBS structure.

Note that in this specification, the light-emitting apparatus refers to an image display device or a light source (including a lighting apparatus). In addition, a light-emitting apparatus includes a module in which a light-emitting device is attached to a connector such as a flexible printed circuit (FPC) or a TCP (Tape Carrier Package), a module in which a printed wiring board is provided on the tip of a TCP, or a module in which an IC (integrated circuit) is directly mounted on a substrate over which a light-emitting device is formed by a COG (Chip On Glass) method.

Note that the non-rectangular shape refers to shapes other than rectangles including rough quadrangles, examples of which include polygons other than quadrangles, circles, ovals, and shapes with partly curved outer peripheries. Such complex shapes can be handled, resulting in a high degree of design flexibility and improved design of the display apparatus.

### Effect of the Invention

In one embodiment of the present invention, a display apparatus with high display quality can be provided. In one embodiment of the present invention, a display apparatus with reduced power consumption can be provided.

In one embodiment of the present invention, by combining curved display panels with different shapes, the curvatures of the display panels are selectively changed, so that a display apparatus that has a display surface along a complex shape or a concave or convex region of an in-car component can be achieved, and the interior of the car can be made to look luxurious.

According to one embodiment of the present invention, a novel display apparatus that is highly convenient or reliable can be provided. A novel input/output apparatus that is highly convenient or reliable can be provided. A novel light-emitting apparatus, a novel display apparatus, a novel input/output apparatus, or a novel semiconductor apparatus can be provided.

In the case where an omnidirectional camera is used as an in-vehicle camera, the display apparatus enables images captured by the omnidirectional camera to be displayed at once in an easy-to-see manner for a user.

The display apparatus enables the degree of design flexibility of a display apparatus to be increased and design of the display apparatus to be improved.

Note that the description of these effects does not preclude the existence of other effects. One embodiment of the present invention does not need to have all of these effects. Other effects will be apparent from the description of the specification, the drawings, or the claims, and other effects can be derived from the description of the specification, the drawings, or the claims.

### BRIEF DESCRIPTION OF THE DRAWINGS

FIG. 1A is an external view of a display apparatus of one embodiment of the present invention;

FIG. 1B is a schematic top view of an unfolded display panel.

FIG. 2A is a schematic top view of an unfolded display panel; FIG. 2B is an external view of a display apparatus of one embodiment of the present invention.

FIG. 3A is an external view of a display apparatus of one embodiment of the present invention;

FIG. 3B is a schematic top view of a display panel in FIG. 3A when unfolded; FIG. 3C is an external view of a display apparatus of one embodiment of the present invention; FIG. 3D is a schematic top view of a display panel in FIG. 3C when unfolded.

FIG. 4A is an external view of a display apparatus; FIG. 4B is a schematic cross-sectional view including an axis X3 of a light-emitting apparatus of one embodiment of the present invention;

FIG. 4C is a perspective view of part of the display apparatus.

FIG. 5A is a top view of a plurality of display panels before overlapping; FIG. 5B is an external view of a display apparatus of one embodiment of the present invention.

FIG. 6A is a top view illustrating an example of a display region 100; FIG. 6B is a cross-sectional view illustrating an example of the display region 100.

FIG. 7A to FIG. 7E are top views illustrating examples of a pixel.

FIG. 8A to FIG. 8E are top views illustrating examples of a pixel.

FIG. 9A and FIG. 9B are diagrams each illustrating a structure example of a display apparatus.

FIG. 10A to FIG. 10C are diagrams each illustrating a structure example of a display apparatus.

FIG. 11A, FIG. 11B, and FIG. 11D are cross-sectional views each illustrating an example of a display apparatus. FIG. 11C and FIG. 11E are diagrams each illustrating an example of an image.

FIG. 11F to FIG. 11H are top views each illustrating an example of a pixel.

FIG. 12A is a cross-sectional view illustrating a structure example of a display apparatus. FIG. 12B to FIG. 12D are top views each illustrating an example of a pixel.

FIG. 13A is a cross-sectional view illustrating a structure example of a display apparatus. FIG. 13B to FIG. 13I are top views each illustrating an example of a pixel.

FIG. 14A to FIG. 14F are diagrams each illustrating a structure example of a light-emitting device.

FIG. 15A and FIG. 15B are diagrams each illustrating structure examples of light-emitting devices and a light-receiving device.

FIG. 16A and FIG. 16B are diagrams each illustrating a structure example of a display apparatus.

FIG. 17A to FIG. 17D are diagrams each illustrating a structure example of a display apparatus.

FIG. 18A to FIG. 18C are diagrams each illustrating a structure example of a display apparatus.

FIG. 19A to FIG. 19D are diagrams each illustrating a structure example of a display apparatus.

FIG. 20A to FIG. 20F are diagrams each illustrating a structure example of a display apparatus.

FIG. 21A to FIG. 21F are diagrams each illustrating a structure example of a display apparatus.

FIG. 22 is a diagram illustrating a structure example of a display apparatus.

FIG. 23A is a cross-sectional view illustrating an example of a display apparatus. FIG. 23B is a cross-sectional view illustrating an example of a transistor.

FIG. 24A to FIG. 24D are diagrams each illustrating an example of a pixel. FIG. 24E and FIG. 24F are diagrams each illustrating an example of a circuit diagram of a pixel.

FIG. 25A and FIG. 25B are schematic views each illustrating a car using a display panel.

FIG. 26A and FIG. 26B are diagrams each illustrating an electronic device provided with a curved, typically, spherical or hemispherical display panel.

FIG. 27 is a diagram illustrating a structure example of a vehicle.

FIG. 28A, FIG. 28B, and FIG. 28C are diagrams each illustrating a structure example of a vehicle control apparatus. FIG. 28D is an unfolded view of a display apparatus.

FIG. 29 is a perspective view illustrating a display apparatus of one embodiment of the present invention.

FIG. 30 is a schematic view illustrating an example of a display apparatus of one embodiment of the present invention in an unfolded state.

FIG. 31A is a top view of two display panels; FIG. 31B is a schematic view illustrating the case where the two display panels are combined to form a curved surface.

FIG. 32A is a front view of a display apparatus; FIG. 32B and FIG. 32C are cross-sectional views of the display apparatus; FIG. 32D is an enlarged schematic view of part of a cross-sectional structure of the display apparatus of one embodiment of the present invention.

FIG. 33A, FIG. 33B, and FIG. 33C are diagrams each illustrating an example of a cross section of a display apparatus of one embodiment of the present invention.

FIG. 34 is a diagram illustrating an example of an electric motorcycle including a display apparatus.

FIG. 35A, FIG. 35B, and FIG. 35C are diagrams each illustrating a structure example of the inside of a vehicle.

FIG. 36A and FIG. 36C are perspective views each illustrating a modification example of a shape of a display apparatus; FIG. 36B and FIG. 36D are each an example of the display apparatus in an unfolded state.

### MODE FOR CARRYING OUT THE INVENTION

In the case where there is a description “X and Y are connected” in this specification, the case where X and Y are electrically connected, the case where X and Y are functionally connected, and the case where X and Y are directly connected are regarded as being disclosed in this specification. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y. Note that a switch has a function of being controlled to be turned on or off. That is, a switch has a function of controlling whether or not current flows by being in a conduction state (on state) or a non-conduction state (off state).

For example, in the case where X and Y are functionally connected, one or more circuits that allow functional connection between X and Y (e.g., a logic circuit (an inverter, a NAND circuit, or a NOR circuit); a signal converter circuit (a digital-analog converter circuit, an analog-digital converter circuit, or a gamma correction circuit); a potential level converter circuit (a power supply circuit (a step-up circuit or a step-down circuit) or a level shifter circuit for changing the potential level of a signal); a voltage source; a current source; a switching circuit; an amplifier circuit (a circuit that can increase signal amplitude or the amount of current, an operational amplifier, a differential amplifier circuit, a source follower circuit, or a buffer circuit); a signal generation circuit; a memory circuit; or a control circuit) can be connected between X and Y. Note that for example, even when another circuit is sandwiched between X and Y, X and Y are functionally connected when a signal output from X is transmitted to Y.

Note that an explicit description that X and Y are electrically connected includes the case where X and Y are electrically connected (i.e., the case where X and Y are connected with another element or another circuit sandwiched therebetween) and the case where X and Y are directly connected (i.e., the case where X and Y are connected without another element or another circuit sandwiched therebetween).

In this specification, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Therefore, the terms “source” and “drain” can be sometimes replaced with each other in this specification. In this specification, the expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification, one of the gate and the back gate of the transistor may be referred to as a first gate and the other of the gate and the back gate of the transistor may be referred to as a second gate. Moreover, the terms “gate” and “back gate” can be sometimes replaced with each other in one transistor. In the case where a transistor includes three or more gates, the gates may be sometimes referred to as a first gate, a second gate, or a third gate, in this specification.

Unless otherwise specified, off-state current in this specification refers to drain current of a transistor in an off state (also referred to as a non-conducting state or a cutoff state). Unless otherwise specified, an off state refers to, in an n-channel transistor, a state where voltage V_{gs} between its gate and source is lower than the threshold voltage Vₜₕ (in a p-channel transistor, higher than Vₜₕ).

In this specification, a metal oxide is an oxide of metal in a broad sense. Metal oxides are classified into an oxide insulator, an oxide conductor (including a transparent oxide conductor), and an oxide semiconductor (also simply referred to as an OS). For example, in the case where a metal oxide is used in an active layer of a transistor, the metal oxide is referred to as an oxide semiconductor in some cases. That is, an OS transistor can also be called a transistor including a metal oxide or an oxide semiconductor.

Ordinal numbers such as “first”, “second”, and “third” in this specification are used to avoid confusion among components. Thus, the terms do not limit the number of components. In addition, the terms do not limit the order of components. For example, a “first” component in one embodiment in this specification can be referred to as a “second” component in other embodiments or the scope of claims. As another example, a “first” component in one embodiment in this specification can be omitted in other embodiments or the scope of claims.

In this specification, the terms for describing positioning, such as “over” and “under”, are sometimes used for convenience to describe the positional relationship between components with reference to drawings. The positional relation between components is changed as appropriate in accordance with the direction in which the components are described. Thus, terms for the description are not limited to those used in the specification, and the description can be rephrased appropriately depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed on and in direct contact with the insulating layer A, and does not exclude the case where another component is provided between the insulating layer A and the electrode B.

In this specification and the like, the terms “film” or “layer” can be interchanged with each other depending on the situation. For example, the term “conductive layer” can be changed into the term “conductive film” in some cases. As another example, the term “insulating film” can be changed into the term “insulating layer” in some cases. Alternatively, the term “film” or “layer” is not used and can be interchanged with another term depending on the case or the situation. For example, the term “conductive layer” or “conductive film” can be changed into the term “conductor” in some cases. As another example, the term “insulating layer” or “insulating film” can be changed into the term “insulator” in some cases.

Embodiments of the present invention will be described in detail below with reference to the drawings. Note that the present invention is not limited to the following description, and it is readily understood by those skilled in the art that modes and details of the present invention can be modified in various ways. The present invention should not be construed as being limited to the description of the embodiments below.

### Embodiment 1

In this embodiment, an example of a display apparatus that uses a flexible non-rectangular substrate, includes a light-emitting device formed over the flexible substrate, and is provided with a curved display surface will be described below.

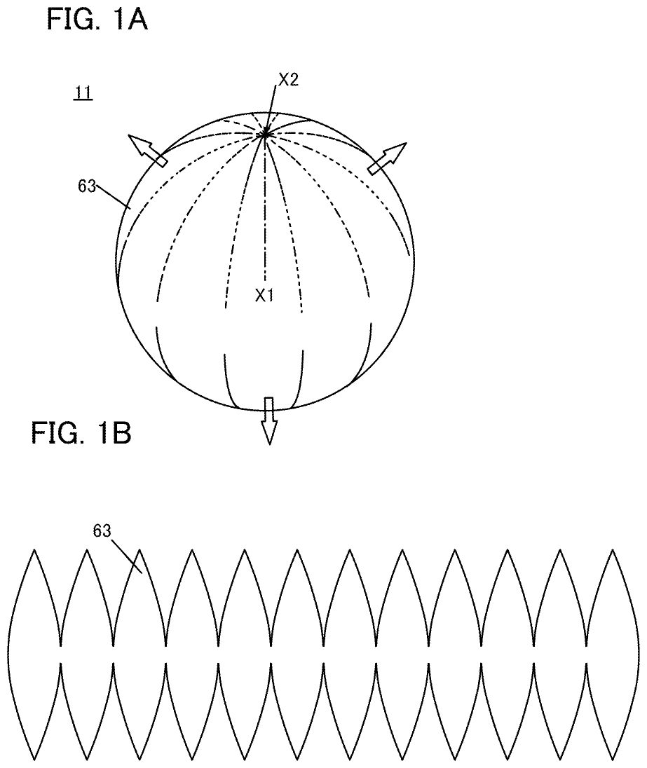

FIG. 1A is an external view of a display panel 11 of one embodiment of the present invention. FIG. 1B is a schematic top view of an unfolded display panel before manufacture of the display panel 11. Circuit design for an unfolded display panel in a schematic top view on a plane enables an outline of a display region of the display panel to have a non-rectangular shape, for example, a circular shape, an elliptical shape, or a polygonal shape. Furthermore, depending on the circuit design, a display panel including a display region with a three-dimensional shape, for example, a cylindrical shape, a spherical shape, or a hemispherical shape can be achieved.

An example of a method for manufacturing a display apparatus is described below. A plurality of pixels are arranged in a matrix over a flexible substrate. The flexible substrate including the plurality of pixels arranged in a matrix is also referred to as a flexible display. A method in which a transistor or a light-emitting device is directly formed on a flexible substrate may be employed, or a method in which a transistor or a light-emitting device is formed over a glass substrate, separated from the glass substrate, and then bonded to a flexible substrate with an adhesive layer may be employed. Although there are various kinds of separation methods and transfer methods, there is no particular limitation and a known technique is employed as appropriate.

In the case where a glass substrate is used, a glass substrate with a size of the 3rd generation (550 mm×650 mm), the 3.5th generation (600 mm×720 mm or 620 mm×750 mm), the 4th generation (680 mm×880 mm or 730 mm×920 mm), the 5th generation (1100 mm×1300 mm), the 6th generation (1500 mm×1850 mm), the 7th generation (1870 mm×2200 mm), the 8th generation (2200 mm×2400 mm), the 9th generation (2400 mm×2800 mm or 2450 mm×3050 mm), or the 10th generation (2950 mm×3400 mm), or a larger size can be used. A glass substrate can withstand heat treatment temperatures higher than that in the case of forming a transistor directly on a flexible substrate; thus, a glass substrate is suitable for the case where the process temperature for forming a transistor is high.

Examples of flexible substrates include polyester resins typified by PET and PEN, a polyacrylonitrile resin, an acrylic resin, a polyimide resin, a polymethyl methacrylate resin, a PC resin, a PES resin, polyamide resins (such as nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a PTFE resin, and an ABS resin. In particular, a material with a low coefficient of linear expansion is preferred, and for example, a polyamide imide resin, a polyimide resin, a polyamide resin, and PET can be suitably used. A substrate in which a fibrous body is impregnated with a resin and a substrate whose coefficient of linear expansion is reduced by mixing an inorganic filler with a resin can also be used.

Alternatively, a metal film can be used as the flexible substrate. As the metal film, stainless steel or aluminum can be used.

The flexible substrate may have a structure in which a layer of any of the materials given above and at least one of a hard coat layer (e.g., a silicon nitride layer) by which a surface of a device is protected from damage and a layer for dispersing pressure (e.g., an aramid resin layer) are stacked.

As the adhesive layer, an ultraviolet curable adhesive, a reactive curable adhesive, a thermosetting adhesive, or an anaerobic adhesive can be used. An adhesive sheet may be used.

Then, the flexible substrate is processed or cut into a non-rectangular shape illustrated in FIG. 1B.

Twelve tips of the non-rectangles each with an angle of about 30° are gathered in one place (e.g., apex X2) to form one hemisphere and the other 12 tips each with an angle of about 30° are gathered in one place to form the other hemisphere, so that the display panel 11 including one substantially spherical display region 63 can be formed. The display panel 11 includes the display region 63 whose display surface is convex when part of the flexible non-rectangular substrate is bent. Ideally, the display panel is preferably assembled such that the width of a seam is as small as possible.

Before the display panel 11 is assembled, the flexible substrate may be heated while being pressed against a sphere mold to be rounded. Since a flexible substrate, depending on its material or thickness, is unlikely to have a curved surface in some cases, a resulting display panel cannot be exactly called spherical. Although a shape that can be called a dodecahedron is obtained in some cases when the shape illustrated in FIG. 1A is formed, the shape is called substantially spherical in this specification. Since parts of the display panel illustrated in FIG. 1B are connected at the constricted portions, the whole display panel 11 can also be regarded as one surface even when the display panel is assembled to have the shape illustrated in FIG. 1A.

A framework is preferably included in a hollow of the display apparatus so that a substantially spherical surface is held or fixed. As the framework, a wire-like material or a frame made of thinned plastic, wood, or bamboo can be used as well as a metal. The display panel may be attached to a metal sphere (aluminum) that is hollow. In the case where the metal sphere has a specular surface, light can be efficiently emitted. The display panel may be attached to a paper sphere fixed with glue like papier-mache. In the hollow of the display apparatus, a transistor provided in the display region 63 or a driver circuit, a memory device, and a power source that are electrically connected to an EL device can be provided. The power source includes a power source circuit or a power storage device. In the memory device, a video signal for displaying full-color images on the display region 63 can be stored.

A wireless circuit may be provided in the hollow of the display apparatus so that a video signal from the outside is received and stored in the memory device. An image signal stored in the memory device is converted, by an image processing circuit, into a signal for displaying an image on the display region 63, whereby full-color display on the display region 63 can be achieved.

As illustrated in FIG. 1A, the radius of a sphere of the display apparatus including the display panel 11 is the length of a straight line connecting center X1 to a fixed point X (an apex X2 in FIG. 1A) that is one point on a spherical surface. Although depending on the size of a substrate to be used, the radius of the display panel 11 can be greater than or equal to 1 cm and less than or equal to 200 cm, preferably greater than or equal to 10 cm and less than or equal to 100 cm.

The display apparatus includes a light-emitting device including pixel regions formed in a matrix; an organic EL device is used in this embodiment. Although the direction of light emission is schematically indicated by three arrows in FIG. 1A, light can be emitted in all directions.

A quantum dot can be used as a color conversion (wavelength conversion) material of an organic EL device. A quantum dot is a semiconductor nanocrystal with a diameter of several nanometers and contains approximately 1×10³ to 1×10⁶ atoms. A quantum dot confines an electron or a hole, and an exciton, which results in discrete energy states and an energy shift depending on the size of a quantum dot. This means that quantum dots made of the same substance emit light with different wavelengths depending on their size; accordingly, emission wavelengths can be easily adjusted by changing the size of quantum dots.

The display region 63 can have a function of a touch panel. The touch panel can be operated when a user touches it or holds his/her hand over it, or by gesture.

The display apparatus including the display panel 11 can be regarded as a highly convenient novel display apparatus.

The display apparatus including the display panel 11 can be used as an interior accessory like a globe or as a lighting device. In the case where the display panel 11 is used as an interior product, for example, display can be changed. Furthermore, the display apparatus including the display panel 11 can be used in amusement supplies or toys.

The display apparatus including the display panel 11 tends to be unstable like a ball. In the case where the display panel 11 is not fixed, it may be set on a crystal ball stand or a cushion so as to be accessible to a user. The weight of a power source inside the display panel 11 may be used to generate imbalance and the center of gravity of the display panel 11 may be used to always keep the top and bottom constant like a tumble doll so that the display panel 11 stands still in a certain direction. An electromagnet or a magnet provided inside the display panel 11 or around the display panel 11 may be used to display the display panel 11 in the air by magnetic force.

When the display panel 11 has not only an image display function but also other communication functions and has a radius of about 3 cm, it can be placed in a user's pocket and carried around as a portable information terminal.

The display panel 11 illustrated in FIG. 1A and FIG. 1B may have a plurality of resolutions. Specifically, the center X1 or the vicinity of the center X1 of the display panel 11 illustrated in FIG. 1A can have high resolution, and the apex X2 or the vicinity of the apex X2 of the display panel 11 can have lower resolution than the center X1 or the vicinity of the center X1 of the display panel 11.

For example, the resolution at the center X1 or in the vicinity of the center X1 is greater than or equal to 500 ppi (pixels per inch) and less than or equal to 10000 ppi, and the resolution at the apex X2 or in the vicinity of the apex X2 is greater than or equal to 100 ppi and less than 500 ppi.

Note that the resolution of the display panel 11 is not limited to the above. For example, the resolution at the center X1 or in the vicinity of the center X1 may be greater than or equal to 100 ppi and less than 500 ppi, and the resolution at the apex X2 or in the vicinity of the apex X2 may be greater than or equal to 500 ppi and less than or equal to 10000 ppi. The resolution of the display panel 11 may be gradually changed from the center X1 to the apex X2.

By changing the resolution in the surface of the display panel 11 as described above, an effect that a viewer of the display panel 11 is more likely to feel immersed can be obtained. Moreover, by changing the resolution in the surface of the display panel 11, the power consumption of the display panel 11 can be reduced.

In the case where the light-emitting devices included in the display panel 11 are formed using a fine metal mask (FMM) structure, the resolution is difficult to vary among the light-emitting devices in some cases. Here, the FMM structure will be described below.

In the FMM structure, a metal mask provided with opening portions (also referred to as an FMM) is set to be opposed to a substrate so that EL can be deposited in a desired region at the time of EL evaporation. Then, the EL is deposited in the desired region by EL evaporation through the FMM. When the size of the substrate at the time of EL evaporation is larger, the size of the FMM is increased and accordingly the weight thereof is also increased. In addition, heat is applied to the FMM at the time of EL evaporation and may change the shape of the FMM. Furthermore, there is a method in which EL evaporation is performed while a certain level of tension is applied to the FMM. Therefore, the weight and strength of the FMM are important parameters.

Therefore, in the case where the resolution is varied in the surface of the display panel 11 with use of an FMM, the design of the FMM needs to be changed. Note that in the case of changing the design of the FMM, deformation of the FMM needs to be considered, which makes it very difficult to vary the resolution in the surface of the display panel. By contrast, the display panel of one embodiment of the present invention is manufactured using an MML structure, which brings an excellent effect that the resolution in the surface of the display panel is easily varied. That is, the display panel of one embodiment of the present invention (e.g., a flexible display panel over a non-rectangle) and the MML structure are very compatible with each other. In other words, the flexible display panel and the MML structure have a high affinity for each other.

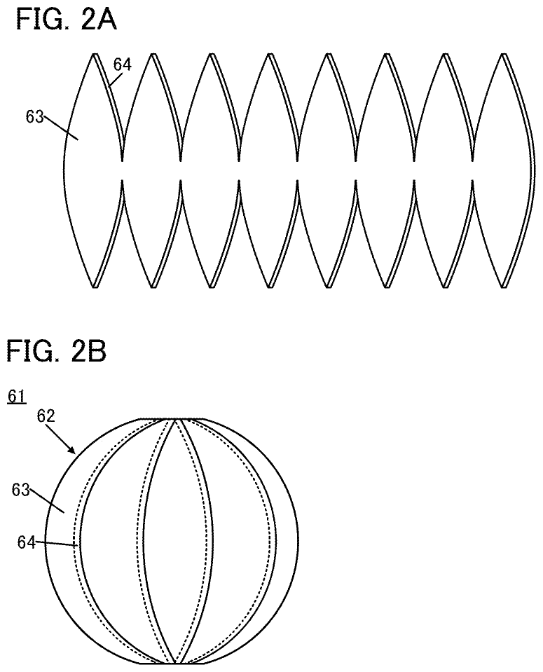

Next, an example that is different from FIG. 1 is illustrated in FIG. 2. In the example, driver circuits including transistors are provided over one flexible substrate.

FIG. 2A is a schematic top view of an unfolded display panel. FIG. 2B is an external view of a display apparatus of one embodiment of the present invention.

A display panel 61 illustrated in FIG. 2B includes the display region 63 and a non-display region 64. Pixel regions formed in a matrix are provided in the display region 63, and driver circuits electrically connected to the pixel regions are provided in the non-display region 64. Note that some of the driver circuits provided in the non-display region 64 may be provided in the pixel regions in the display region 63. Such a structure can reduce the area of the non-display region.

A method for manufacturing the display panel 61 is substantially the same as that of the display panel 11 and is thus omitted, and only different parts are described below.

Eight tips of non-rectangles each with an angle of about 45° are gathered in one place to form one hemisphere, and the other eight tips each with an angle of about 45° are gathered in one place to form the other hemisphere, so that one substantially spherical display apparatus is obtained.

When eight tips are gathered in one place, bending is performed at the boundary between the display region 63 and the non-display region 64 so that the display region 63 is stacked on top of the non-display region 64, whereby the driver circuit can be positioned under the pixel region. This state can also be expressed as the driver circuit being provided on the rear side of the pixel region. This structure enables the display panel 61 that has a spherical surface without affecting display to be provided as illustrated in FIG. 2B. Ideally, it is preferable that the display panel be assembled by stacking the non-display region 64 and the display region 63 so that the width of a seam is as small as possible.

Since a flexible substrate, depending on its material or thickness, is unlikely to have a curved surface in some cases, a resulting display panel cannot be exactly called spherical. Although a shape that can be called a dodecahedron is obtained in some cases when the shape illustrated in FIG. 2B is formed, the shape is called substantially spherical in this specification. Since parts of the display panel illustrated in FIG. 2A are connected at the constricted portions, the whole display panel 61 can also be regarded as one surface even when the display panel is assembled to have the shape illustrated in FIG. 2B.

By providing the driver circuits over one flexible substrate, the number of driver ICs can be reduced. Furthermore, space saving can be achieved.

The display panel 11 has the display region 63 on its entire surface. When the display panel is fixed, a string or a metal wire is fixed at a certain portion in a seam to hang the display panel in a car or on the ceiling. The display panel 11 may be fixed after removing part where an element and a wiring are not provided. In that case, the entire surface does not serve as the display region 63. In the case where the display panel 11 is fixed after removing part thereof, a video signal or electric power for driving can be supplied from the outside through the fixed portion without placing a power source inside the display panel 11.

FIG. 1 and FIG. 2 illustrate examples of display apparatuses including the substantially spherical display region 63; however, one embodiment of the present invention is not limited thereto, and the display apparatus may have a substantially hemispherical surface or surfaces with other three-dimensional shapes. Such a structure enables a video signal or electric power for driving to be supplied from the outside.

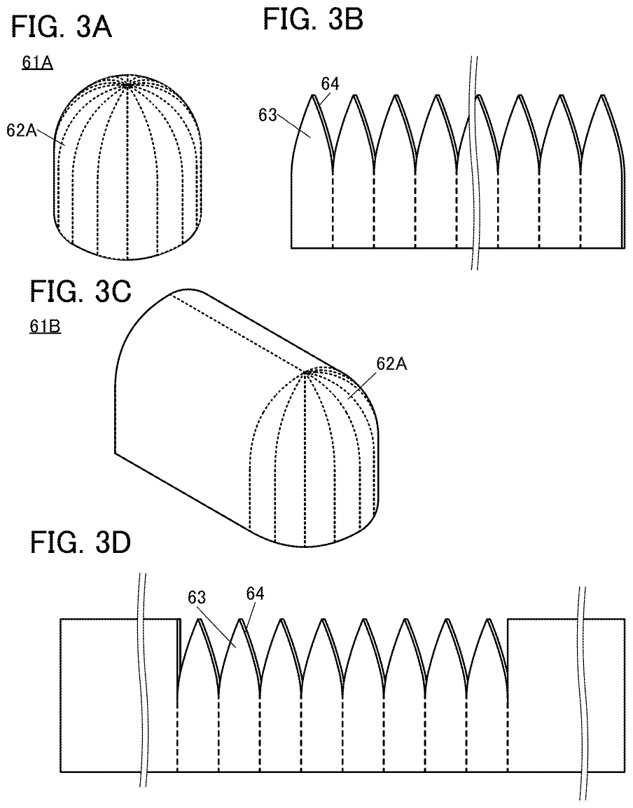

Other examples of shapes of a display panel will be described below with reference to FIG. 3.

FIG. 3A is an external view of a display apparatus of one embodiment of the present invention. FIG. 3B is a schematic top view of the display apparatus in FIG. 3A when unfolded. FIG. 3C is an external view of a display apparatus of one embodiment of the present invention. FIG. 3D is a schematic top view of the display apparatus in FIG. 3C when unfolded.

FIG. 3A is a schematic view of a display portion 61A that has a shape in which on one flat surface of a cylinder, a hemisphere with the same diameter as the cylinder is stacked.

FIG. 3B is an unfolded view in which bending is performed at the boundary between the display region 63 and the non-display region 64, and the bending portion is indicated by a dotted line. Although a large number of non-display regions 64 are used in FIG. 3B, some of them are omitted for simplification. Such a structure in which the display regions are formed with small widths is suitable for the case where a flexible substrate is difficult to have a curved surface depending on its material or thickness.

The display portion 61A can be installed in a car, specifically, on a dashboard, a ceiling, or a wall. Furthermore, a view of the outside of a car taken by a camera mounted on the car can be displayed as a panorama view on the display portion 61A.

The display portion 61A can be supplied with electric power or a video signal from the bottom.

FIG. 3C illustrates another example. FIG. 3C illustrates a display portion 61B that has a shape in which a curved shape like a tunnel, a hemisphere, and a cylinder are combined.

FIG. 3D is an unfolded view in which bending is performed at the boundary between the display region 63 and the non-display region 64, and the bending portion is indicated by a dotted line.

The display portion 61B can be installed in a car, specifically, on a dashboard, a ceiling, or a wall. The display portion 61B can be supplied with electric power or a video signal from the bottom.

In the example, part of the flexible non-rectangular substrate is bent to make a display surface have a convex shape; however, one embodiment of the present invention is not particularly limited. A display surface of a display apparatus may have a concave region.

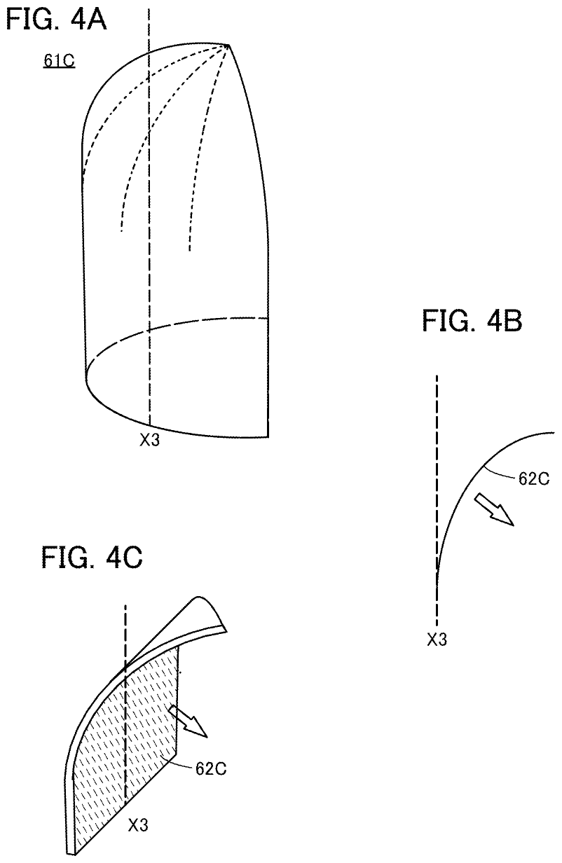

FIG. 4A is an external view of a display apparatus. FIG. 4B is a schematic cross-sectional view including an axis X3 of a light-emitting apparatus of one embodiment of the present invention. FIG. 4C is a perspective view of part of the display apparatus. Note that FIG. 4A and FIG. 4C selectively illustrate only part of the shape for clarity, not corresponding to the whole display apparatus.

FIG. 4A is a schematic view of a display portion 61C that has a shape in which on one flat surface of a cylinder, a hemisphere with the same diameter as the cylinder is stacked. In the case where the display portion 61C is cut along a surface including the axis X3 in FIG. 4A, light is emitted as indicated by an arrow in FIG. 4B. That is, a display surface of the display portion 61C has a concave region. FIG. 4C is a perspective view of the case where the axis X3 is seen with a different line of sight from FIG. 4A. Light is emitted from a curved surface of the concave region of the display portion 61C as indicated by an arrow in FIG. 4C.

The display portion 61C illustrated in FIG. 4A can be achieved by changing the direction of bending of the flexible substrate from FIG. 1, FIG. 2, and FIG. 3.

The display portion 61C can be installed on an inner wall of a car, specifically, on a dashboard, a ceiling, or a wall. The display portion 61C can display a map and thus can be used as a navigation device of a vehicle (e.g., a car, an aircraft, or a submarine). The display portion 61C can also be installed in a boundary portion between a ceiling and a pillar of a car. The display portion 61C can also be installed in a windshield of a helmet, enabling a driver to see a display on the display portion 61C while wearing the helmet.

The above-described structure of one embodiment of the present invention enables a display apparatus with high display quality to be provided. The structure of one embodiment of the present invention enables a display apparatus with reduced power consumption to be provided. The structure of one embodiment of the present invention enables the degree of design flexibility of a display apparatus to be increased and design of the display apparatus to be improved.

At least part of this embodiment can be implemented in combination with the other embodiments described in this specification as appropriate.

### Embodiment 2

In this embodiment, a structure that is different from that in the above embodiment will be described. Specifically, an example of a structure in which a plurality of the display regions 63 are used and some of them are made to overlap will be described in this embodiment while the example in which one display region 63 is bent to form the display panel is described in Embodiment 1.

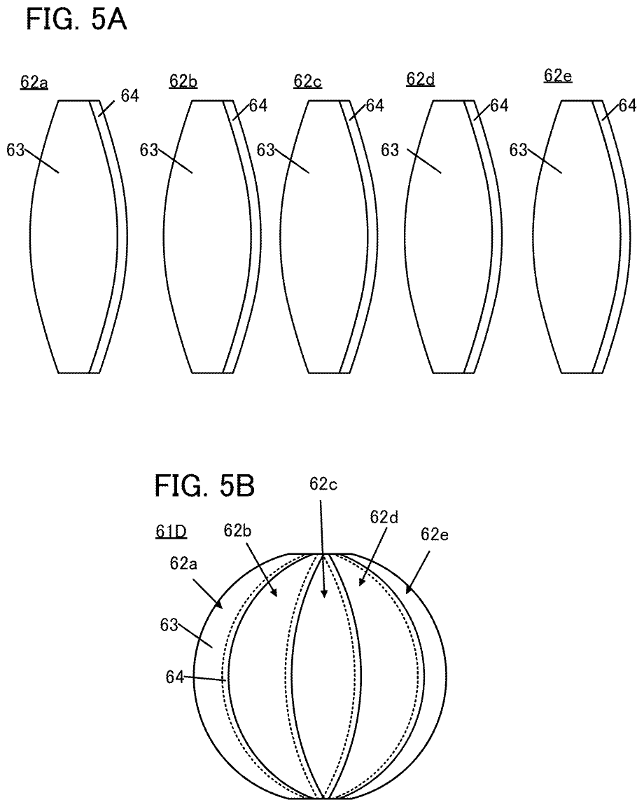

FIG. 5A is a top view of the plurality of display regions 63 before overlapping, here, members 62a, 62b, 62c, 62d, and 62e representing five display regions 63. FIG. 5B is an external view of a display panel of one embodiment of the present invention.

The five display regions 63 each include the non-display region 64. The non-display regions 64 are made to overlap and bent, whereby a hemispherical display portion 61D illustrated in FIG. 5B can be obtained. FIG. 5A illustrates the example in which the five display regions 63 are used; however, the number of display regions 63 is not particularly limited, may be selected as appropriate by a practitioner in accordance with a desired shape, and may be two or more.

The display portion 61D can be installed on an inner wall of a car, specifically, on a dashboard, a ceiling, or a wall. The display portion 61D can also be installed on a wristwatch dial.

Although the hemispherical display portion 61D is described here as an example, a spherical structure, a structure in which a hemisphere and a cylinder are combined, or a structure in which a curved surface of a concave region emits light can be obtained by combining the display portion 61D and Embodiment 1.

A defect called a point defect or a line defect might occur in a display panel for some reason. This embodiment makes it possible to assemble display panels with good display quality selected from among a plurality of display panels. Furthermore, part of the display panel can be replaced in the case of malfunction.

Meanwhile, unlike in Embodiment 1, a plurality of panels are made to overlap, which might cause noticeable seams. An image displayed on the seam area can be made less noticeable by adjusting an image display signal and processing an image with use of a driver circuit.

### Embodiment 3

In this embodiment, a specific structure of the display region in Embodiment 1 or Embodiment 2 will be described below.

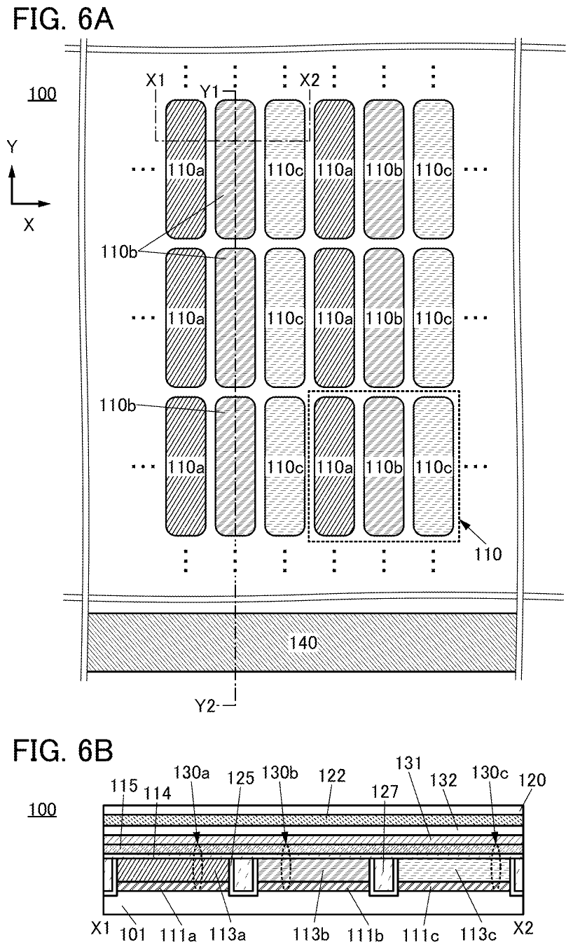

FIG. 6A is a top view of a display region 100. The display region 100 includes a pixel portion in which a plurality of pixels 110 are arranged in a matrix, and a connection portion 140 outside the pixel portion. A region between the pixels and the connection portion 140 do not emit light but are included in the display region 100.

The pixel 110 illustrated in FIG. 6A employs stripe arrangement. The pixel 110 illustrated in FIG. 6A consists of three subpixels 110a, 110b, and 110c. The subpixels 110a, 110b, and 110c include light-emitting devices that emit light of different colors. The subpixels 110a, 110b, and 110c can be of three colors of red (R), green (G), and blue (B) or of three colors of yellow (Y), cyan (C), and magenta (M).

FIG. 6A illustrates an example in which subpixels of different colors are arranged in the X direction and subpixels of the same color are arranged in the Y direction. Note that subpixels of different colors may be arranged in the Y direction and subpixels of the same color may be arranged in the X direction.

Although the top view of FIG. 6A illustrates an example in which the connection portion 140 is positioned on the lower side of the pixel portion, one embodiment of the present invention is not limited thereto. The connection portion 140 is provided in at least one of the upper side, the right side, the left side, and the lower side of the pixel portion in the top view. The number of connection portions 140 can be one or more.

FIG. 6B is a cross-sectional view taken along the dashed-dotted line X1-X2 in FIG. 6A. As illustrated in FIG. 6B, in the display region 100, light-emitting devices 130a, 130b, and 130c are provided over a layer 101 including transistors and insulating layers 131 and 132 are provided to cover these light-emitting devices. A substrate 120 is bonded to the insulating layer 132 with a resin layer 122. In a region between adjacent light-emitting devices, an insulating layer 125 and an insulating layer 127 over the insulating layer 125 are provided.

The display region of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 including transistors can employ a stacked-layer structure in which a plurality of transistors are provided over a substrate and an insulating layer is provided to cover these transistors, for example. The layer 101 including transistors may have a depressed portion between adjacent light-emitting devices. For example, an insulating layer positioned on the outermost surface of the layer 101 including transistors may have a depressed portion. A structure example of the layer 101 including transistors will be described later.

The light-emitting devices 130a, 130b, and 130c emit light of different colors. The light-emitting devices 130a, 130b, and 130c preferably emit light of three colors, red (R), green (G), and blue (B), for example.

As the light-emitting devices 130a, 130b, and 130c, an EL device typified by an OLED (Organic Light Emitting Diode) or a QLED (Quantum-dot Light Emitting Diode) is preferably used. Examples of a light-emitting substance contained in the EL device include a substance that exhibits fluorescence (a fluorescent material), a substance that exhibits phosphorescence (a phosphorescent material), an inorganic compound (a quantum dot material), and a substance that exhibits thermally activated delayed fluorescence (a thermally activated delayed fluorescent (TADF) material). Note that as a TADF material, a material that is in a thermal equilibrium state between a singlet excited state and a triplet excited state may be used. Since such a TADF material enables a short emission lifetime (excitation lifetime), an efficiency decrease of the light-emitting device in a high-luminance region can be inhibited.

The light-emitting device includes an EL layer between a pair of electrodes. In this specification, one of the pair of electrodes may be referred to as a pixel electrode and the other may be referred to as a common electrode.

One of the pair of electrodes of the light-emitting device functions as an anode and the other electrode functions as a cathode. The case where the pixel electrode functions as an anode and the common electrode functions as a cathode is described below as an example.

The light-emitting device 130a includes a pixel electrode 111a over the layer 101 including transistors, an island-shaped first organic layer 113a over the pixel electrode 111a, a fifth organic layer 114 over the island-shaped first organic layer 113a, and a common electrode 115 over the fifth organic layer 114. In the light-emitting device 130a, the first organic layer 113a and the fifth organic layer 114 can be collectively referred to as an EL layer.

There is no particular limitation on the structure of the light-emitting device in this embodiment, and the light-emitting device can have a single structure or a tandem structure. Note that a structure example of the light-emitting device will be described later in Embodiment 6.

The light-emitting device 130b includes a pixel electrode 111b over the layer 101 including transistors, an island-shaped second organic layer 113b over the pixel electrode 111b, the fifth organic layer 114 over the island-shaped second organic layer 113b, and the common electrode 115 over the fifth organic layer 114. In the light-emitting device 130b, the second organic layer 113b and the fifth organic layer 114 can be collectively referred to as an EL layer.

The light-emitting device 130c includes a pixel electrode 111c over the layer 101 including transistors, an island-shaped third organic layer 113c over the pixel electrode 111c, the fifth organic layer 114 over the island-shaped third organic layer 113c, and the common electrode 115 over the fifth organic layer 114. In the light-emitting device 130c, the third organic layer 113c and the fifth organic layer 114 can be collectively referred to as an EL layer.

The light-emitting devices of different colors share one film serving as the common electrode. The common electrode shared by the light-emitting devices of different colors is electrically connected to a conductive layer provided in the connection portion 140. Thus, the same potential is supplied to the common electrode included in the light-emitting devices of different colors.

A conductive film that transmits visible light is used as the electrode through which light is extracted, which is either the pixel electrode or the common electrode. A conductive film that reflects visible light is preferably used as the electrode through which light is not extracted.

As a material that forms the pair of electrodes (the pixel electrode and the common electrode) of the light-emitting device, a metal, an alloy, an electrically conductive compound, and a mixture thereof can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) typified by an alloy of aluminum, nickel, and lanthanum (Al—Ni—La), and an alloy of silver, palladium, and copper (Ag—Pd—Cu, also referred to as APC). In addition, it is possible to use aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not described above (e.g., lithium (Li), cesium (Cs), calcium (Ca), or strontium (Sr)), europium (Eu), ytterbium (Yb), an alloy containing an appropriate combination of any of these elements, or graphene.

The light-emitting devices preferably employ a microcavity structure. Therefore, one of the pair of electrodes of the light-emitting devices is preferably an electrode having properties of transmitting and reflecting visible light (a semi-transmissive and semi-reflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used in the light-emitting device. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity lower than or equal to 1×10⁻² cm.

The first organic layer 113a, the second organic layer 113b, and the third organic layer 113c are each provided in an island shape. The first organic layer 113a, the second organic layer 113b, and the third organic layer 113c each include a light-emitting layer. The first organic layer 113a, the second organic layer 113b, and the third organic layer 113c preferably include light-emitting layers that emit light of different colors.

The light-emitting layer is a layer containing a light-emitting substance. The light-emitting layer can include one or more kinds of light-emitting substances. As the light-emitting substance, a substance that exhibits an emission color of blue, violet, bluish violet, green, yellowish green, yellow, orange, or red is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton, an organometallic complex (particularly an iridium complex) having a phenylpyridine derivative including an electron-withdrawing group as a ligand, a platinum complex, and a rare earth metal complex.

The light-emitting layer may contain one or more kinds of organic compounds (a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, high efficiency, low-voltage driving, and a long lifetime of a light-emitting device can be achieved at the same time.

In addition to the light-emitting layer, the first organic layer 113a, the second organic layer 113b, and the third organic layer 113c may further include a layer containing any of a substance with a high hole-injection property, a substance with a high hole-transport property, a hole-blocking material, a substance with a high electron-transport property, a substance with a high electron-injection property, an electron-blocking material, or a substance with a bipolar property (a substance with a high electron-transport property and a high hole-transport property).

Either a low molecular compound or a high molecular compound can be used for the light-emitting devices, and an inorganic compound may also be included. Each layer included in the light-emitting device can be formed by an evaporation method (including a vacuum evaporation method), a transfer method, a printing method, an inkjet method, or a coating method.

For example, the first organic layer 113a, the second organic layer 113b, and the third organic layer 113c may each include one or more of a hole-injection layer, a hole-transport layer, a hole-blocking layer, an electron-blocking layer, an electron-transport layer, and an electron-injection layer. A hole-injection layer, a hole-transport layer, a hole-blocking layer, an electron-blocking layer, an electron-transport layer, and an electron-injection layer are referred to as functional layers in some cases.

In the EL layer, one or more of a hole-injection layer, a hole-transport layer, a hole-blocking layer, an electron-blocking layer, an electron-transport layer, and an electron-injection layer can be formed as a layer common to different colors. For example, a carrier-injection layer (a hole-injection layer or an electron-injection layer) may be formed as the fifth organic layer 114. Note that all the layers in the EL layer may be separately formed for different colors. That is, the EL layer does not necessarily include a layer common to different colors.

The first organic layer 113a, the second organic layer 113b, and the third organic layer 113c each preferably include a light-emitting layer and a carrier-transport layer over the light-emitting layer. In that case, the light-emitting layer is prevented from being exposed on the outermost surface in the manufacturing process of the display region 100, so that damage to the light-emitting layer can be reduced. Thus, the reliability of the light-emitting device can be improved.

The hole-injection layer is a functional layer that injects holes from the anode to the hole-transport layer and contains a material with a high hole-injection property. Examples of the material with a high hole-injection property include an aromatic amine compound and a composite material containing a hole-transport material and an acceptor material (an electron-accepting material).

The hole-transport layer is a functional layer that transports holes injected from the anode by the hole-injection layer, to the light-emitting layer. The hole-transport layer is a layer that contains a hole-transport material. As the hole-transport material, a substance having a hole mobility greater than or equal to 10⁶ cm²/Vs is preferable. Note that other substances can also be used as long as the substances have a hole-transport property higher than an electron-transport property. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 10⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a functional layer that injects electrons from a cathode to the electron-transport layer and a layer that contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. The electron-injection layer may have a stacked-layer structure of two or more layers. In the stacked-layer structure, for example, lithium fluoride can be used for the first layer and ytterbium can be used for the second layer.

Alternatively, for the electron-injection layer, an electron-transport material may be used. For example, a compound having an unshared electron pair and an electron deficient heteroaromatic ring can be used as the electron-transport material. pecifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, or inverse photoelectron spectroscopy.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-α:2′,3′-c]phenazine (abbreviation: HATNA), or 2,4,6-tris[3′-(pyridin-3-yl)biphenyl-3-yl]-1,3,5-triazine (abbreviation: TmPPPyTz) can be used for the organic compound having an unshared electron pair. Note that NBPhen has a higher glass transition point (Tg) than BPhen and thus has high heat resistance.

In the case of manufacturing a tandem light-emitting device, an intermediate layer is provided between two light-emitting units. The intermediate layer has a function of injecting electrons into one of the two light-emitting units and injecting holes to the other when voltage is applied between the pair of electrodes.

For the intermediate layer, a material that can be used for the electron-injection layer, for example, lithium can be suitably used. Alternatively, as another example, a material that can be employed for the hole-injection layer can be suitably used for the intermediate layer. Alternatively, a layer that includes a hole-transport material and an acceptor material (an electron-accepting material) can be suitably used for the intermediate layer. Alternatively, a layer that includes an electron-transport material and a donor material can be suitably used for the intermediate layer. Forming the intermediate layer with such a layer can inhibit an increase in drive voltage in the case of stacking light-emitting units.

Side surfaces of the pixel electrodes 111a, 111b, and 111c, the first organic layer 113a, the second organic layer 113b, and the third organic layer 113c are covered with the insulating layer 125 and the insulating layer 127. This inhibits the fifth organic layer 114 (or the common electrode 115) from being in contact with a side surface of any of the pixel electrodes 111a, 111b, and 111c, the first organic layer 113a, the second organic layer 113b, and the third organic layer 113c, thereby inhibiting a short circuit in the light-emitting device.

The insulating layer 125 preferably covers at least the side surfaces of the pixel electrodes 111a, 111b, and 111c. Furthermore, the insulating layer 125 preferably covers the side surfaces of the first organic layer 113a, the second organic layer 113b, and the third organic layer 113c. The insulating layer 125 can be in contact with the side surfaces of the pixel electrodes 111a, 111b, and 111c, the first organic layer 113a, the second organic layer 113b, and the third organic layer 113c.

The insulating layer 127 is provided over the insulating layer 125 to fill a depressed portion formed by the insulating layer 125. The insulating layer 127 can overlap with the side surfaces of the pixel electrodes 111a, 111b, and 111c, the first organic layer 113a, the second organic layer 113b, and the third organic layer 113c, with the insulating layer 125 therebetween.

Note that one of the insulating layer 125 and the insulating layer 127 is not necessarily provided. For example, in the case where the insulating layer 125 is not provided, the insulating layer 127 can be in contact with the side surfaces of the first organic layer 113a, the second organic layer 113b, and the third organic layer 113c. The insulating layer 127 can be provided over a protective layer 121 to fill gaps between the EL layers included in the light-emitting devices.

The fifth organic layer 114 and the common electrode 115 are provided over the first organic layer 113a, the second organic layer 113b, the third organic layer 113c, the insulating layer 125, and the insulating layer 127. Before the insulating layer 125 and the insulating layer 127 are provided, a step is generated due to a region where the pixel electrode and the EL layer are provided and a region where neither the pixel electrode nor the EL layer is provided (region between the light-emitting elements). In the display region of one embodiment of the present invention, the step can be eliminated by providing the insulating layer 125 and the insulating layer 127, and the coverage with the fifth organic layer 114 and the common electrode 115 can be improved. Thus, poor connection due to step disconnection can be inhibited. Alternatively, an increase in electric resistance, which is caused by local thinning of the common electrode 115 due to the step, can be inhibited.

To improve the planarity of a surface over which the fifth organic layer 114 and the common electrode 115 are formed, the top surface of the insulating layer 125 and the top surface of the insulating layer 127 are each preferably level or substantially level with the top surface of at least one of the first organic layer 113a, the second organic layer 113b, and the third organic layer 113c. The top surface of the insulating layer 127 is preferably flat and may have a projection portion or a depressed portion.

The insulating layer 125 includes regions in contact with the side surfaces of the first organic layer 113a, the second organic layer 113b, and the third organic layer 113c and functions as a protective insulating layer for the first organic layer 113a, the second organic layer 113b, and the third organic layer 113c. Providing the insulating layer 125 can prevent impurities (e.g., oxygen and moisture) from entering the first organic layer 113a, the second organic layer 113b, and the third organic layer 113c through their side surfaces, resulting in a highly reliable display region.

When the width (thickness) of the insulating layer 125 in the regions in contact with the side surfaces of the first organic layer 113a, the second organic layer 113b, and the third organic layer 113c is large in the cross-sectional view, the distance between the first organic layer 113a, the second organic layer 113b, and the third organic layer 113c is large, which results in a low aperture ratio. Meanwhile, when the width (thickness) of the insulating layer 125 is small, the effect of preventing impurities from entering the first organic layer 113a, the second organic layer 113b, and the third organic layer 113c through their side surfaces may be weakened. The width (thickness) of the insulating layer 125 in the regions in contact with the side surfaces of the first organic layer 113a, the second organic layer 113b, and the third organic layer 113c is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to 10 nm and less than or equal to 50 nm. When the width (thickness) of the insulating layer 125 is within the above range, the display region can have both a high aperture ratio and high reliability.

The insulating layer 125 can be an insulating layer containing an inorganic material. For the insulating layer 125, an inorganic insulating film, for example, an oxide insulating film, a nitride insulating film, an oxynitride insulating film, or a nitride oxide insulating film can be used. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer in forming the insulating layer 127 described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer.

Note that in this specification, oxynitride refers to a material that contains more oxygen than nitrogen in its composition, and nitride oxide refers to a material that contains more nitrogen than oxygen in its composition. For example, when silicon oxynitride is described, it refers to a material that contains more oxygen than nitrogen in its composition; when silicon nitride oxide is described, it refers to a material that contains more nitrogen than oxygen in its composition.

The insulating layer 125 can be formed by a sputtering method, a CVD method, a PLD method, or an ALD method. The insulating layer 125 is preferably formed by an ALD method achieving good coverage.

The insulating layer 127 provided over the insulating layer 125 has a function of filling the depressed portion of the insulating layer 125, which is formed between the adjacent light-emitting devices. In other words, the insulating layer 127 has an effect of improving the planarity of the surface over which the common electrode 115 is formed. An insulating layer containing an organic material can be suitably used for the insulating layer 127. As the insulating layer 127, an acrylic resin, a polyimide resin, an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins can be used, for example. Alternatively, for the insulating layer 127, polyvinyl alcohol (PVA), polyvinyl butyral, polyvinylpyrrolidone, polyethylene glycol, polyglycerin, pullulan, water-soluble cellulose, or an alcohol-soluble polyamide resin can be used. Alternatively, a photosensitive resin can be used for the insulating layer 127. A photoresist may be used for the photosensitive resin. As the photosensitive resin, a positive photosensitive material or a negative photosensitive material can be used.

The difference in level between the top surface of the insulating layer 127 and the top surface of any of the first organic layer 113a, the second organic layer 113b, and the third organic layer 113c is preferably less than or equal to 0.5 times, further preferably less than or equal to 0.3 times the thickness of the insulating layer 127, for example. As another example, the insulating layer 127 may be provided so that the top surface of any of the first organic layer 113a, the second organic layer 113b, and the third organic layer 113c is higher than the top surface of the insulating layer 127. As another example, the insulating layer 127 may be provided so that the top surface of the insulating layer 127 is higher than the top surface of the light-emitting layer included in the first organic layer 113a, the second organic layer 113b, or the third organic layer 113c.

Insulating layers 131 and 132 are preferably provided over the light-emitting devices 130a, 130b, and 130c. Providing the insulating layers 131 and 132 can improve the reliability of the light-emitting devices.

There is no limitation on the conductivity of the insulating layers 131 and 132. As the insulating layers 131 and 132, at least one of an insulating film, a semiconductor film, and a conductive film can be used.

The insulating layers 131 and 132 including inorganic films prevent oxidation of the common electrode 115. The insulating layers 131 and 132 including inorganic films inhibit entry of impurities (e.g., moisture and oxygen) into the light-emitting devices 130a, 130b, and 130c. The insulating layers 131 and 132 including inorganic films can inhibit deterioration of the light-emitting devices and improve the reliability of the display regions.

As the insulating layers 131 and 132, an inorganic insulating film, for example, an oxide insulating film, a nitride insulating film, an oxynitride insulating film, or a nitride oxide insulating film can be used. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

Each of the insulating layers 131 and 132 preferably includes a nitride insulating film or a nitride oxide insulating film, and further preferably includes a nitride insulating film

As the insulating layers 131 and 132, an inorganic film containing In—Sn oxide (also referred to as ITO), In—Zn oxide, Ga—Zn oxide, Al—Zn oxide, or indium gallium zinc oxide (In—Ga—Zn oxide, also referred to as IGZO) can also be used. The inorganic film preferably has high resistance, specifically, higher resistance than the common electrode 115. The inorganic film may further contain nitrogen.

When light emitted from the light-emitting device is extracted through the insulating layers 131 and 132, the insulating layers 131 and 132 preferably have a high visible-light-transmitting property. For example, ITO, IGZO, and aluminum oxide are preferable because they are inorganic materials having a high visible-light-transmitting property.

The insulating layers 131 and 132 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layers.

Furthermore, the insulating layers 131 and 132 may include an organic film. For example, the insulating layer 132 may include both an organic film and an inorganic film.

The insulating layer 131 and the insulating layer 132 may be formed by different deposition methods. Specifically, the insulating layer 131 is formed by an atomic layer deposition (ALD) method and the insulating layer 132 may be formed by a sputtering method.

End portions of top surfaces of the pixel electrodes 111a, 111b, and 111c are not covered with the insulating layer. This allows the distance between the adjacent light-emitting devices to be extremely narrowed. Accordingly, the display region can have high resolution or high definition.

In the display region 100 of this embodiment, the distance between the light-emitting devices can be narrowed. Specifically, the distance between the light-emitting devices, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, a region is provided, in which the distance between the side surface of the first organic layer 113a and the side surface of the second organic layer 113b or the distance between the side surface of the second organic layer 113b and the side surface of the third organic layer 113c is less than or equal to 1 μm, preferably less than or equal to 0.5 μm (500 nm), further preferably less than or equal to 100 nm.

A light-blocking layer may be provided on the surface of the substrate 120 on the resin layer 122 side. A variety of optical members can be arranged on the outer surface of the substrate 120. Examples of the optical members include a polarizing plate, a retardation plate, a light diffusion layer (a diffusion film), an anti-reflective layer, and a light-condensing film. Furthermore, an antistatic film preventing the attachment of dust, a water repellent film suppressing the attachment of stain, a hard coat film suppressing generation of a scratch caused by the use, or an impact-absorbing layer may be provided on the outer surface of the substrate 120.

For the substrate 120, any of the following can be used: polyester resins typified by polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 120.

In the case where a circularly polarizing plate overlaps with the display region, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic resin film.

When a film is used for the substrate and the film absorbs water, creases might be generated in the display panel. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

As the resin layer 122, an ultraviolet curable adhesive, a reactive curable adhesive, a thermosetting adhesive, or an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, typified by an epoxy resin, is preferred. A two-liquid-mixture-type resin may be used. An adhesive sheet may be used.

As materials that can be used for a gate, a source, and a drain of a transistor and a variety of wirings and electrodes included in a display panel, aluminum, titanium, chromium, nickel, copper, yttrium, zirconium, molybdenum, silver, tantalum, and tungsten, and an alloy containing any of these metals as its main component can be given. A single-layer structure or a stacked-layer structure including a film containing any of these materials can be used.

As a light-transmitting conductive material, a conductive oxide, for example, indium oxide, indium tin oxide, indium zinc oxide, zinc oxide, or zinc oxide containing gallium, or graphene can be used. Alternatively, gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) may be used. Note that in the case of using the metal material or the alloy material (or the nitride thereof), the material is made thin enough to have a light-transmitting property. Furthermore, a stacked film of the above materials can be used for a conductive layer. For example, a stacked film of indium tin oxide and an alloy of silver and magnesium is preferably used, in which case the conductivity can be increased. They can also be used for conductive layers such as wirings and electrodes included in the display panel, and conductive layers (e.g., a conductive layer functioning as a pixel electrode or a common electrode) included in a light-emitting device.

Examples of insulating materials that can be used for each insulating layer include an acrylic resin and an epoxy resin and inorganic insulating materials such as silicon oxide, silicon oxynitride, silicon nitride oxide, silicon nitride, and aluminum oxide.

### [Pixel Layout]

Next, pixel layouts different from that in FIG. 6A will be described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons typified by a triangle, a tetragon (including a rectangle and a square), and a pentagon, polygons with rounded corners, an ellipse; and a circle. Here, the top surface shape of the subpixel corresponds to the top surface shape of a light-emitting region of the light-emitting device.

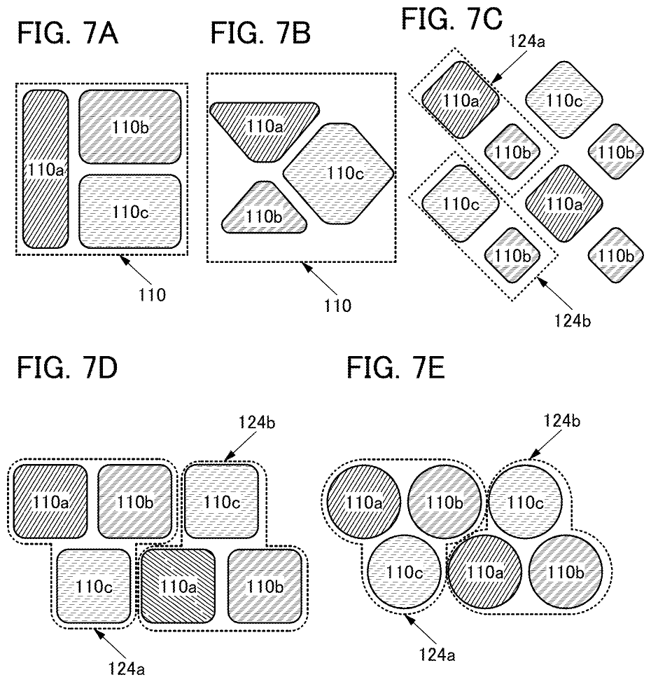

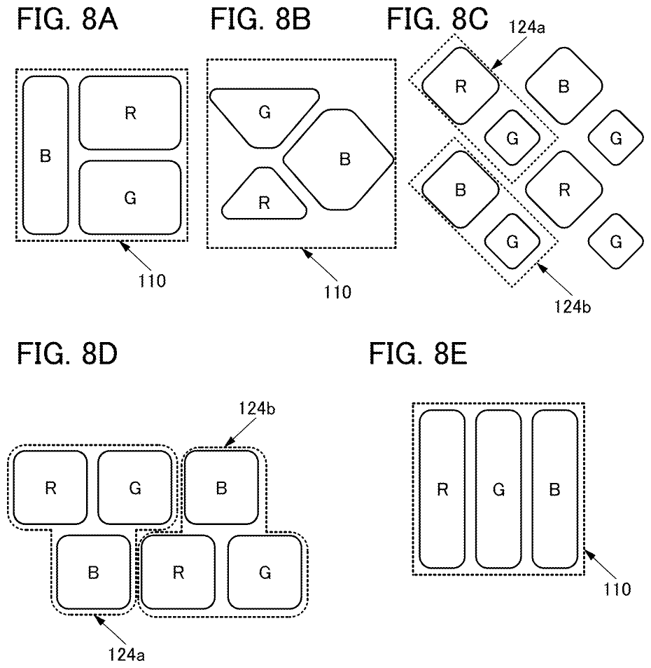

The pixel 110 illustrated in FIG. 7A employs S-stripe arrangement. The pixel 110 illustrated in FIG. 7A consists of three subpixels 110a, 110b, and 110c. For example, as illustrated in FIG. 8A, the subpixel 110a may be a blue subpixel B, the subpixel 110b may be a red subpixel R, and the subpixel 110c may be a green subpixel G.

The pixel 110 illustrated in FIG. 7B includes the subpixel 110a whose top surface shape is a rough trapezoid with rounded corners, the subpixel 110b whose top surface shape is a rough triangle with rounded corners, and the subpixel 110c whose top surface shape is a rough tetragon or rough hexagon with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 8B, the subpixel 110a may be a green subpixel G, the subpixel 110b may be a red subpixel R, and the subpixel 110c may be a blue subpixel B.

Pixels 124a and 124b illustrated in FIG. 7C employ PenTile arrangement. FIG. 7C illustrates an example where the pixels 124a including the subpixel 110a and the subpixel 110b and the pixels 124b including the subpixel 110b and the subpixel 110c are alternately arranged. For example, as illustrated in FIG. 8C, the subpixel 110a may be a red subpixel R, the subpixel 110b may be a green subpixel G, and the subpixel 110c may be a blue subpixel B.

The pixels 124a and 124b illustrated in FIG. 7D and FIG. 7E employ delta arrangement. The pixel 124a includes two subpixels (the subpixel 110a and the subpixel 110b) in the upper row (first row) and one subpixel (the subpixel 110c) in the lower row (second row). The pixel 124b includes one subpixel (the subpixel 110c) in the upper row (first row) and two subpixels (the subpixel 110a and the subpixel 110b) in the lower row (second row). For example, as illustrated in FIG. 8D, the subpixel 110a may be a red subpixel R, the subpixel 110b may be a green subpixel G, and the subpixel 110c may be a blue subpixel B.

FIG. 7D illustrates an example where a top surface shape of each subpixel is a rough tetragon with rounded corners, and FIG. 7E illustrates an example where a top surface shape of each subpixel is a circle.

In a photolithography method, as a pattern to be processed becomes finer, the influence of light diffraction becomes more difficult to ignore; thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a top surface shape of a subpixel becomes a polygon with rounded corners, an ellipse, or a circle in some cases.

Furthermore, in the manufacturing method of the display panel of one embodiment of the present invention, the light-emitting unit or the like including the EL layer is processed to into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape at the time of processing. As a result, a top surface shape of the EL layer becomes a polygon with rounded corners, an ellipse, or a circle in some cases. For example, when a resist mask whose top surface shape is a square is intended to be formed, a resist mask whose top surface shape is a circle may be formed, and the top surface shape of the EL layer may be a circle.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion of a figure on a mask pattern.

Also in the pixel 110 illustrated in FIG. 6A, which employs stripe arrangement, the subpixel 110a may be a red subpixel R, the subpixel 110b may be a green subpixel G, and the subpixel 110c may be a blue subpixel B as illustrated in FIG. 8E, for example.

In one embodiment of the present invention, an organic EL device is used as a light-emitting device.

In the display region 100 of one embodiment of the present invention, light-emitting devices are arranged in a matrix in a pixel portion, and an image can be displayed on the pixel portion.

The refresh rate of the display region 100 of one embodiment of the present invention can be variable. For example, the refresh rate is adjusted (in the range from 0.1 Hz to 240 Hz, for example) in accordance with contents displayed on the display region 100, whereby power consumption can be reduced.

### Embodiment 4

In this embodiment, structure examples and application examples of a stacked-layer panel that is one embodiment of a display panel that can easily have a larger size are described with reference to drawings.

One embodiment of the present invention is a display panel capable of increasing its size by arranging a plurality of display panels to partly overlap one another. In two of the overlapping display panels, at least a display panel positioned on the display surface side (upper side) includes a region transmitting visible light that is adjacent to a display portion. A pixel of a display panel positioned on the lower side and the region transmitting visible light of the display panel positioned on the upper side are provided to overlap with each other. Thus, the two of the overlapping display panels can display a seamless and contiguous image when seen from the display surface side (in a plan view).

For example, one embodiment of the present invention is a stacked-layer panel including a first display panel and a second display panel. The first display panel includes a first region, and the first region includes a first pixel and a second pixel. The second display panel includes a second region, a third region, and a fourth region. The second region includes a third pixel. The third region has a function of transmitting visible light. The fourth region has a function of blocking visible light. The second pixel of the first display panel and the third region of the second display panel have a region where they overlap with each other. The aperture ratio of the second pixel is preferably higher than the aperture ratio of the first pixel.

For one or both of the first display panel and the second display panel, the display apparatus described above as an example, which includes a light-emitting device and a light-receiving device, can be used. In other words, at least one of the first pixel, the second pixel, and the third pixel includes a light-emitting device and a light-receiving device.

Specifically, the following structure can be employed, for example.

### Structure Example 1

### [Display Panel]

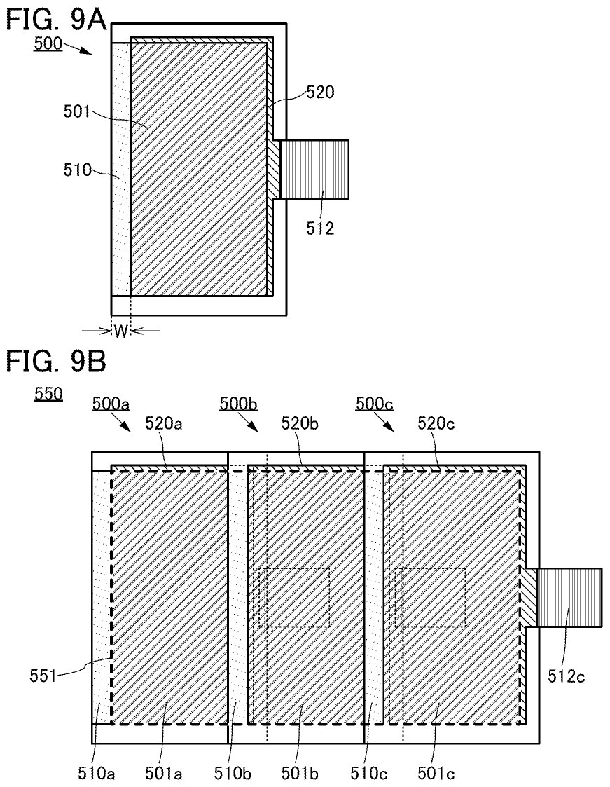

FIG. 9A is a schematic top view of a display panel 500 included in a display apparatus of one embodiment of the present invention. Note that although an example in which the display panel 500 has a rectangular shape is illustrated for easy understanding, the display panel can have a non-rectangular shape, depending on the design of a practitioner, as in the example that is illustrated in FIG. 5 and described in Embodiment 2. For example, a display region is designed to have the shape illustrated in FIG. 5A and is formed over a flexible rectangular substrate, and then the flexible rectangular substrate is partly cut and taken out, whereby the display region 63 illustrated in FIG. 5A can be formed. Similarly, a display region is designed to have the shape illustrated in FIG. 1B and is formed, and then a flexible rectangular substrate is partly cut and taken out, whereby the display region 63 illustrated in FIG. 1B can be formed.

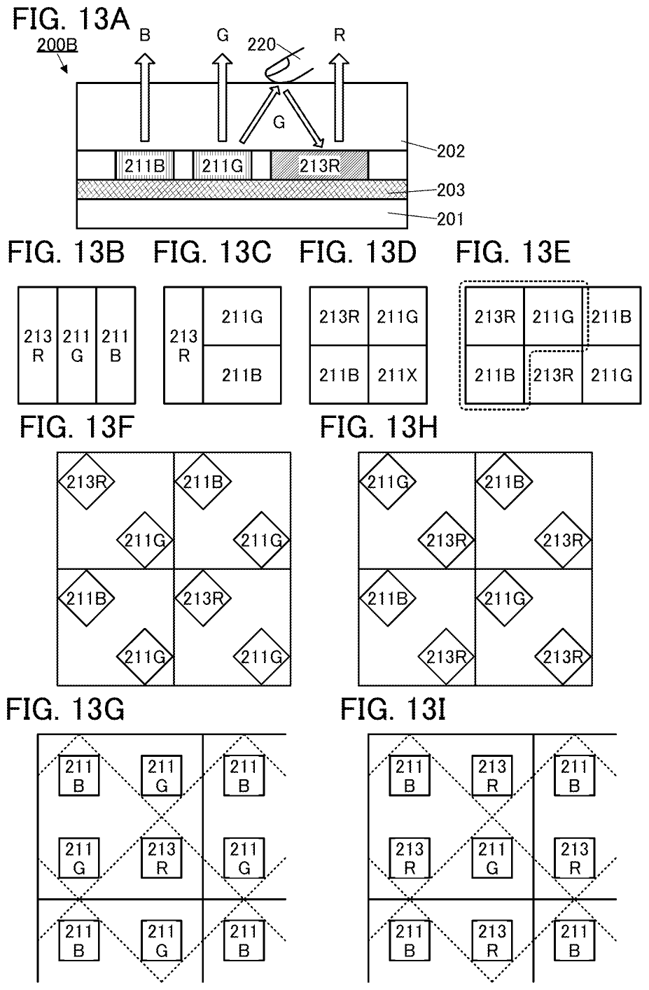

The display panel 500 includes a display region 501, and a region 510 transmitting visible light and a region 520 having a portion blocking visible light that are adjacent to the display region 501. FIG. 13A illustrates an example in which the display panel 500 is provided with an FPC (Flexible Printed Circuit) 512.

Here, an image can be displayed on the display region 501 even when the display panel 500 is used independently. Moreover, an image can be captured by the display region 501 even when the display panel 500 is used independently.

In the region 510, for example, a pair of substrates included in the display panel 500, a sealant for sealing the display device interposed between the pair of substrates may be provided. Here, for a member provided in the region 510, a material with a visible-light-transmitting property is used.

In the region 520, for example, a wiring electrically connected to pixels included in the display region 501 is provided. In addition to such a wiring, driver circuits (e.g., a scan line driver circuit and a signal line driver circuit) for driving the pixels or a protective circuit may be provided. Furthermore, the region 520 includes a region where a terminal electrically connected to the FPC 512 (also referred to as a connection terminal) or a wiring electrically connected to the terminal is provided.

For specific description of a cross-sectional structure example of the display panel, the other embodiments can be referred to.

### [Stacked-Layer Panel]

A stacked-layer panel 550 of one embodiment of the present invention includes a plurality of display panels 500 described above. FIG. 9B is a schematic top view of the stacked-layer panel 550 including three display panels.

Hereinafter, to distinguish display panels from each other, components included in the display panels from each other, or components relating to the display panels from each other, letters are added to reference numerals of them. Unless otherwise specified, “a” is appended to a reference numeral of a display panel of a plurality of display panels partly overlapping with each other, which is positioned on the lowest side (the side opposite to the display surface) and components thereof, and alphabetical letters are appended in alphabetical order to a reference numeral/reference numerals of one or more display panels positioned thereover and components thereof. Furthermore, unless otherwise specified, even in describing a structure that includes a plurality of display panels, matters common to the display panels or components thereof are described without alphabetical letters.

The stacked-layer panel 550 illustrated in FIG. 9B includes a display panel 500a, a display panel 500b, and a display panel 500c.

The display panel 500b is placed so that part of the display panel 500b is stacked over an upper side (a display surface side) of the display panel 500a. Specifically, the display panel 500b is placed so that a display region 501a of the display panel 500a and a region 510b transmitting visible light of the display panel 500b overlap with each other and the display region 501a of the display panel 500a and a region 520b blocking visible light of the display panel 500b do not overlap with each other.

Similarly, the display panel 500c is placed so as to partly overlap with an upper side (display surface side) of the display panel 500b. Specifically, the display panel 500c is placed so that a display region 501b of the display panel 500b and a region 510c transmitting visible light of the display panel 500c overlap with each other and the display region 501b of the display panel 500b and a region 520c blocking visible light of the display panel 500c do not overlap with each other.

The region 510b transmitting visible light overlaps with the display region 501a; thus, the whole display region 501a can be visually recognized from the display surface side. Similarly, the whole display region 501b can also be visually recognized from the display surface side when the region 510c overlaps with the display region 501b. Therefore, a region where the display region 501a, the display region 501b, and a display region 501c are placed seamlessly can serve as a display region 551 of the stacked-layer panel 550.

The display region 551 of the stacked-layer panel 550 can be enlarged by the number of display panels 500. Here, by using display panels each having an image capturing function (i.e., display panels each including a light-emitting device and a light-receiving device) as all the display panels 500, the entire display region 551 can serve as an imaging region.

Note that without limitation to the above, a display panel having an image capturing function and a display panel not having an image capturing function (e.g., a display panel having no light-receiving device) may be combined. For example, a display panel having an image capturing function can be used only where needed, and a display panel not having an image capturing function can be used in other portions.

### Structure Example 2

In FIG. 9B, the plurality of display panels 500 overlap with each other in one direction; however, the plurality of display panels 500 may overlap with each other in two directions of the vertical and horizontal directions.

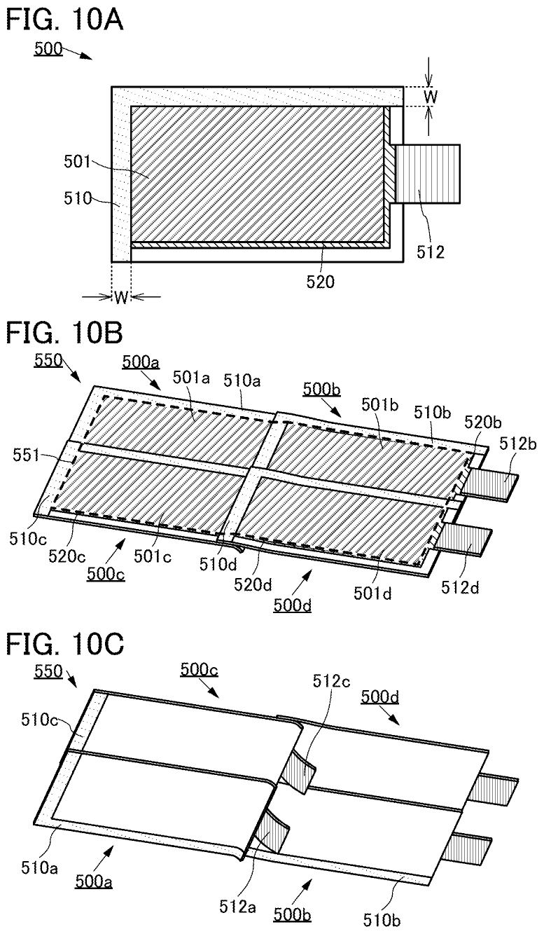

FIG. 10A illustrates an example of the display panel 500 that differs from that in FIG. 9A in the shape of the region 510. In the display panel 500 illustrated in FIG. 10A, the region 510 transmitting visible light is positioned along two sides of the display region 501.

FIG. 10B is a schematic perspective view of the stacked-layer panel 550 in which the display panels 500 illustrated in FIG. 10A are arranged two by two in the vertical and horizontal directions. FIG. 10C is a schematic perspective view of the stacked-layer panel 550 when seen from a side opposite to the display surface side.

In FIG. 10B and FIG. 10C, a region along a short side of the display region 501a of the display panel 500a overlaps with part of the region 510b of the display panel 500b. In addition, a region along a long side of the display region 501a of the display panel 500a overlaps with part of the region 510c of the display panel 500c. Moreover, a region 510d of a display panel 500d overlaps with a region along a long side of the display region 501b of the display panel 500b and a region along a short side of the display region 501c of the display panel 500c.

Therefore, as illustrated in FIG. 10B, a region where the display region 501a, the display region 501b, the display region 501c, and the display region 501d are arranged seamlessly can serve as the display region 551 of the stacked-layer panel 550.

Here, it is preferable that a flexible material be used for the pair of substrates included in the display panel 500 and the display panel 500 have flexibility. In that case, as in the display panel 500a in FIG. 10B and FIG. 10C, for example, when an FPC 512a is provided on the display surface side, part of the display panel 500a on the side where the FPC 512a is provided is curved, whereby the FPC 512a can be placed under the display region 501b of the adjacent display panel 500b so as to overlap with the display region 501b. As a result, the FPC 512a can be placed without physical interference with the rear surface of the display panel 500b. Furthermore, when the display panel 500a and the display panel 500b overlap with and are bonded to each other, it is not necessary to consider the thickness of the FPC 512a; thus, a difference in height between the top surface of the region 510b of the display panel 500b and the top surface of the display region 501a of the display panel 500a can be reduced. As a result, it is possible to prevent an end portion of the display panel 500b over the display region 501a from being visible.

Moreover, each display panel 500 is made flexible, whereby the display panel 500b can be curved gently so that the level of the top surface of the display region 501b of the display panel 500b is the same as the level of the top surface of the display region 501a of the display panel 500a. Thus, the display regions can have the same height except in the vicinity of a region where the display panel 500a and the display panel 500b overlap with each other, and the display quality of an image displayed on the display region 551 of the stacked-layer panel 550 can be improved.

Although the relation between the display panel 500a and the display panel 500b is taken as an example in the above description, the same applies to the relation between any other two adjacent display panels.

To reduce the step between two adjacent display panels 500, the thickness of the display panel 500 is preferably small. For example, the thickness of the display panel 500 is preferably less than or equal to 1 mm, further preferably less than or equal to 300 μm, still further preferably less than or equal to 100 μm.

A substrate for protecting the display region 551 of the stacked-layer panel 550 may be provided. In that case, the substrate may be provided for each display panel, or one substrate may be provided for a plurality of display panels.

Note that although the structure where the four rectangular display panels 500 are stacked is described here, an extremely large stacked-layer panel can be obtained by increasing the number of display panels 500. By changing a method for arranging the plurality of display panels 500, the shape of the contour of the display region of the stacked-layer panel can be a non-rectangular shape, for example, a circular shape, an elliptical shape, or a polygonal shape. By arranging the display panels 500 three-dimensionally, a stacked-layer panel including display regions with a three-dimensional shape, for example, a circular cylindrical shape, a spherical shape, or a hemispherical shape can be obtained.

At least part of this embodiment can be implemented in combination with the other embodiments described in this specification as appropriate.

### Embodiment 5

In this embodiment, a light-emitting and light-receiving apparatus of one embodiment of the present invention will be described.

A light-emitting and light-receiving portion of the light-emitting and light-receiving apparatus of one embodiment of the present invention includes a light-receiving device and a light-emitting device. The light-emitting and light-receiving portion has a function of displaying an image with the use of the light-emitting device. Furthermore, the light-emitting and light-receiving portion has one or both of a function of capturing an image with the use of the light-receiving device and a sensing function. Thus, the light-emitting and light-receiving apparatus of one embodiment of the present invention can also be referred to as a display apparatus, and the light-emitting and light-receiving portion can also be referred to as a display portion.

Alternatively, the light-emitting and light-receiving apparatus of one embodiment of the present invention may have a structure including a light-emitting and light-receiving device and a light-emitting device.

First, the light-emitting and light-receiving apparatus that includes a light-receiving device and a light-emitting device is described.

The light-emitting and light-receiving apparatus of one embodiment of the present invention includes a light-receiving device and a light-emitting device in a light-emitting and light-receiving portion. In the light-emitting and light-receiving apparatus of one embodiment of the present invention, the light-emitting devices are arranged in a matrix in the light-emitting and light-receiving portion, and an image can be displayed on the light-emitting and light-receiving portion. Furthermore, the light-receiving devices are arranged in a matrix in the light-emitting and light-receiving portion, and the light-emitting and light-receiving portion has one or both of an image capturing function and a sensing function. The light-emitting and light-receiving portion can be used as an image sensor or a touch sensor. That is, light is detected in the light-emitting and light-receiving portion, whereby an image can be captured and touch operation of an object (e.g., a finger or a stylus) can be detected. Furthermore, in the light-emitting and light-receiving apparatus of one embodiment of the present invention, the light-emitting devices can be used as a light source of the sensor. Accordingly, a light-receiving portion and a light source do not need to be provided separately from the light-emitting and light-receiving apparatus; hence, the number of components of an electronic device can be reduced.

In the light-emitting and light-receiving apparatus of one embodiment of the present invention, when an object reflects (or scatters) light emitted from the light-emitting device included in the light-emitting and light-receiving portion, the light-receiving device can detect the reflected light (or the scattered light); thus, image capturing and touch operation sensing are possible even in a dark place.

The light-emitting device included in the light-emitting and light-receiving apparatus of one embodiment of the present invention functions as a display device.

As the light-emitting device, EL devices typified by an OLED and a QLED are preferably used. Examples of a light-emitting substance contained in the EL device include a substance exhibiting fluorescence (a fluorescent material), a substance exhibiting phosphorescence (a phosphorescent material), an inorganic compound (a quantum dot material), and a substance exhibiting thermally activated delayed fluorescence (a thermally activated delayed fluorescence (TADF) material). A micro-LED can also be used as the light-emitting device.

The light-emitting and light-receiving apparatus of one embodiment of the present invention has a function of sensing light with the use of the light-receiving device.

In the case where the light-receiving device is used as the image sensor, the light-emitting and light-receiving apparatus can capture an image with the use of the light-receiving device. For example, the light-emitting and light-receiving apparatus can be used as a scanner.

An electronic device including the light-emitting and light-receiving apparatus of one embodiment of the present invention can obtain data related to biological information such as a fingerprint or a palm print by using a function of an image sensor. That is, a biometric authentication sensor can be incorporated in the light-emitting and light-receiving apparatus. When the light-emitting and light-receiving apparatus incorporates a biometric authentication sensor, the number of components of an electronic device can be reduced as compared to the case where a biometric authentication sensor is provided separately from the light-emitting and light-receiving apparatus; thus, the size and weight of the electronic device can be reduced.

When the light-receiving device is used as a touch sensor, the light-emitting and light-receiving apparatus can detect touch operation of an object with the use of the light-receiving device.

For example, a pn or pin photodiode can be used as the light-receiving device. The light-receiving device functions as a photoelectric conversion device that detects light entering the light-receiving device and generates electric charge. The amount of electric charge generated from the light-receiving devices depend on the amount of light entering the light-receiving device.

It is particularly preferable to use an organic photodiode including a layer containing an organic compound as the light-receiving device. An organic photodiode, which is easily made thin, lightweight, and large in area and has a high degree of flexibility in shape and design, can be used in a variety of apparatuses.

In one embodiment of the present invention, an organic EL device is used as the light-emitting device, and an organic photodiode is used as the light-receiving devices. The organic EL device and the organic photodiode can be formed over the same substrate. Thus, the organic photodiode can be incorporated in the display apparatus including the organic EL device.

In the case where all the layers of the organic EL elements and the organic photodiodes are formed separately, the number of deposition steps is extremely large. However, a large number of layers of the organic photodiodes can have a structure in common with the organic EL devices; thus, concurrently forming the layers that can have a common structure can inhibit an increase in the number of deposition steps.

For example, one of a pair of electrodes (a common electrode) can be a layer shared by the light-receiving device and the light-emitting device. As another example, at least one of a hole-injection layer, a hole-transport layer, an electron-transport layer, and an electron-injection layer is may be shared by the light-receiving device and the light-emitting device. When the light-receiving device and the light-emitting device include a common layer in such a manner, the number of deposition steps and the number of masks can be reduced, thereby reducing the number of manufacturing steps and the manufacturing cost of the light-emitting and light-receiving apparatus. Furthermore, the light-emitting and light-receiving apparatus including the light-receiving device can be manufactured using an existing manufacturing apparatus and an existing manufacturing method for the display apparatus.

Next, a light-emitting and light-receiving apparatus including a light-emitting and light-receiving device and a light-emitting device is described. Note that functions, behavior, and effects similar to those in the above are not described in some cases.

In the light-emitting and light-receiving apparatus of one embodiment of the present invention, a subpixel exhibiting any color includes a light-emitting and light-receiving device instead of a light-emitting device, and subpixels exhibiting the other colors each include a light-emitting device. The light-emitting and light-receiving device has both a function of emitting light (a light-emitting function) and a function of receiving light (a light-receiving function). For example, in the case where a pixel includes three subpixels of red, green, and blue, at least one of the subpixels includes a light-emitting and light-receiving device and the other subpixels each include a light-emitting device. Thus, the light-emitting and light-receiving portion of the light-emitting and light-receiving apparatus of one embodiment of the present invention has a function of displaying an image using both a light-emitting and light-receiving device and a light-emitting device.

The light-emitting and light-receiving device functions as both a light-emitting device and a light-receiving device, whereby the pixel can have a light-receiving function without an increase in the number of subpixels included in the pixel. Thus, the light-emitting and light-receiving portion of the light-emitting and light-receiving apparatus can be provided with one or both of an image capturing function and a sensing function while keeping the aperture ratio of the pixel (aperture ratio of each subpixel) and the resolution of the light-emitting and light-receiving apparatus. Accordingly, in the light-emitting and light-receiving apparatus of one embodiment of the present invention, the pixel aperture ratio can be more increased and the resolution can be increased more easily than in the case where a subpixel including a light-receiving device is provided separately from a subpixel including a light-emitting device.

In the light-emitting and light-receiving portion of the light-emitting and light-receiving apparatus of one embodiment of the present invention, the light-emitting and light-receiving devices and the light-emitting devices are arranged in a matrix, and an image can be displayed on the light-emitting and light-receiving portion. The light-emitting and light-receiving portion can be used as an image sensor or a touch sensor. In the light-emitting and light-receiving apparatus of one embodiment of the present invention, the light-emitting device can be used as a light source of the sensor. Thus, image capturing or touch operation sensing are possible even in a dark place.

The light-emitting and light-receiving device can be manufactured by combining an organic EL device and an organic photodiode. For example, by adding an active layer of an organic photodiode to a stacked-layer structure of an organic EL device, the light-emitting and light-receiving device can be manufactured. Furthermore, in the light-emitting and light-receiving device manufactured by combining an organic EL device and an organic photodiode, concurrently forming layers that can be shared with the organic EL device can inhibit an increase in the number of deposition steps.

For example, one of a pair of electrodes (a common electrode) can be a layer shared by the light-emitting and light-receiving device and the light-emitting device. As another example, at least one of a hole-injection layer, a hole-transport layer, an electron-transport layer, and an electron-injection layer is preferably shared by the light-emitting and light-receiving device and the light-emitting device.

Note that a layer included in the light-emitting and light-receiving device might have a different function between the case where the light-emitting and light-receiving device functions as the light-receiving device and the case where the light-emitting and light-receiving device functions as the light-emitting device. In this specification, the name of a component is based on its function in the case where the light-emitting and light-receiving device functions as a light-emitting device.

The light-emitting and light-receiving apparatus of this embodiment has a function of displaying an image using the light-emitting device and the light-emitting and light-receiving device. That is, the light-emitting device and the light-emitting and light-receiving device function as display devices.

The light-emitting and light-receiving apparatus of this embodiment has a function of sensing light with the use of the light-emitting and light-receiving device. The light-emitting and light-receiving device can detect light having a shorter wavelength than light emitted from the light-emitting and light-receiving device itself.

When the light-emitting and light-receiving device is used as an image sensor, the light-emitting and light-receiving apparatus of this embodiment can capture an image with the use of the light-emitting and light-receiving device. When the light-emitting and light-receiving device is used as a touch sensor, the light-emitting and light-receiving apparatus of this embodiment can detect touch operation of an object with the use of the light-emitting and light-receiving device.

The light-emitting and light-receiving device functions as a photoelectric conversion device. The light-emitting and light-receiving device can be manufactured by adding an active layer of a light-receiving device to the above-described structure of the light-emitting device. For the light-emitting and light-receiving device, an active layer of a pn photodiode or a pin photodiode can be used, for example.

It is particularly preferable to use, for the light-emitting and light-receiving device, an active layer of an organic photodiode including a layer containing an organic compound. An organic photodiode, which is easily made thin, lightweight, and large in area and has a high degree of flexibility in shape and design, can be used in a variety of apparatuses.

The display apparatus that is an example of the light-emitting and light-receiving apparatus of one embodiment of the present invention will be specifically described below with reference to drawings.

### Structure Example 1 of Display Apparatus

### Structure Example 1-1

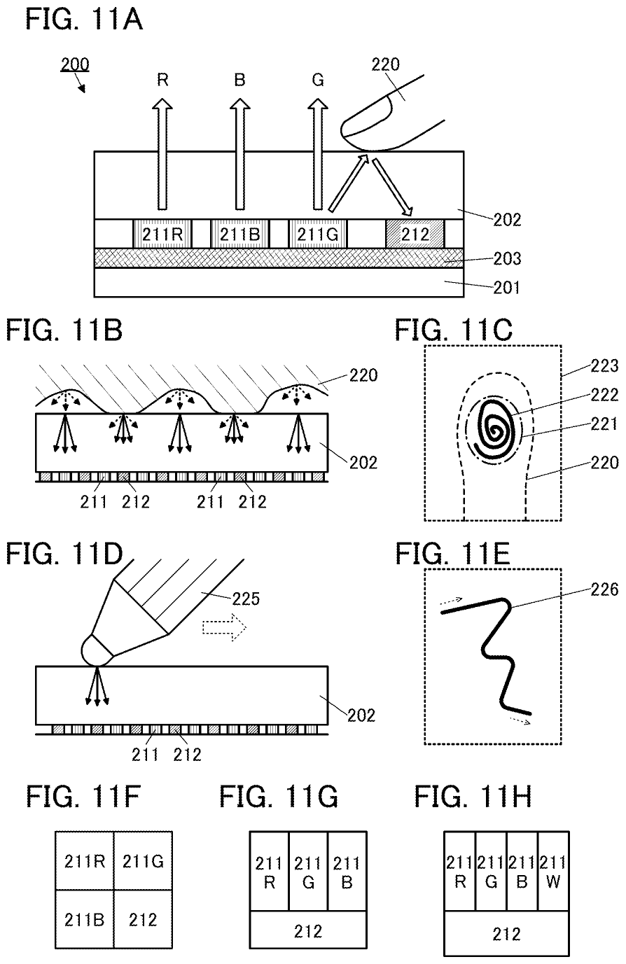

FIG. 11A is a schematic view of a display panel 200. The display panel 200 includes a substrate 201, a substrate 202, a light-receiving device 212, a light-emitting device 211R, a light-emitting device 211G, a light-emitting device 211B, and a functional layer 203.

The light-emitting device 211R, the light-emitting device 211G, the light-emitting device 211B, the light-receiving device 212 are provided between the substrate 201 and the substrate 202. The light-emitting device 211R, the light-emitting device 211G, and the light-emitting device 211B emit red (R) light, green (G) light, and blue (B) light, respectively. Note that in the following description, the term “light-emitting device 211” may be used when the light-emitting device 211R, the light-emitting device 211G, and the light-emitting device 211B are not distinguished from each other.

The display panel 200 includes a plurality of pixels arranged in a matrix. One pixel includes one or more subpixels. One subpixel includes one light-emitting device. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel also includes a light-receiving device 212. The light-receiving device 212 may be provided in all the pixels or in some of the pixels. In addition, one pixel may include a plurality of light-receiving devices 212.

FIG. 11A illustrates a finger 220 touching a surface of the substrate 202. Part of light emitted from the light-emitting device 211G is reflected by a contact portion between the substrate 202 and the finger 220. In the case where part of the reflected light is incident on the light-receiving device 212, the contact of the finger 220 with the substrate 202 can be detected. That is, the display panel 200 can function as a touch panel.

The functional layer 203 includes a circuit for driving the light-emitting device 211R, the light-emitting device 211G, and the light-emitting device 211B and a circuit for driving the light-receiving device 212. The functional layer 203 is provided with a switch, a transistor, a capacitor, and a wiring. Note that in the case where the light-emitting device 211R, the light-emitting device 211G, the light-emitting device 211B, and the light-receiving device 212 are driven by a passive matrix method, the switch and the transistor are not necessarily provided.

The display panel 200 preferably has a function of sensing a fingerprint of the finger 220. FIG. 11B schematically illustrates an enlarged view of the contact portion in a state where the finger 220 touches the substrate 202. FIG. 11B illustrates the light-emitting devices 211 and the light-receiving devices 212 that are alternately arranged.

The fingerprint of the finger 220 is formed of depressions and projections. Therefore, as illustrated in FIG. 11B, the projections of the fingerprint touch the substrate 202.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected on a contact surface or a non-contact surface between the finger 220 and the substrate 202 and is incident on the light-receiving device 212 positioned directly below the contact surface or the non-contact surface is the sum of intensities of regularly reflected light and diffusely reflected light. As described above, regularly reflected light (indicated by solid arrows) is dominant in the depressions of the finger 220 where the finger 220 does not touch the substrate 202, whereas diffusely reflected light (indicated by dashed arrows) from the finger 220 is dominant in the projections where the finger 220 touches the substrate 202. Thus, the intensity of light received by the light-receiving device 212 positioned directly below the depression is higher than the intensity of light received by the light-receiving device 212 positioned directly below the projection. Accordingly, an image of the fingerprint of the finger 220 can be captured.

In the case where an arrangement interval between the light-receiving devices 212 is smaller than a distance between two projections of a fingerprint, preferably a distance between a depression and a projection adjacent to each other, a clear fingerprint image can be obtained. The distance between a depression and a projection of a human's fingerprint is approximately 200 μm; thus, the arrangement interval between the light-receiving devices 212 is, for example, less than or equal to 400 μm, preferably less than or equal to 200 μm, further preferably less than or equal to 150 μm, still further preferably less than or equal to 100 μm, yet still further preferably less than or equal to 50 μm and greater than or equal to 1 μm, preferably greater than or equal to 10 μm, further preferably greater than or equal to 20 μm.

FIG. 11C illustrates an example of a fingerprint image captured by the display panel 200. In an image-capturing range 223 in FIG. 11C, the outline of the finger 220 is indicated by a dashed line and the outline of a contact portion 221 is indicated by a dashed-dotted line. In the contact portion 221, a high-contrast image of a fingerprint 222 can be captured owing to a difference in the amount of light incident on the light-receiving devices 212.

The display panel 200 can also function as a touch panel or a pen tablet. FIG. 11D illustrates a state where a tip of a stylus 225 slides in a direction indicated by a dashed arrow while the tip of the stylus 225 touches the substrate 202.

As illustrated in FIG. 11D, when diffusely reflected light that is diffused at the contact surface of the tip of the stylus 225 and the substrate 202 is incident on the light-receiving device 212 that overlaps with the contact surface, the position of the tip of the stylus 225 can be detected with high accuracy.

FIG. 11E illustrates an example of a path 226 of the stylus 225 that is detected by the display panel 200. The display panel 200 can detect the position of a sensing target, such as the stylus 225, with high position accuracy, so that high-definition drawing can be performed using a drawing application. Unlike the case of using a capacitive touch sensor or an electromagnetic induction touch pen, the display panel 200 can detect even the position of a highly insulating sensing target; hence, the material of a tip portion of the stylus 225 is not limited, and a variety of writing materials (e.g., a brush, a glass pen, and a quill pen) can be used.

Here, FIG. 11F to FIG. 11H illustrate examples of pixels that can be used in the display panel 200.

The pixels illustrated in FIG. 11F and FIG. 11G each include the light-emitting device 211R for red (R), the light-emitting device 211G for green (G), the light-emitting device 211B for blue (B), and the light-receiving device 212. The pixels each include a pixel circuit for driving the light-emitting device 211R, the light-emitting device 211G, the light-emitting device 211B, and the light-receiving device 212.

FIG. 11F illustrates an example in which three light-emitting devices and one light-receiving device are provided in a matrix of 2×2. FIG. 11G illustrates an example in which three light-emitting devices are arranged in a line and one laterally long light-receiving device 212 is provided thereunder.

The pixel illustrated in FIG. 11H is an example including a light-emitting device 211W for white (W). Here, four light-emitting devices are arranged in a line and the light-receiving device 212 is provided thereunder.

Note that the pixel structure is not limited to the above, and a variety of arrangement methods can be employed.

### Structure Example 1-2

An example of a structure that includes a light-emitting device emitting visible light, a light-emitting device emitting infrared light, and a light-receiving device will be described below.

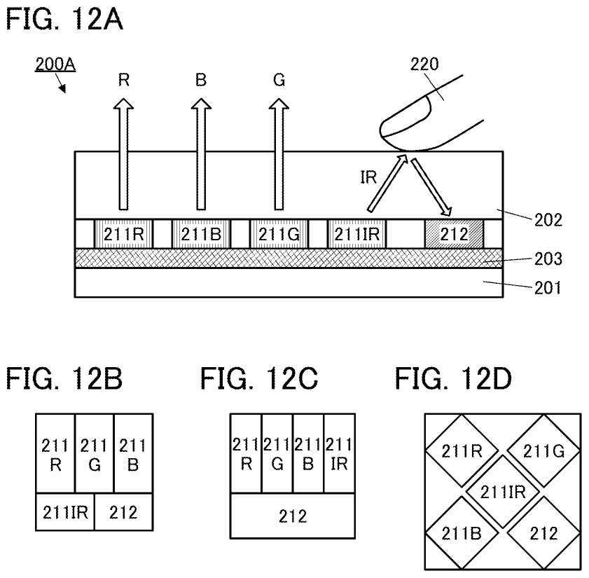

A display panel 200A illustrated in FIG. 12A includes a light-emitting device 211IR in addition to the components illustrated in FIG. 11A as an example. The light-emitting device 211IR is a light-emitting device emitting infrared light IR. In this case, a device that is capable of receiving at least the infrared light IR emitted from the light-emitting device 211IR is preferably used as the light-receiving device 212. As the light-receiving device 212, a device that is capable of receiving visible light and infrared light is further preferably used.

As illustrated in FIG. 12A, when the finger 220 touches the substrate 202, the infrared light IR emitted from the light-emitting device 211IR is reflected by the finger 220 and part of the reflected light is incident on the light-receiving device 212, so that the positional information of the finger 220 can be obtained.

FIG. 12B to FIG. 12D illustrate examples of pixels that can be used in the display panel 200A.

FIG. 12B illustrates an example in which three light-emitting devices are arranged in a line and the light-emitting device 211IR and the light-receiving device 212 are arranged side by side thereunder. FIG. 12C illustrates an example in which four light-emitting devices including the light-emitting device 211IR are arranged in a line and the light-receiving device 212 is provided thereunder.

FIG. 12D illustrates an example in which three light-emitting devices and the light-receiving device 212 are arranged in all directions around the light-emitting device 211IR.

Note that in the pixels illustrated in FIG. 12B to FIG. 12D, the positions of the light-emitting devices can be interchangeable, or the positions of the light-emitting device and the light-receiving device can be interchangeable.

### Structure Example 1-3

An example of a structure that includes a light-emitting device emitting visible light and a light-emitting and light-receiving device emitting and receiving visible light will be described below.

A display panel 200B illustrated in FIG. 13A includes the light-emitting device 211B, the light-emitting device 211G, and a light-emitting and light-receiving device 213R. The light-emitting and light-receiving device 213R has a function of a light-emitting device that emits red (R) light and a function of a photoelectric conversion device that receives visible light. FIG. 13A illustrates an example in which the light-emitting and light-receiving device 213R receives green (G) light emitted from the light-emitting device 211G. Note that the light-emitting and light-receiving device 213R may receive blue (B) light emitted from the light-emitting device 211B. Alternatively, the light-emitting and light-receiving device 213R may receive both green light and blue light.

For example, the light-emitting and light-receiving device 213R preferably receives light having a shorter wavelength than light emitted from itself. Alternatively, the light-emitting and light-receiving device 213R may receive light (e.g., infrared light) having a longer wavelength than light emitted from itself. The light-emitting and light-receiving device 213R may receive light having approximately the same wavelength as light emitted from itself; however, in that case, the light-emitting and light-receiving device 213R also receives light emitted from itself, whereby its emission efficiency might be decreased. Therefore, the peak of the emission spectrum and the peak of the absorption spectrum of the light-emitting and light-receiving device 213R preferably overlap as little as possible.

Here, light emitted from the light-emitting and light-receiving device is not limited to red light. Light emitted from the light-emitting device is not limited to a combination of green light and blue light. For example, the light-emitting and light-receiving device can be a device that emits green or blue light and receives light having a different wavelength from light emitted from itself.

The light-emitting and light-receiving device 213R serves as both a light-emitting device and a light-receiving device as described above, whereby the number of elements provided in one pixel can be reduced. Thus, higher definition, a higher aperture ratio, and higher resolution can be easily achieved.

FIG. 13B to FIG. 13I illustrate examples of pixels that can be used in the display panel 200B.

FIG. 13B illustrates an example in which the light-emitting and light-receiving device 213R, the light-emitting device 211G, and the light-emitting device 211B are arranged in a line column. FIG. 13C illustrates an example in which the light-emitting device 211G and the light-emitting device 211B are alternately arranged in the vertical direction and the light-emitting and light-receiving device 213R is provided alongside the light-emitting elements.

FIG. 13D illustrates an example in which three light-emitting devices (the light-emitting device 211G, the light-emitting device 211B, and a light-emitting device 211X) and one light-emitting and light-receiving device are arranged in matrix of 2×2. The light-emitting device 211X is a device that emits light of a color other than R, G, and B. Examples of light of a color other than R, G, and B include white (W) light, yellow (Y) light, cyan (C) light, magenta (M) light, infrared light (IR), and ultraviolet light (UV). In the case where the light-emitting device 211X emits infrared light, the light-emitting and light-receiving device preferably has a function of sensing infrared light or a function of sensing both visible light and infrared light. The wavelength of light that the light-emitting and light-receiving device detects can be determined depending on the application of a sensor.

FIG. 13E illustrates two pixels. A region that includes three devices and is enclosed by a dotted line corresponds to one pixel. The pixels each include the light-emitting device 211G, the light-emitting device 211B, and the light-emitting and light-receiving device 213R. In the left pixel illustrated in FIG. 13E, the light-emitting device 211G is provided in the same row as the light-emitting and light-receiving device 213R, and the light-emitting device 211B is provided in the same column as the light-emitting and light-receiving device 213R. In the right pixel illustrated in FIG. 13E, the light-emitting device 211G is provided in the same row as the light-emitting and light-receiving device 213R, and the light-emitting device 211B is provided in the same column as the light-emitting device 211G. In the pixel layout illustrated in FIG. 13E, the light-emitting and light-receiving device 213R, the light-emitting device 211G, and the light-emitting device 211B are repeatedly arranged in both the odd-numbered row and the even-numbered row, and in each column, the light-emitting devices or the light-emitting element and the light-emitting and light-receiving device arranged in the odd-numbered row and the even-numbered row emit light of different colors.

FIG. 13F illustrates four pixels that employ PenTile arrangement; adjacent two pixels have different combinations of light-emitting devices or a light-emitting device and a light-emitting and light-receiving device that emit light of two different colors. FIG. 13F illustrates a top-surface shape of the light-emitting device or light-emitting and light-receiving device.

The upper left pixel and the lower right pixel illustrated in FIG. 13F each include the light-emitting and light-receiving device 213R and the light-emitting device 211G. The upper right pixel and the lower left pixel each include the light-emitting device 211G and the light-emitting device 211B. That is, in the example illustrated in FIG. 13F, the light-emitting device 211G is provided in each pixel.

The top-surface shapes of the light-emitting device and the light-emitting and light-receiving device are not particularly limited and can be a circular shape, an elliptical shape, a polygonal shape, or a polygonal shape with rounded corners. FIG. 13F illustrates an example in which the top surface shapes of the light-emitting device and the light-emitting and light-receiving device are each a square tilted at approximately 45° (a diamond shape). Note that the top-surface shape of the light-emitting devices and the light-emitting and light-receiving devices may vary depending on the color thereof, or the light-emitting devices and the light-emitting and light-receiving devices of some colors or all colors may have the same top-surface shape.

The sizes of light-emitting regions (or light-emitting and light-receiving regions) of the light-emitting devices and the light-emitting and light-receiving devices may vary depending on the color thereof, or the light-emitting devices and the light-emitting and light-receiving devices of some colors or all colors may have light-emitting regions of the same size. For example, in FIG. 13F, the light-emitting region of the light-emitting device 211G provided in each pixel may have a smaller area than the light-emitting regions (or the light-emitting and light-receiving regions) of the other devices.

FIG. 13G is a modification example of the pixel arrangement illustrated in FIG. 13F. Specifically, the structure of FIG. 13G is obtained by rotating the structure of FIG. 13F by 45°. Although one pixel is regarded as including two devices in FIG. 13F, one pixel can be regarded as being formed of four devices as illustrated in FIG. 13G.

FIG. 13H is a modification example of the pixel arrangement illustrated in FIG. 13F. The upper left pixel and the lower right pixel illustrated in FIG. 13H each include the light-emitting and light-receiving device 213R and the light-emitting device 211G. The upper right pixel and the lower left pixel each include the light-emitting and light-receiving device 213R and the light-emitting device 211B. That is, in the example illustrated in FIG. 13H, the light-emitting and light-receiving device 213R is provided in each pixel. The structure illustrated in FIG. 13H enables higher-resolution image capturing than the structure illustrated in FIG. 13F because of including the light-emitting and light-receiving device 213R in each pixel. Thus, the accuracy of biometric authentication can be increased, for example.

FIG. 13I illustrates a modification example of the pixel arrangement illustrated in FIG. 13H, which is obtained by rotating the pixel arrangement illustrated in FIG. 13H by 45°.

In the description with reference to FIG. 13I, one pixel is regarded as being formed of four devices (two light-emitting devices and two light-emitting and light-receiving devices). The pixel including a plurality of light-emitting and light-receiving devices having a light-receiving function allows high-resolution image capturing. Accordingly, the accuracy of biometric authentication can be increased. For example, the resolution of image capturing can be the square root of 2 times the resolution of display.

A display apparatus that employs the structure illustrated in FIG. 13H or FIG. 13I includes p (p is an integer greater than or equal to 2) first light-emitting devices, q (q is an integer greater than or equal to 2) second light-emitting devices, and r (r is an integer greater than p and greater than q) light-emitting and light-receiving devices. As for p and r, r=2p is satisfied. As for p, q, and r, r=p+q is satisfied. Either the first light-emitting devices or the second light-emitting devices emit green light, and the other light-emitting devices emit blue light. The light-emitting and light-receiving devices emit red light and have a light-receiving function.

In the case where touch operation is detected with the light-emitting and light-receiving devices, for example, it is preferable that light emitted from a light source be less likely to be perceived by a user. Since blue light has lower visibility than green light, light-emitting devices that emit blue light are preferably used as a light source. Accordingly, the light-emitting and light-receiving devices preferably have a function of receiving blue light. Note that without limitation to the above, light-emitting devices used as a light source can be selected as appropriate depending on the sensitivity of the light-emitting and light-receiving devices.

As described above, the display apparatus of this embodiment can employ a variety of pixel arrangements.

At least part of this embodiment can be implemented in combination with the other embodiments described in this specification as appropriate.

### Embodiment 6

In this embodiment, a light-emitting device and a light-receiving device that can be used in a light-emitting and light-receiving apparatus of one embodiment of the present invention will be described.

### [Light-Emitting Device]

Light-emitting devices can be classified roughly into a single structure and a tandem structure. A device having a single structure includes one light-emitting unit between a pair of electrodes, and the light-emitting unit preferably includes one or more light-emitting layers. To obtain white light emission with a single structure, two or more light-emitting layers are selected such that emission colors of the light-emitting layers are complementary colors. For example, when the emission color of a first light-emitting layer and the emission color of a second light-emitting layer are complementary colors, the light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, a structure in which white light emission can be obtained by combining light from light-emitting layers of a plurality of light-emitting units is employed. Note that a combination of emission colors for obtaining white light emission is similar to that in the case of a single structure. In the device having a tandem structure, an intermediate layer, for example, a charge-generation layer is suitably provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

### Structure Example of Light-Emitting Device

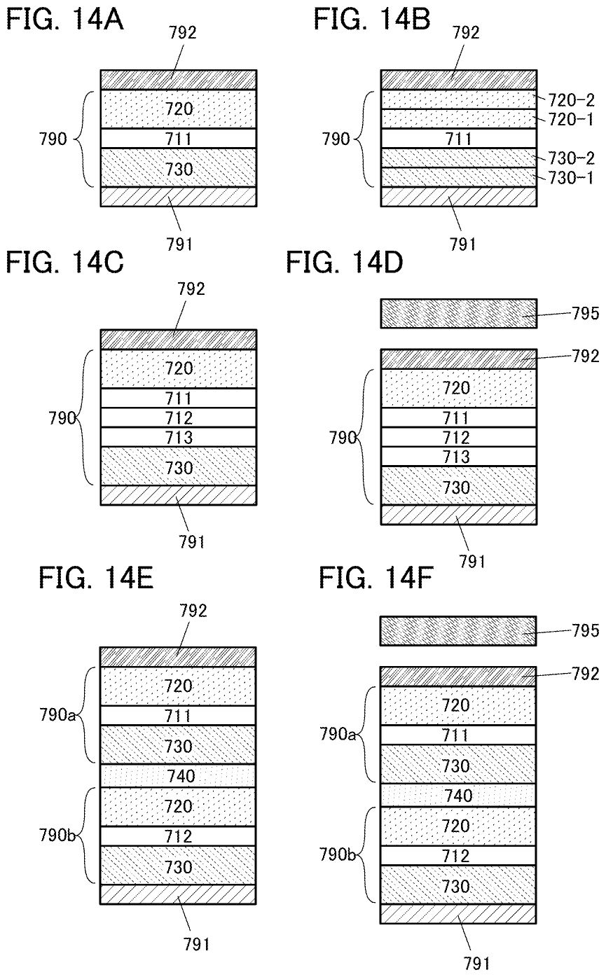

As illustrated in FIG. 14A, the light-emitting device includes an EL layer 790 between a pair of electrodes (a lower electrode 791 and an upper electrode 792). The EL layer 790 can be formed of a plurality of layers including a layer 720, a light-emitting layer 711, and a layer 730. The layer 720 can include, for example, a layer containing a substance with a high electron-injection property (an electron-injection layer) and a layer containing a substance with a high electron-transport property (an electron-transport layer). The light-emitting layer 711 contains a light-emitting compound, for example. The layer 730 can include, for example, a layer containing a substance with a high hole-injection property (a hole-injection layer) and a layer containing a substance with a high hole-transport property (a hole-transport layer).

The structure including the layer 720, the light-emitting layer 711, and the layer 730, which is provided between a pair of electrodes, can function as a single light-emitting unit, and the structure in FIG. 14A is referred to as a single structure in this specification.

FIG. 14B is a modification example of the EL layer 790 included in the light-emitting device illustrated in FIG. 14A. Specifically, the light-emitting device illustrated in FIG. 14B includes a layer 730-1 over the lower electrode 791, a layer 730-2 over the layer 730-1, the light-emitting layer 711 over the layer 730-2, a layer 720-1 over the light-emitting layer 711, a layer 720-2 over the layer 720-1, and the upper electrode 792 over the layer 720-2. For example, when the lower electrode 791 is an anode and the upper electrode 792 is a cathode, the layer 730-1 functions as a hole-injection layer, the layer 730-2 functions as a hole-transport layer, the layer 720-1 functions as an electron-transport layer, and the layer 720-2 functions as an electron-injection layer. Alternatively, when the lower electrode 791 is a cathode and the upper electrode 792 is an anode, the layer 730-1 functions as an electron-injection layer, the layer 730-2 functions as an electron-transport layer, the layer 720-1 functions as a hole-transport layer, and the layer 720-2 functions as a hole-injection layer. With such a layered structure, carriers can be efficiently injected to the light-emitting layer 711, and the efficiency of the recombination of carriers in the light-emitting layer 711 can be enhanced.

Note that structures in which a plurality of light-emitting layers (light-emitting layers 711, 712, and 713) are provided between the layer 720 and the layer 730 as illustrated in FIG. 14C and FIG. 14D are variations of the single structure.

Structures in which a plurality of light-emitting units (EL layer 790a and EL layer 790b) are connected in series with an intermediate layer (charge-generation layer) 740 therebetween as illustrated in FIG. 14E and FIG. 14F are referred to as a tandem structure in this specification. In this specification, the structures illustrated in FIG. 14E and FIG. 14F are referred to as a tandem structure; however, without being limited to this, a tandem structure may be referred to as a stack structure, for example. The tandem structure enables a light-emitting device capable of high-luminance light emission.

In FIG. 14C, light-emitting materials that emit light of the same color may be used for the light-emitting layer 711, the light-emitting layer 712, and the light-emitting layer 713.

Alternatively, different light-emitting materials may be used for the light-emitting layer 711, the light-emitting layer 712, and the light-emitting layer 713. White light can be obtained when the light-emitting layer 711, the light-emitting layer 712, and the light-emitting layer 713 emit light of complementary colors. FIG. 14D illustrates an example in which a coloring layer 795 functioning as a color filter is provided. When white light passes through the color filter, light of a desired color can be obtained.

In FIG. 14E, the same light-emitting material may be used for the light-emitting layer 711 and the light-emitting layer 712. Alternatively, light-emitting materials that emit light of different colors may be used for the light-emitting layer 711 and the light-emitting layer 712. White light can be obtained when the light-emitting layer 711 and the light-emitting layer 712 emit light of complementary colors. FIG. 14F illustrates an example in which the coloring layer 795 is further provided

In FIG. 14C, FIG. 14D, FIG. 14E, and FIG. 14F, the layer 720 and the layer 730 may each have a layered structure of two or more layers as illustrated in FIG. 14B.

In FIG. 14D, the same light-emitting material may be used for the light-emitting layer 711, the light-emitting layer 712, and the light-emitting layer 713. Similarly, in FIG. 14F, the same light-emitting material may be used for the light-emitting layer 711 and the light-emitting layer 712. In that case, by using a color conversion layer instead of the coloring layer 795, light of a desired color different from the emission color of the light-emitting material can be obtained. For example, a blue-light-emitting material is used for each light-emitting layer and blue light passes through the color conversion layer, whereby light with a wavelength longer than that of blue light (e.g., red light or green light) can be obtained. For the color conversion layer, a fluorescent material, a phosphorescent material, or quantum dots can be used.

A structure in which light-emitting devices that emit light of different colors (here, blue (B), green (G), and red (R)) are separately formed is referred to as an SBS (Side By Side) structure in some cases

The emission color of the light-emitting device can be red, green, blue, cyan, magenta, yellow, or white depending on the material of the EL layer 790. Furthermore, the color purity can be further increased when the light-emitting device has a microcavity structure.

The light-emitting device that emits white light preferably contains two or more kinds of light-emitting substances in the light-emitting layer. To obtain white light emission, two or more kinds of light-emitting substances are selected such that their emission colors are complementary. For example, when emission colors of a first light-emitting layer and a second light-emitting layer are complementary colors, the light-emitting device as a whole can be configured to emit white light. The same applies to a light-emitting device including three or more light-emitting layers.

The light-emitting layer preferably contains two or more selected from light-emitting substances that emit light of red (R), green (G), blue (B), yellow (Y), and orange (O). Alternatively, the light-emitting layer preferably contains two or more light-emitting substances that emit light containing two or more of spectral components of R, G, and B.

### [Light-Receiving Device]

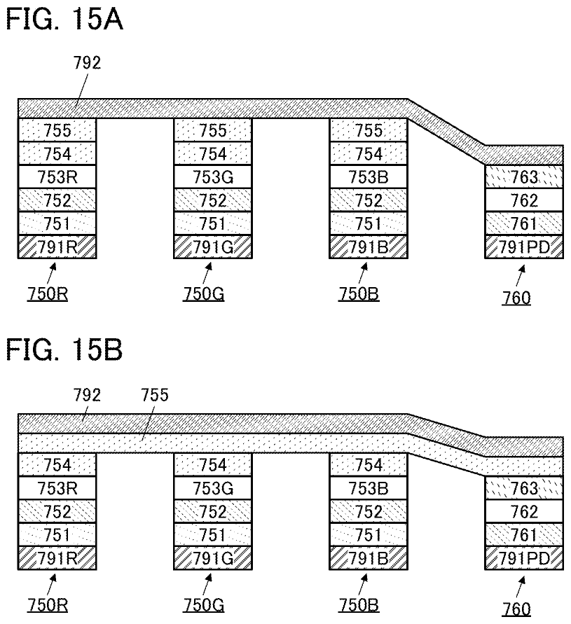

FIG. 15A is a schematic cross-sectional view of a light-emitting device 750R, a light-emitting device 750G, a light-emitting device 750B, and a light-receiving device 760. The light-emitting device 750R, the light-emitting device 750G, the light-emitting device 750B, and the light-receiving device 760 share an upper electrode 792.

The light-emitting device 750R includes a pixel electrode 791R, a layer 751, a layer 752, a light-emitting layer 753R, a layer 754, a layer 755, and the upper electrode 792. The light-emitting device 750G includes the pixel electrode 791G and a light-emitting layer 753G. The light-emitting device 750B includes the pixel electrode 791B and a light-emitting layer 753B.

The layer 751 includes, for example, a layer containing a substance with a high hole-injection property (a hole-injection layer). The layer 752 includes, for example, a layer containing a substance with a high hole-transport property (a hole-transport layer). The layer 754 includes, for example, a layer containing a substance with a high electron-transport property (an electron-transport layer). A layer 755 includes, for example, a layer containing a substance with a high electron-injection property (an electron-injection layer).

Alternatively, the layer 751 may include an electron-injection layer, the layer 752 may include an electron-transport layer, the layer 754 may include a hole-transport layer, and the layer 755 may include a hole-injection layer.

FIG. 15A illustrates the layer 751 and the layer 752 separately; however, one embodiment of the present invention is not limited thereto. For example, the layer 752 may be omitted when the layer 751 has functions of both a hole-injection layer and a hole-transport layer or the layer 751 has functions of both an electron-injection layer and an electron-transport layer.

Note that the light-emitting layer 753R included in the light-emitting device 750R contains a light-emitting substance that emits red light, the light-emitting layer 753G included in the light-emitting device 750G contains a light-emitting substance that emits green light, and the light-emitting layer 753B included in the light-emitting device 750B contains a light-emitting substance that emits blue light. Note that the light-emitting device 750G and the light-emitting device 750B have a structure in which the light-emitting layer 753R included in the light-emitting device 750R is replaced with the light-emitting layer 753G and the light-emitting layer 753B, respectively, and the other components are similar to those of the light-emitting device 750R.

The structure (e.g., material and thickness) of the layer 751, the layer 752, the layer 754, and the layer 755 may be the same or different from each other among the light-emitting devices of different colors.

The light-receiving device 760 includes a pixel electrode 791PD, a layer 761, a layer 762, a layer 763, and the upper electrode 792. The light-receiving device 760 can be configured not to include a hole-injection layer or an electron-injection layer.

The layer 762 includes an active layer (also referred to as a photoelectric conversion layer). The layer 762 has a function of absorbing light in a specific wavelength range and generating carriers (electrons and holes).

The layer 761 and the layer 763 each include, for example, a hole-transport layer or an electron-transport layer. In the case where the layer 761 includes a hole-transport layer, the layer 763 includes an electron-transport layer. In the case where the layer 761 includes an electron-transport layer, the layer 763 includes a hole-transport layer.

In the light-receiving device 760, the pixel electrode 791PD may be an anode and the upper electrode 792 may be a cathode, or the pixel electrode 791PD may be a cathode and the upper electrode 792 may be an anode.

FIG. 15B is a modification example of FIG. 15A. FIG. 15B illustrates an example in which the light-emitting devices and the light-receiving device share the layer 755 as well as the upper electrode 792. In this case, the layer 755 can be referred to as a common layer. The light-emitting devices and the light-receiving device share one or more common layers in this manner, whereby the manufacturing process can be simplified, resulting in reduced manufacturing cost.

Here, the layer 755 functions as an electron-injection layer or a hole-injection layer of the light-emitting devices 750R, 750G, and 750G. In this case, the layer 755 functions as an electron-transport layer or a hole-transport layer of the light-receiving device 760. Thus, the light-receiving device 760 illustrated in FIG. 15B is not necessarily provided with the layer 763 functioning as an electron-transport layer or a hole-transport layer.

### [Light-Emitting Device]

A specific structure example of the light-emitting device will be described here.

The light-emitting devices include at least a light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, or a substance with a bipolar property (a substance with a high electron-transport property and a high hole-transport property).

Either a low molecular compound or a high molecular compound can be used for the light-emitting devices, and an inorganic compound may also be included. Each layer included in the light-emitting device can be formed by an evaporation method (including a vacuum evaporation method), a transfer method, a printing method, an inkjet method, or a coating method.

For example, the light-emitting device can include one or more of a hole-injection layer, a hole-transport layer, a hole-blocking layer, an electron-blocking layer, an electron-transport layer, and an electron-injection layer.

The hole-injection layer is a layer that injects holes from an anode to a hole-transport layer and contains a material with a high hole-injection property. Examples of the material with a high hole-injection property include an aromatic amine compound, and a composite material containing a hole-transport material and an acceptor material (an electron-accepting material).

The hole-transport layer is a layer that transports holes, which are injected from the anode by the hole-injection layer, to the light-emitting layer. The hole-transport layer is a layer that contains a hole-transport material. As the hole-transport material, a substance having a hole mobility greater than or equal to 10⁶ cm²/Vs is preferable. Note that other substances can also be used as long as the substances have a hole-transport property higher than an electron-transport property. As the hole-transport material, materials with a high hole-transport property, typified by a π-electron rich heteroaromatic compound (e.g., a carbazole derivative, a thiophene derivative, and a furan derivative) and an aromatic amine (a compound having an aromatic amine skeleton), are preferable.

The electron-transport layer is a layer that transports electrons, which are injected from a cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as the substances have an electron-transport property higher than a hole-transport property. As the electron-transport material, it is possible to use a material with a high electron-transport property, of a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, lithium, cesium, ytterbium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), cesium carbonate, or a compound thereof. In addition, the electron-injection layer may have a stacked-layer structure of two or more layers. In the stacked-layer structure, for example, lithium fluoride can be used for the first layer and ytterbium can be used for the second layer.

Alternatively, an electron-transport material may be used for the electron-injection layer. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, or inverse photoelectron spectroscopy.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-α:2′,3′-c]phenazine (abbreviation: HATNA), or 2,4,6-tris[3′-(pyridin-3-yl)biphenyl-3-yl]-1,3,5-triazine (abbreviation: TmPPPyTz) can be used as the organic compound having an unshared electron pair. Note that NBPhen has a higher glass transition temperature (Tg) than BPhen and thus has high heat resistance.

The light-emitting layer is a layer that contains a light-emitting substance. The light-emitting layer can include one or more kinds of light-emitting substances. As the light-emitting substance, a substance that exhibits an emission color of blue, violet, bluish violet, green, yellowish green, yellow, orange, or red is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

### [Light-Receiving Device]

The active layer included in the light-receiving device includes a semiconductor. Examples of the semiconductor include an inorganic semiconductor typified by silicon and an organic semiconductor including an organic compound. This embodiment shows an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, an electron-donating property (donor property) usually increases; however, having a spherical shape, fullerene has a high electron-accepting property even when π-electrons widely spread therein. The high electron-accepting property efficiently causes rapid charge separation and is useful for the light-receiving device. Both C₆₀ and C₇₀ have a wide absorption band in the visible light region, and C₇₀ is especially preferable because of having a larger π-electron conjugation system and a wider absorption band in the long wavelength region than C₆₀. Other examples of the fullerene derivative include [6,6]-Phenyl-C71-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C₆₀ (abbreviation: ICBA).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Other examples of the p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, the light-receiving device may further include a layer containing any of a substance with a high hole-transport property, a substance with a high electron-transport property, or a substance with a bipolar property (a substance with a high electron-transport property and a high hole-transport property). Without limitation to the above, the light-receiving device may further include a layer containing a substance with a high hole-injection property, a hole-blocking material, a material with a high electron-injection property, or an electron-blocking material.

Either a low molecular compound or a high molecular compound can be used in the light-receiving device, and an inorganic compound may also be included. Each layer included in the light-receiving device can be formed by an evaporation method (including a vacuum evaporation method), a transfer method, a printing method, an inkjet method, or a coating method.

As the hole-transport material or the electron-blocking material, a high molecular compound typified by poly(3,4-ethylenedioxythiophene)/poly(styrenesulfonic acid) (PEDOT/PSS), or an inorganic compound such as a molybdenum oxide or copper iodide (CuI) can be used, for example. As the electron-transport material or the hole-blocking material, zinc oxide (ZnO) or polyethylenimine ethoxylated (PEIE) can be used. The light-receiving device may include a mixed film of PEIE and ZnO, for example.

For the active layer, a high molecular compound typified by poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the wavelength range. In that case, the third material may be a low molecular compound or a high molecular compound.

The above is the description of the light-receiving device.

At least part of this embodiment can be implemented in combination with the other embodiments described in this specification as appropriate.

### Embodiment 7

In this embodiment, a structure example of a light-emitting apparatus or a display apparatus that can be used as the light-emitting and light-receiving apparatus of one embodiment of the present invention will be described.

One embodiment of the present invention is a display apparatus that includes a light-emitting device and a light-receiving device. For example, three kinds of light-emitting devices emitting light of red (R), green (G), and blue (B) are included, whereby a full-color display apparatus can be achieved.

In one embodiment of the present invention, fine patterning of EL layers and an EL layer and an active layer is performed by a photolithography method without a shadow mask typified by a metal mask. This allows a display apparatus with high resolution and a high aperture ratio, which has been difficult to achieve, to be obtained. Moreover, EL layers can be formed separately, enabling the display apparatus to perform extremely clear display with high contrast and high display quality.

It is difficult to set the distance between EL layers for different colors or between an EL layer and an active layer to be less than 10 μm with a formation method using a metal mask, for example. By contrast, with use of the above method, the distance can be decreased to less than or equal to 3 μm, less than or equal to 2 μm, or less than or equal to 1 μm. For example, with use of an exposure apparatus for LSI, the distance can be decreased to less than or equal to 500 nm, less than or equal to 200 nm, less than or equal to 100 nm, or less than or equal to 50 nm. This can significantly reduce the area of a non-light-emitting region that may exist between two light-emitting devices or between a light-emitting device and a light-receiving device, so that the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

Furthermore, patterns of the EL layer and the active layer themselves can be made extremely smaller than those in the case of using a metal mask. For example, in the case of using a metal mask for forming EL layers separately, a variation in the thickness of the pattern occurs between the center and the edge of the pattern, which causes a reduction in an effective area that can be used as a light-emitting region with respect to the entire pattern area. By contrast, in the above manufacturing method, a pattern is formed by processing a film deposited to have a uniform thickness, which enables a uniform thickness in the pattern. Thus, even with a fine pattern, almost the entire area can be used as a light-emitting region. Therefore, the above manufacturing method makes it possible to achieve both high resolution and a high aperture ratio.

In many cases, an organic film formed using an FMM (Fine Metal Mask) has an extremely small taper angle (e.g., a taper angle greater than 0° and less than 30°) so that the thickness of the film becomes smaller in a portion closer to an end portion. Therefore, it is difficult to clearly observe a side surface of an organic film formed using an FMM because the side surface and a top surface are continuously connected. By contrast, in one embodiment of the present invention, an EL layer is processed without using an FMM and has a clear side surface. In particular, in one embodiment of the present invention, part of the EL layer preferably has a taper angle greater than or equal to 30° and less than or equal to 120°, further preferably greater than or equal to 60° and less than or equal to 120°.

Note that in this specification, an end portion of an object having a tapered shape indicates that the end portion of the object has a cross-sectional shape in which the angle between a side surface (a top surface) of the object and a surface on which the object is formed (a bottom surface) is greater than 0° and less than 90° in a region of the end portion and the thickness continuously increases from the end portion. A taper angle refers to an angle between a bottom surface (a surface on which an object is formed) and a side surface (a surface) at an end portion of the object.

More specific examples will be described below.

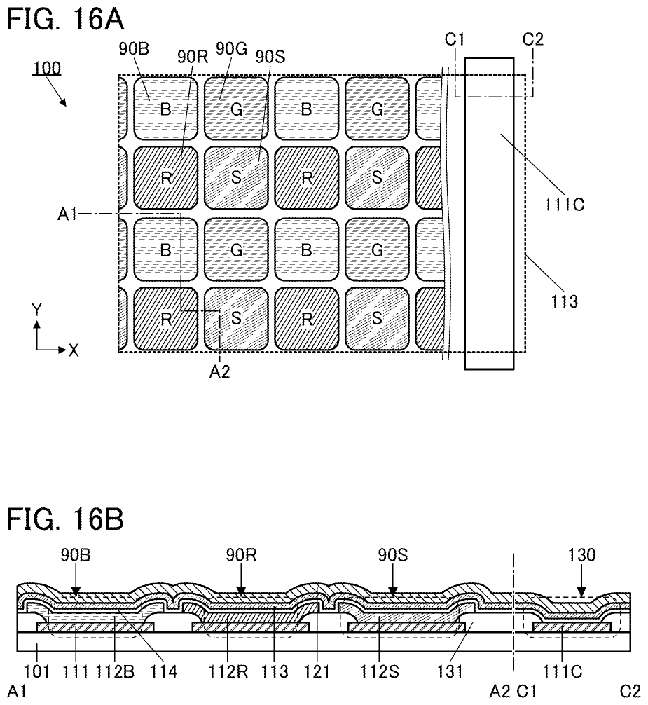

FIG. 16A is a schematic top view of the display region 100. The display region 100 includes a plurality of light-emitting devices 90R exhibiting red, a plurality of light-emitting devices 90G exhibiting green, a plurality of light-emitting devices 90B exhibiting blue, and a plurality of light-receiving devices 90S. In FIG. 4A, light-emitting regions of the light-emitting devices and the light-receiving devices are denoted by R, G, B, and S to easily differentiate the light-emitting devices.

The light-emitting devices 90R, the light-emitting devices 90G, the light-emitting devices 90B, and the light-receiving devices 90S are arranged in a matrix. In FIG. 16A, two devices are alternately arranged in one direction. Note that the arrangement method of the light-emitting devices is not limited thereto; another arrangement method such as stripe arrangement, S-stripe arrangement, delta arrangement, Bayer arrangement, or zigzag arrangement may be used, or a PenTile arrangement or a diamond arrangement may also be used.

FIG. 16A illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting devices 90R are arranged. In FIG. 16A, the common electrode 113 is denoted by a dashed line.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface, a top surface of the connection electrode 111C can have a belt-like shape, an L shape, a U shape (a square bracket shape), or a quadrangular shape.

FIG. 16B is a schematic cross-sectional view taken along the dashed-dotted line A1-A2 and dashed-dotted line C1-C2 in FIG. 16A. FIG. 16B is a schematic cross-sectional view of the light-emitting device 90B, the light-emitting device 90R, the light-receiving device 90S, and the connection electrode 111C.

Note that the light-emitting device 90G that is not illustrated in the schematic cross-sectional view can have a structure similar to that of the light-emitting device 90B or the light-emitting device 90R. In the following description, the description of the light-emitting device can be referred to.

The light-emitting device 90B includes a pixel electrode 111, an organic layer 112B, an organic layer 114, and the common electrode 113. The light-emitting device 90R includes the pixel electrode 111, an organic layer 112R, an organic layer 114, and the common electrode 113. The light-receiving device 90S includes the pixel electrode 111, an organic layer 114, and the common electrode 113. The organic layer 114 and the common electrode 113 are shared by the light-emitting device 90B, the light-emitting device 90R, and the light-receiving device 90S. The organic layer 114 can also be referred to as a common layer.

The organic layer 112R contains at least a light-emitting organic compound that emits light with intensity in a red wavelength range. The organic layer 112B contains at least a light-emitting organic compound that emits light with intensity in a blue wavelength range. The common electrode 113 contains a photoelectric conversion material that has sensitivity in the visible light or infrared light wavelength range. The organic layer 112R and the organic layer 112B can also be referred to as an EL layer.

The organic layer 112R, the organic layer 112B, and the common electrode 113 may each include one or more of an electron-injection layer, an electron-transport layer, a hole-injection layer, and a hole-transport layer. The organic layer 114 does not necessarily include the light-emitting layer. For example, the organic layer 114 includes one or more of an electron-injection layer, an electron-transport layer, a hole-injection layer, and a hole-transport layer.

Here, the uppermost layer in the stacked-layer structure of the organic layer 112R, the organic layer 112B, and the organic layer 112S, i.e., the layer in contact with the organic layer 114 is preferably a layer other than the light-emitting layer. For example, a structure is preferable in which an electron-injection layer, an electron-transport layer, a hole-injection layer, a hole-transport layer, or a layer other than those is provided to cover the light-emitting layer so as to be in contact with the organic layer 114. When a top surface of the light-emitting layer is protected by another layer in manufacturing each light-emitting device, the reliability of the light-emitting device can be improved.

The pixel electrode 111 is provided for each device. The common electrode 113 and the organic layer 114 are each provided as a continuous layer shared by the light-emitting devices. A conductive film that has a property of transmitting visible light is used for either the pixel electrodes or the common electrode 113, and a reflective conductive film is used for the other. When the pixel electrodes have a light-transmitting property and the common electrode 113 has a reflective property, a bottom-emission display apparatus can be obtained; by contrast, when the pixel electrodes have a reflective property and the common electrode 113 has a light-transmitting property, a top-emission display apparatus can be obtained. Note that when both the pixel electrodes and the common electrode 113 transmit light, a dual-emission display apparatus can be obtained.

An insulating layer 131 is provided to cover an end portion of the pixel electrode 111. An end portion of the insulating layer 131 preferably has a tapered shape. Note that in this specification, an end portion of an object having a tapered shape indicates that the end portion has a cross-sectional shape in which the angle between a surface of the object and a surface on which the object is formed is greater than 0° and less than 90° in a region of the end portion and the thickness continuously increases from the end portion.

When an organic resin is used for the insulating layer 131, the surface can be moderately curved. Thus, coverage with a film formed over the insulating layer 131 can be improved.

Examples of materials that can be used for the insulating layer 131 include an acrylic resin, a polyimide resin, an epoxy resin, a polyamide resin, a polyimide-amide resin, a siloxane resin, a benzocyclobutene-based resin, a phenol resin, and precursors of these resins.

Alternatively, an inorganic insulating material may be used for the insulating layer 131. Examples of inorganic insulating materials that can be used for the insulating layer 131 include silicon oxide, silicon oxynitride, silicon nitride oxide, silicon nitride, aluminum oxide, aluminum oxynitride, and hafnium oxide. Yttrium oxide, zirconium oxide, gallium oxide, tantalum oxide, magnesium oxide, lanthanum oxide, cerium oxide, or neodymium oxide may be used.

As illustrated in FIG. 16B, spaces are provided between two organic layers of the light-emitting devices of different colors and the light-emitting device and the light-receiving device. In this manner, the organic layer 112R, the organic layer 112B, and a common electrode 115 are preferably provided so as not to be in contact with each other. This can suitably prevent unintentional light emission due to current flowing through two adjacent organic layers. As a result, the contrast can be increased to achieve a display apparatus with high display quality.

The organic layer 112R, the organic layer 112B, and the common electrode 115 each preferably have a taper angle greater than or equal to 30°. In an end portion of each of the organic layer 112R, an organic layer 112G, and the organic layer 112B, the angle between a side surface (a surface) and a bottom surface (a surface on which the layer is formed) is preferably greater than or equal to 30° and less than or equal to 120°, further preferably greater than or equal to 45° and less than or equal to 120°, still further preferably greater than or equal to 60° and less than or equal to 120°. Alternatively, the organic layer 112R, the organic layer 112G, and the organic layer 112B each preferably have a taper angle of 90° or a neighborhood thereof (e.g., greater than or equal to 80° and less than or equal to 100°).

A protective layer 121 is provided over the common electrode 113. The protective layer 121 has a function of preventing diffusion of impurities (water) into the light-emitting devices from above.

The protective layer 121 can have, for example, a single-layer structure or a stacked-layer structure at least including an inorganic insulating film. Examples of the inorganic insulating film include a silicon oxide film, a silicon oxynitride film, a silicon nitride oxide film, a silicon nitride film, an aluminum oxide film, an aluminum oxynitride film, or a hafnium oxide film. Alternatively, a semiconductor material such as indium gallium oxide or indium gallium zinc oxide may be used for the protective layer 121.

As the protective layer 121, a stacked-layer film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables a top surface of the organic insulating film to be flat, and accordingly, coverage with the inorganic insulating film thereover is improved, leading to an improvement in barrier properties. Moreover, a top surface of the protective layer 121 is flat; thus, when a component (e.g., a color filter, an electrode of a touch sensor, or a lens array) is provided above the protective layer 121, the component is less likely to be affected by an uneven shape caused by a structure below the protective layer 121.

In the connection portion 130, the common electrode 113 is provided on and in contact with the connection electrode 111C and the protective layer 121 is provided to cover the common electrode 113. The insulating layer 131 is provided to cover an end portion of the connection electrode 111C.

A structure example of a display apparatus whose structure is partly different from that illustrated in FIG. 16B will be described below. Specifically, an example in which the insulating layer 131 is not provided will be described.

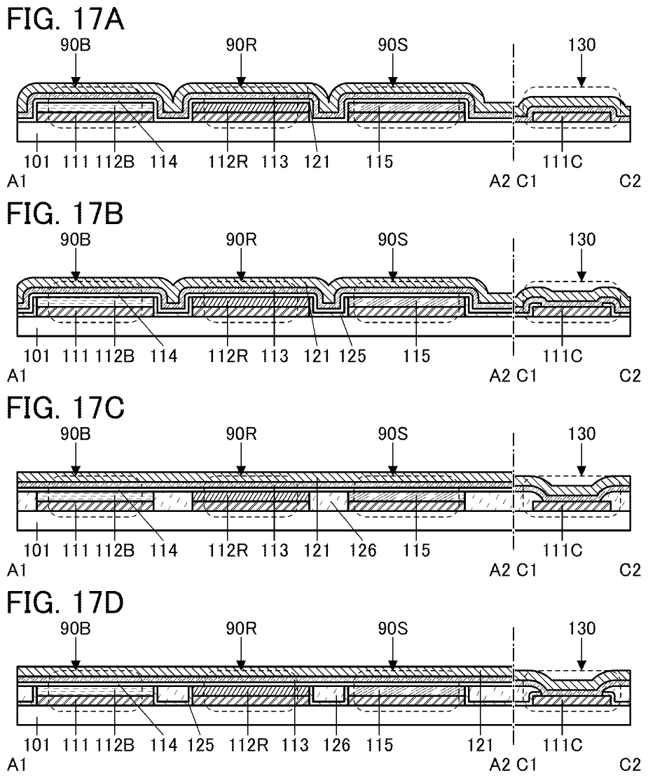

FIG. 17A to FIG. 17C each illustrate an example of the case where side surfaces of the pixel electrode 111 are substantially aligned with side surfaces of the organic layer 112R, the organic layer 112B, or the common electrode 115.

In FIG. 17A, the organic layer 114 is provided to cover top surfaces and side surfaces of the organic layer 112R, the organic layer 112B, and the common electrode 115. The organic layer 114 can prevent the pixel electrode 111 and the common electrode 113 from being in contact with each other and being electrically short-circuited.

FIG. 6B illustrates an example in which an insulating layer 125 is provided to be in contact with side surfaces of the organic layer 112R, the organic layer 112G, and the organic layer 112B and a side surface of the pixel electrode 111. The insulating layer 125 can prevent the pixel electrode 111 and the common electrode 113 from being electrically short-circuited and effectively inhibit leakage current therebetween.

The insulating layer 125 can be an insulating layer containing an inorganic material. As the insulating layer 125, an inorganic insulating film such as an oxide insulating film, a nitride insulating film, an oxynitride insulating film, and a nitride oxide insulating film can be used. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when an aluminum oxide film, a hafnium oxide film, or a silicon oxide film formed by an ALD method is used as the insulating layer 125, the insulating layer 125 can have few pinholes and an excellent function of protecting the organic layer.

Note that in this specification, oxynitride refers to a material in which an oxygen content is higher than a nitrogen content, and nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The insulating layer 125 can be formed by a sputtering method, a CVD method, a PLD method, or an ALD method. The insulating layer 125 is preferably formed by an ALD method achieving good coverage.

In FIG. 17C, resin layers 126 are provided between two adjacent light-emitting devices and between the light-emitting device and the light-receiving device so as to fill the space between two facing pixel electrodes and two facing organic layers. The resin layer 126 can planarize a surface on which the organic layer 114 and the common electrode 113 are formed; accordingly, disconnection of the common electrode 113 due to poor coverage in a step between adjacent light-emitting devices can be prevented.

An insulating layer containing an organic material can be suitably used as the resin layer 126. For example, as the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins can be used. As the resin layer 126, polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photosensitive resin can be used as the resin layer 126. A photoresist may be used for the photosensitive resin. As the photosensitive resin, a positive photosensitive material or a negative photosensitive material can be used.

A colored material (e.g., a material containing a black pigment) may be used for the resin layer 126 so that the resin layer 126 has a function of blocking stray light from adjacent pixels and inhibiting color mixture.

In FIG. 17D, the insulating layer 125 and the resin layer 126 over the insulating layer 125 are provided. Since the insulating layer 125 prevents the organic layer 112R and the resin layer 126 from being in contact with each other, impurities (moisture) included in the resin layer 126 can be prevented from being diffused into the organic layer 112R, whereby a highly reliable display apparatus can be achieved.

A reflective film (e.g., a metal film containing one or more of silver, palladium, copper, titanium, and aluminum) may be provided between the insulating layer 125 and the resin layer 126 so that light emitted from the light-emitting layer is reflected by the reflective film to provide a function of increasing light extraction efficiency.

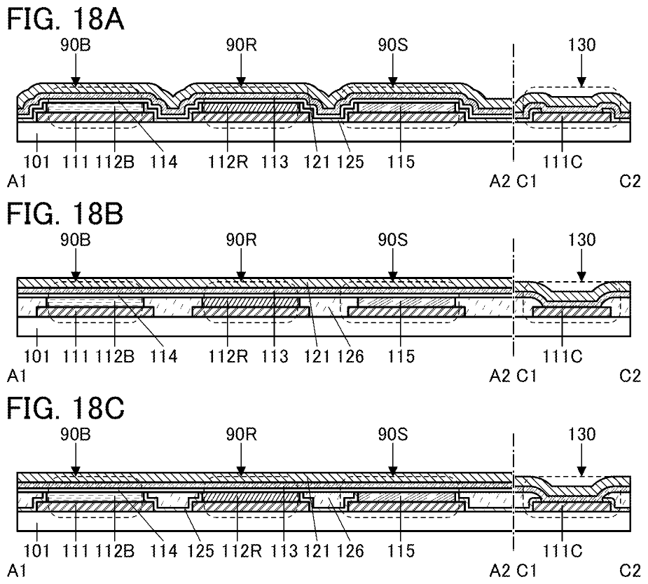

FIG. 18A to FIG. 18C each illustrate an example in which the width of the pixel electrode 111 is larger than the width of the organic layer 112R, the organic layer 112B, or the common electrode 115. The organic layer 112R is provided on the inner side than end portions of the pixel electrode 111.

FIG. 18A illustrates an example in which the insulating layer 125 is provided. The insulating layer 125 is provided to cover a side surface of the organic layer included in the light-emitting element or the light-receiving element and a side surface and part of a top surface of the pixel electrode 111.

FIG. 18B illustrates an example in which the resin layer 126 is provided. The resin layer 126 is positioned between two adjacent light-emitting devices or between the light-emitting device and the light-receiving device and covers a side surface of the organic layer and a top and side surface of the pixel electrode 111.

FIG. 18C illustrates an example in which both the insulating layer 125 and the resin layer 126 are provided. The insulating layer 125 is provided between the organic layer 112R and the resin layer 126.

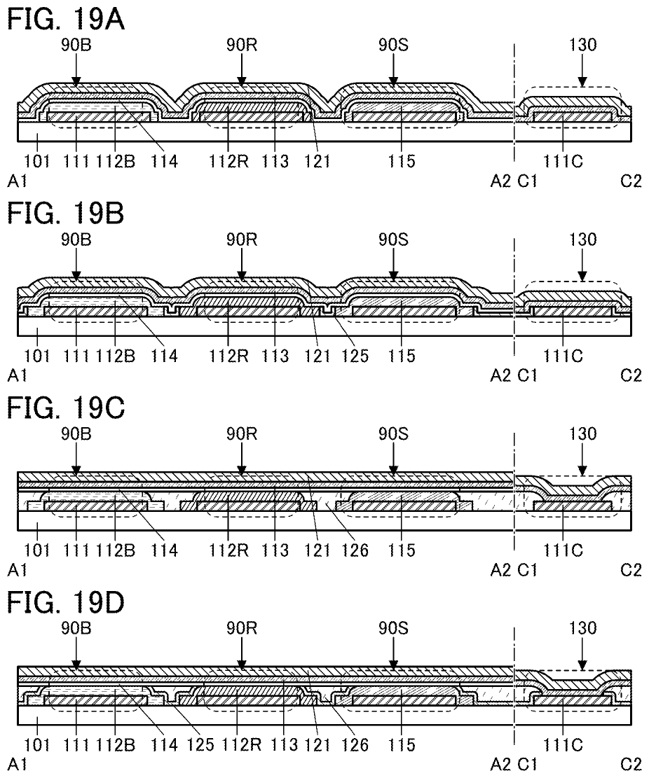

FIGS. 19A to 19D each illustrate an example in which the width of the pixel electrode 111 is smaller than the width of the organic layer 112R, the organic layer 112B, or the common electrode 115. The organic layer 112R extends to an outer side beyond end portions of the pixel electrode 111.

FIG. 19B illustrates an example in which the insulating layer 125 is provided. The insulating layer 125 is provided in contact with side surfaces of the organic layers of two adjacent light-emitting devices. The insulating layer 125 may be provided to cover not only a side surface but also part of a top surface of the organic layer 112R.

FIG. 19C illustrates an example in which the resin layer 126 is provided. The resin layer 126 is positioned between two adjacent light-emitting devices and covers a side surface and part of a top surface of the organic layer 112R. The resin layer 126 may be provided to be in contact with the side surface of the organic layer 112R and not to cover the top surface thereof.

FIG. 19D illustrates an example in which both the insulating layer 125 and the resin layer 126 are provided. The insulating layer 125 is provided between the organic layer 112R and the resin layer 126.

Here, a structure example of the resin layer 126 is described.

A top surface of the resin layer 126 is preferably as flat as possible; however, the top surface of the resin layer 126 may be concave or convex depending on an uneven shape of a surface on which the resin layer 126 is formed and formation conditions of the resin layer 126.

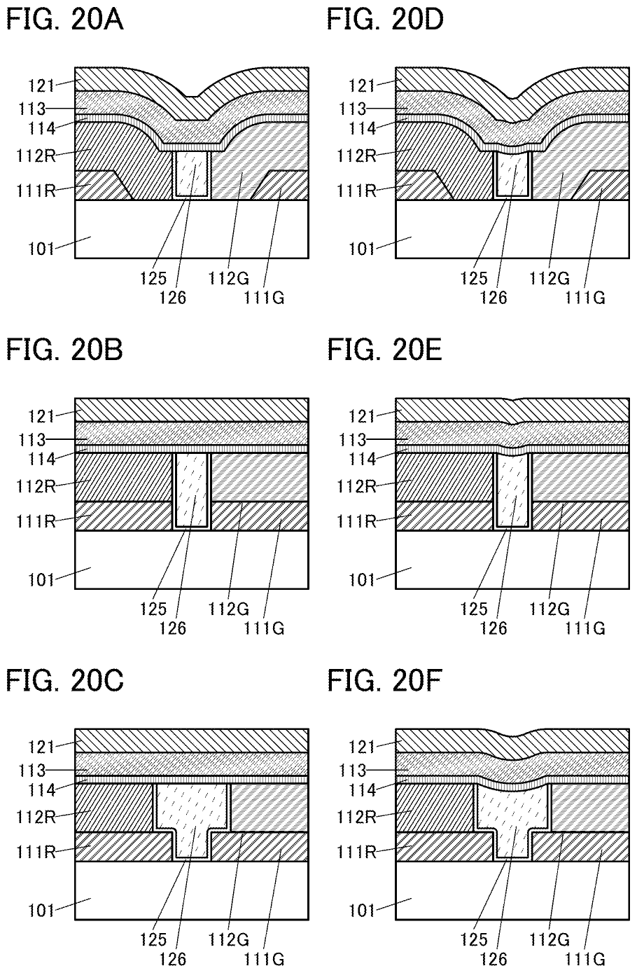

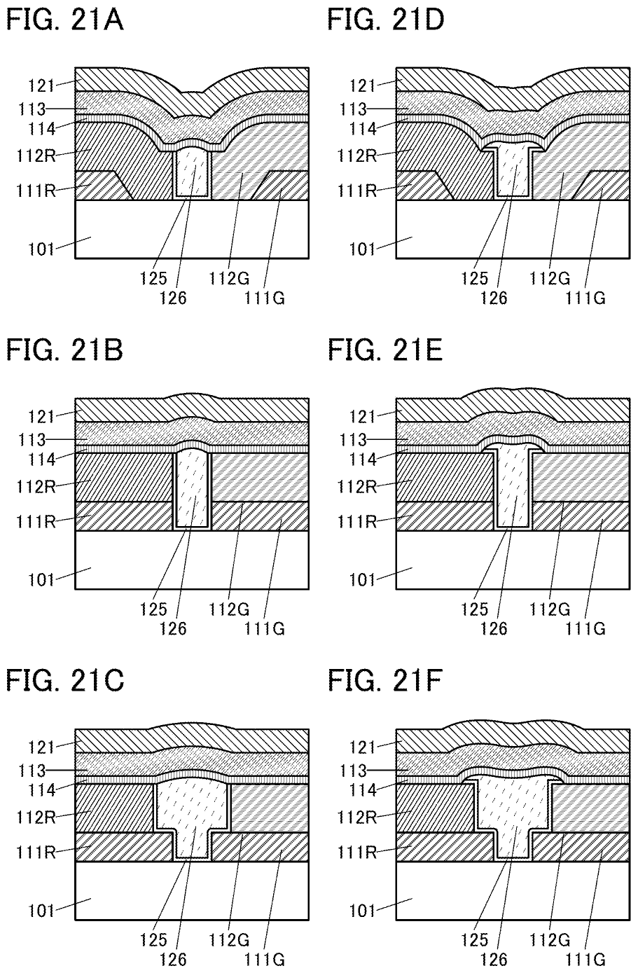

FIG. 20A to FIG. 21F are each an enlarged view of an end portion of the pixel electrode 111R included in the light-emitting device 90R, an end portion of the pixel electrode 111G included in the light-emitting device 90G, and the vicinity thereof. The organic layer 112G is provided over the pixel electrode 111G.

FIG. 20A, FIG. 20B, and FIG. 20C are each an enlarged view of the resin layer 126 having a flat top surface and the vicinity thereof. FIG. 20A illustrates an example of the case where the width of the organic layer 112R is larger than the width of the pixel electrode 111. FIG. 20B illustrates an example in which the widths are substantially the same. FIG. 20C illustrates an example of the case where the width of the organic layer 112R is smaller than the width of the pixel electrode 111.

The organic layer 112R is provided to cover an end portion of the pixel electrode 111 as illustrated in FIG. 20A; for this reason, the end portion of the pixel electrode 111 is preferably tapered. Accordingly, the step coverage with the organic layer 112R is improved and a highly reliable display apparatus can be achieved.

FIG. 20D, FIG. 20E, and FIG. 20F each illustrate an example of the case where a top surface of the resin layer 126 is concave. In this case, a concave portion that reflects the concave top surface of the resin layer 126 is formed on each of top surfaces of the organic layer 114, the common electrode 113, and the protective layer 121.

FIG. 21A, FIG. 21B, and FIG. 21C each illustrate an example of the case where a top surface of the resin layer 126 is convex. In this case, a convex portion that reflects the convex top surface of the resin layer 126 is formed on each of top surfaces of the organic layer 114, the common electrode 113, and the protective layer 121.

FIG. 21D, FIG. 21E, and FIG. 21F each illustrate an example of the case where part of the resin layer 126 covers an upper end portion and part of a top surface of the organic layer 112R and an upper end portion and part of a top surface of the organic layer 112G. In this case, an insulating layer 125 is provided between the resin layer 126 and the top surface of the organic layer 112R or the organic layer 112G.

FIG. 21D, FIG. 21E, and FIG. 21F each illustrate an example of the case where a top surface of the resin layer 126 is partly concave. In this case, unevenness that reflects the shape of the resin layer 126 is formed on each of top surfaces of the organic layer 114, the common electrode 113, and the protective layer 121.

The above is the description of the structure examples of the resin layer.

At least part of this embodiment can be implemented in combination with the other embodiments described in this specification as appropriate.

### Embodiment 8

In this embodiment, a structure example of a display apparatus that can be used as a light-emitting and light-receiving apparatus of one embodiment of the present invention will be described. Although the display apparatus is described here as a display apparatus capable of displaying an image, the display apparatus can be used as a light-emitting and light-receiving apparatus by using a light-emitting device as a light source.

The display apparatus in this embodiment can be a high-resolution display apparatus or a large-sized display apparatus. Accordingly, the display apparatus of this embodiment can be used in, for example, display portions of a digital camera, a digital video camera, a digital photo frame, a mobile phone, a portable game machine, a smartphone, a wristwatch terminal, a tablet terminal, a portable information terminal, and an audio reproducing device, in addition to display portions of electronic devices with a relatively large screen, such as a television device, a desktop or laptop personal computer, various monitors for computers, digital signage, and a pachinko machine.

### [Display Apparatus 400]

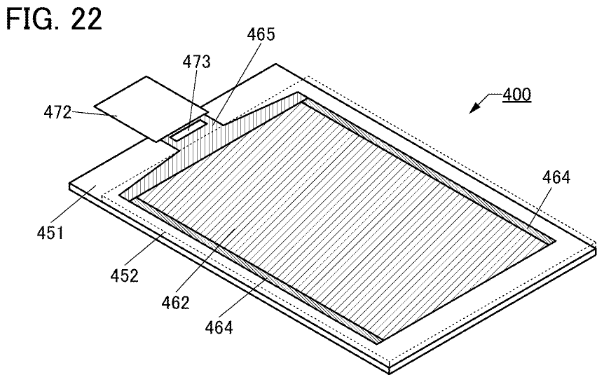

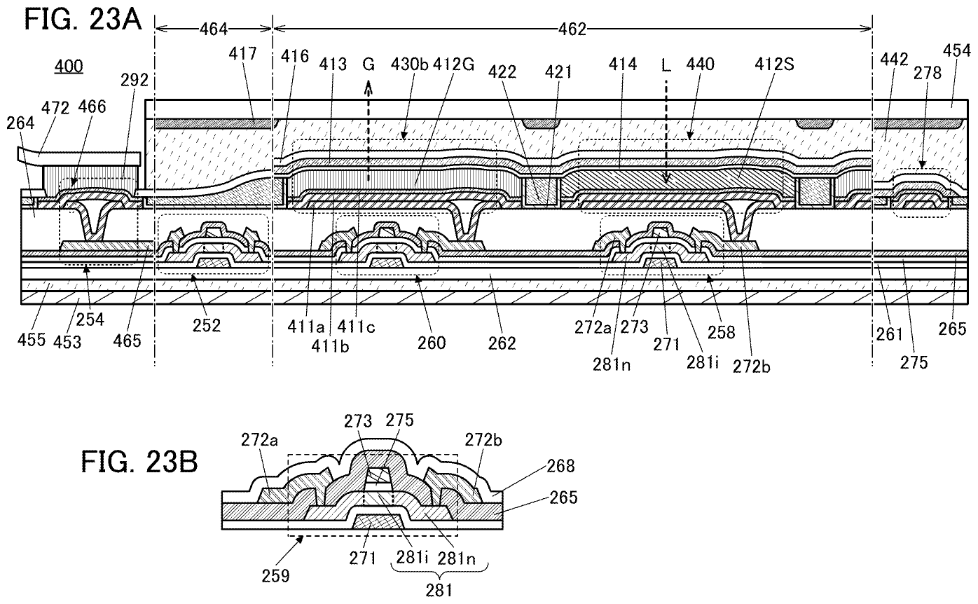

FIG. 22 is a perspective view of a display apparatus 400, and FIG. 23A is a cross-sectional view of the display apparatus 400.

The display apparatus 400 has a structure in which a substrate 452 and a substrate 451 are bonded to each other. In FIG. 22, the substrate 452 is denoted by a dashed line.

The display apparatus 400 includes a display portion 462, a circuit 464, and a wiring 465. FIG. 22 illustrates an example in which an IC 473 and an FPC 472 are mounted on the display apparatus 400. Thus, the structure illustrated in FIG. 13 can be regarded as a display module including the display apparatus 400, the IC (integrated circuit), and the FPC.

As the circuit 464, a scan line driver circuit can be used, for example.

The wiring 465 has a function of supplying a signal and electric power to the display portion 462 and the circuit 464. The signal and electric power are input to the wiring 465 from the outside through the FPC 472 or input to the wiring 465 from the IC 473.

FIG. 22 illustrates an example in which the IC 473 is provided over the substrate 451 by a COG (Chip On Glass) method or a COF (Chip on Film) method. An IC including a scan line driver circuit or a signal line driver circuit can be used as the IC 473, for example. Note that the display apparatus 400 and the display module are not necessarily provided with an IC. The IC may be mounted on the FPC by a COF method.

FIG. 23A illustrates an example of cross sections of part of a region including the FPC 472, part of the circuit 464, part of the display portion 462, and part of a region including a connection portion of the display apparatus 400. FIG. 23A specifically illustrates an example of a cross section of a region including a light-emitting device 430b emitting green light (G) and a light-receiving device 440 receiving reflected light (L) in the display portion 462.

The display apparatus 400 illustrated in FIG. 23A includes a transistor 252, a transistor 260, a transistor 258, the light-emitting device 430b, and the light-emitting device 440 between a substrate 453 and a substrate 454.

Any of the light-emitting devices and the light-receiving devices given above as examples can be applied to the light-emitting device 430b and the light-receiving device 440.

In the case where a pixel of the display apparatus includes three kinds of subpixels including light-emitting devices exhibiting different colors from each other, the three subpixels can be of three colors of red (R), green (G), and blue (B) or of three colors of yellow (Y), cyan (C), and magenta (M). In the case where four subpixels are included, the four subpixels can be of four colors of R, G, B, and white (W) or of four colors of R, G, B, and Y. Alternatively, the subpixel may include a light-emitting device emitting infrared light.

As the light-receiving device 440, a photoelectric conversion device having sensitivity to light in the red, green, or blue wavelength range or a photoelectric conversion device having sensitivity to light in the infrared wavelength range can be used.

The substrate 454 and a protective layer 416 are bonded to each other with an adhesive layer 442. The adhesive layer 442 is provided to overlap with the light-emitting device 430b and the light-receiving device 440, and the display apparatus 400 employs a solid sealing structure. The substrate 454 is provided with a light-blocking layer 417.

The light-emitting device 430b and the light-receiving device 440 each include a conductive layer 411a, a conductive layer 411b, and a conductive layer 411c as pixel electrodes. The conductive layer 411b reflects visible light and functions as a reflective electrode. The conductive layer 411c transmits visible light and functions as an optical adjustment layer.

The conductive layer 411a included in the light-emitting device 430b is connected to a conductive layer 272b included in the transistor 260 through an opening provided in an insulating layer 264. The transistor 260 has a function of controlling the driving of the light-emitting device. The conductive layer 411a included in the light-receiving device 440 is electrically connected to the conductive layer 272b included in the transistor 258. The transistor 258 has a function of controlling, for example, the timing of light exposure using the light-receiving device 440.

An EL layer 412G or a photoelectric conversion layer 412S is provided to cover the pixel electrode. An insulating layer 421 is provided in contact with a side surface of the EL layer 412G and a side surface of the photoelectric conversion layer 412S, and a resin layer 422 is provided to fill a concave portion of the insulating layer 421. An organic layer 414, a common electrode 413, and the protective layer 416 are provided to cover the EL layer 412G and the photoelectric conversion layer 412S. Providing the protective layer 416 that covers the light-emitting device can inhibit entry of impurities (water) into the light-emitting device, thereby increasing the reliability of the light-emitting device.

Light G emitted from the light-emitting device 430b is emitted toward the substrate 452. The light-emitting device 440 receives light L incident through the substrate 452 and converts the light L into an electric signal. For the substrate 452, a material having a high visible-light-transmitting property is preferably used.

The transistor 252, the transistor 260, and the transistor 258 are all formed over the substrate 451. These transistors can be formed using the same material in the same step.

Note that the transistor 252, the transistor 260, and the transistor 258 may be separately formed to have different structures. For example, a transistor having a back gate and a transistor not having a back gate may be formed separately, or transistors whose semiconductors, gate electrodes, gate insulating layers, source electrodes, and drain electrodes are formed of different materials and/or have different thicknesses may be formed separately.

The substrate 453 and an insulating layer 262 are bonded to each other with an adhesive layer 455.

In a manufacturing method of the display apparatus 400, first, a formation substrate provided with the insulating layer 262, the transistors, the light-emitting devices, and the light-receiving device is bonded to the substrate 454 provided with the light-blocking layer 417 with the adhesive layer 442. Then, the substrate 453 is attached to a surface exposed by separation of the formation substrate, whereby the components formed over the formation substrate are transferred to the substrate 453. The substrate 453 and the substrate 454 are preferably flexible. This can increase the flexibility of the display apparatus 400.

A connection portion 254 is provided in a region of the substrate 453 that does not overlap with the substrate 454. In the connection portion 254, the wiring 465 is electrically connected to the FPC 472 through a conductive layer 466 and a connection layer 292. The conductive layer 466 can be obtained by processing the same conductive film as the pixel electrode. Thus, the connection portion 254 and the FPC 472 can be electrically connected to each other through the connection layer 292.

The transistor 252, the transistor 260, and the transistor 258 each include a conductive layer 271 functioning as a gate, an insulating layer 261 functioning as a gate insulating layer, a semiconductor layer 281 including a channel formation region 281i and a pair of low-resistance regions 281n, a conductive layer 272a connected to one of the pair of low-resistance regions 281n, the conductive layer 272b connected to the other of the pair of low-resistance regions 281n, an insulating layer 275 functioning as a gate insulating layer, a conductive layer 273 functioning as a gate, and an insulating layer 265 covering the conductive layer 273. The insulating layer 261 is positioned between the conductive layer 271 and the channel formation region 281i. The insulating layer 275 is positioned between the conductive layer 273 and the channel formation region 281i.

The conductive layer 272a and the conductive layer 272b are connected to the corresponding low-resistance regions 281n through openings provided in the insulating layer 265. One of the conductive layer 272a and the conductive layer 272b functions as a source, and the other functions as a drain.

FIG. 23A illustrates an example in which the insulating layer 275 covers a top surface and a side surface of the semiconductor layer. The conductive layer 272a and the conductive layer 272b are connected to the corresponding low-resistance regions 281n through openings provided in the insulating layer 275 and the insulating layer 265.

In a transistor 259 illustrated in FIG. 23B, the insulating layer 275 overlaps with the channel formation region 281i of the semiconductor layer 281 and does not overlap with the low-resistance regions 281n. The structure illustrated in FIG. 23B can be obtained by processing the insulating layer 275 using the conductive layer 273 as a mask, for example. In FIG. 23B, the insulating layer 265 is provided to cover the insulating layer 275 and the conductive layer 273, and the conductive layer 272a and the conductive layer 272b are connected to the low-resistance regions 281n through the openings in the insulating layer 265. Furthermore, an insulating layer 268 covering the transistor may be provided.

There is no particular limitation on the structures of the transistors included in the display apparatus of this embodiment. For example, a planar transistor, a staggered transistor, or an inverted staggered transistor can be used. A top-gate or bottom-gate transistor structure may be used. Alternatively, gates may be provided above and below a semiconductor layer in which a channel is formed.

The structure in which the semiconductor layer where a channel is formed is provided between two gates is used for the transistor 252, the transistor 260, and the transistor 258. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

The band gap of a metal oxide used for the semiconductor layer of the transistor is preferably greater than or equal to 2 eV, further preferably greater than or equal to 2.5 eV. With the use of a metal oxide having a wide bandgap, the off-state current of the OS transistor can be reduced.

A metal oxide preferably contains at least indium or zinc and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. Specifically, M is preferably one or more kinds selected from gallium, aluminum, yttrium, and tin, and M is further preferably gallium. Hereinafter, a metal oxide containing indium, M, and zinc is referred to as In-M-Zn oxide in some cases.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Further alternatively, an oxide containing indium (In), aluminum (Al), gallium (Ga), and zinc (Zn) (also referred to as IAGZO) may be used for the semiconductor layer.

When the metal oxide is an In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio. By increasing the proportion of the number of indium atoms in the metal oxide, the on-state current or field-effect mobility of the transistor can be improved.

For example, when the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic ratio of In being 1.

The proportion of the number of In atoms may be less than that of the number of M atoms in the In-M-Zn oxide. Examples of the atomic ratio of the metal elements in such an In-M-Zn oxide include In:M:Zn=1:3:2 or a composition in the neighborhood thereof, In:M:Zn=1:3:3 or a composition in the neighborhood thereof, In:M:Zn=1:3:4 or a composition in the neighborhood thereof. By increasing the proportion of the number of M atoms in the metal oxide, the band gap of the In-M-Zn oxide is further increased; thus, the resistance to a negative bias stress test with light irradiation can be improved. Specifically, the amount of change in the threshold voltage or the amount of change in the shift voltage (Vsh) measured in an NBTIS (Negative Bias Temperature Illumination Stress) test of the transistor can be decreased. Note that the shift voltage (Vsh) is defined as Vg at which, in a drain current (Id)-gate voltage (Vg) curve of a transistor, the tangent at a point where the slope of the curve is the steepest intersects the straight line of Id=1 pA. Alternatively, the semiconductor layer of the transistor may contain silicon. Examples of silicon include amorphous silicon and crystalline silicon (e.g., low-temperature polysilicon or single crystal silicon).

In particular, low-temperature polysilicon has relatively high mobility and can be formed over a glass substrate, and thus can be suitably used in a display apparatus. For example, a transistor in which low-temperature polysilicon is used in a semiconductor layer can be used as the transistor 252 included in the driver circuit, and a transistor in which an oxide semiconductor is used in a semiconductor layer can be used as the transistor 260 and the transistor 258 provided for the pixel.

Alternatively, a semiconductor layer of a transistor may include a layered substance that functions as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material functioning as a semiconductor and having high two-dimensional electrical conductivity is used for a channel formation region, a transistor having a high on-state current can be provided.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The transistor included in the circuit 464 and the transistor included in the display portion 462 may have the same structure or different structures. A plurality of transistors included in the circuit 464 may have the same structure or two or more kinds of structures. Similarly, a plurality of transistors included in the display portion 462 may have the same structure or two or more kinds of structures.

A material through which impurities (e.g., water and hydrogen) do not easily diffuse is preferably used for at least one of the insulating layers covering the transistors. This allows the insulating layer to function as a barrier layer. Such a structure can effectively inhibit diffusion of impurities into the transistors from the outside and increase the reliability of the display apparatus.

An inorganic insulating film is preferably used as each of the insulating layer 261, the insulating layer 262, the insulating layer 265, the insulating layer 268, and the insulating layer 275. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film may be used. A stack including two or more of the above inorganic insulating films may also be used.

Here, an organic insulating film often has a lower barrier property than an inorganic insulating film. Therefore, the organic insulating film preferably has an opening in the vicinity of an end portion of the display apparatus 400. This can inhibit entry of impurities from the end portion of the display apparatus 400 through the organic insulating film. Alternatively, the organic insulating film may be formed such that its end portion is positioned inward from the end portion of the display apparatus 400, to prevent the organic insulating film from being exposed at the end portion of the display apparatus 400.

An organic insulating film is suitable for the insulating layer 264 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A light-blocking layer 417 is preferably provided on a surface of the substrate 454 on the substrate 453 side. A variety of optical members can be arranged on the outer side of the substrate 454. Examples of the optical members include a polarizing plate, a retardation plate, a light diffusion layer (a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided on the outer side of the substrate 454.

FIG. 23A illustrates a connection portion 278. In the connection portion 278, the common electrode 413 is electrically connected to a wiring. FIG. 23A illustrates an example in which the wiring has the same stacked-layer structure as the pixel electrode.

For each of the substrate 453 and the substrate 454, glass, quartz, ceramics, sapphire, a resin, a metal, an alloy, or a semiconductor can be used. The substrate on the side from which light from the light-emitting device is extracted is formed using a material that transmits the light. When the substrate 453 and the substrate 454 are formed using a flexible material, the flexibility of the display apparatus can be increased. Furthermore, a polarizing plate may be used as the substrate 453 or the substrate 454.

For each of the substrate 453 and the substrate 454, it is possible to use a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber. Glass that is thin enough to have flexibility may be used for one or both of the substrate 453 and the substrate 454.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic resin film.

When a film is used for the substrate and the film absorbs water, creases might be generated in the display panel. For that reason, a film with a low water absorption rate is preferably used for the substrate. For example, the water absorption rate of the film is preferably lower than or equal to 1%, further preferably lower than or equal to 0.1%, still further preferably lower than or equal to 0.01%.

As the adhesive layer, an ultraviolet curable adhesive, a reactive curable adhesive, a thermosetting adhesive, or an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, typified by an epoxy resin, is preferred. Alternatively, a two-component-mixture-type resin may be used. Further alternatively, an adhesive sheet may be used.

As the connection layer 292, an anisotropic conductive film (ACF) or an anisotropic conductive paste (ACP) can be used.

Examples of materials that can be used for the gates, the sources, and the drains of the transistors and a variety of wirings and electrodes included in the display apparatus include aluminum, titanium, chromium, nickel, copper, yttrium, zirconium, molybdenum, silver, tantalum, and tungsten, and an alloy containing any of these metals as its main component. A single-layer structure or a stacked-layer structure including a film containing any of these materials can be used.

As a light-transmitting conductive material, a conductive oxide, for example, indium oxide, indium tin oxide, indium zinc oxide, zinc oxide, or zinc oxide containing gallium, or graphene can be used. Alternatively, gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) may be used. Note that in the case of using the metal material or the alloy material (or the nitride thereof), the material is made thin enough to have a light-transmitting property. Furthermore, a stacked film of the above materials can be used for a conductive layer. For example, a stacked film of indium tin oxide and an alloy of silver and magnesium is preferably used, in which case the conductivity can be increased. They can also be used for conductive layers such as wirings and electrodes included in the display apparatus, and conductive layers (e.g., a conductive layer functioning as a pixel electrode or a common electrode) included in a light-emitting device.

Examples of insulating materials that can be used for each insulating layer include an acrylic resin, an epoxy resin, or an inorganic insulating material such as silicon oxide, silicon oxynitride, silicon nitride oxide, silicon nitride, and aluminum oxide.

At least part of the structure examples and the drawings corresponding thereto described in this embodiment as examples can be combined with the other structure examples and the other drawings as appropriate.

At least part of this embodiment can be implemented in combination with the other embodiments described in this specification as appropriate.

### Embodiment 9

In this embodiment, an example of a display apparatus including a light-receiving device of one embodiment of the present invention will be described.

In the display apparatus of this embodiment, a pixel can include a plurality of types of subpixels including light-emitting devices that emit light of different colors. For example, the pixel can include three kinds of subpixels. As the three subpixels, subpixels of three colors of red (R), green (G), and blue (B) and subpixels of three colors of yellow (Y), cyan (C), and magenta (M) can be given. Alternatively, the pixel can include four kinds of subpixels. As the four subpixels, subpixels of four colors of R, G, B, and white (W) and subpixels of four colors of R, G, B, and Y can be given.

There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons typified by a triangle, a tetragon (including a rectangle and a square), and a pentagon; polygons with rounded corners; an ellipse; and a circle. The top surface shape of a subpixel herein refers to a top surface shape of a light-emitting region of a light-emitting device.

In the display apparatus including the light-emitting device and the light-receiving device in the pixel, the pixel has a light-receiving function, which enables detection of touch or approach of an object while an image is displayed. For example, all the subpixels included in the display apparatus can display an image; alternatively, some subpixels can emit light as a light source and the other subpixels can display an image.

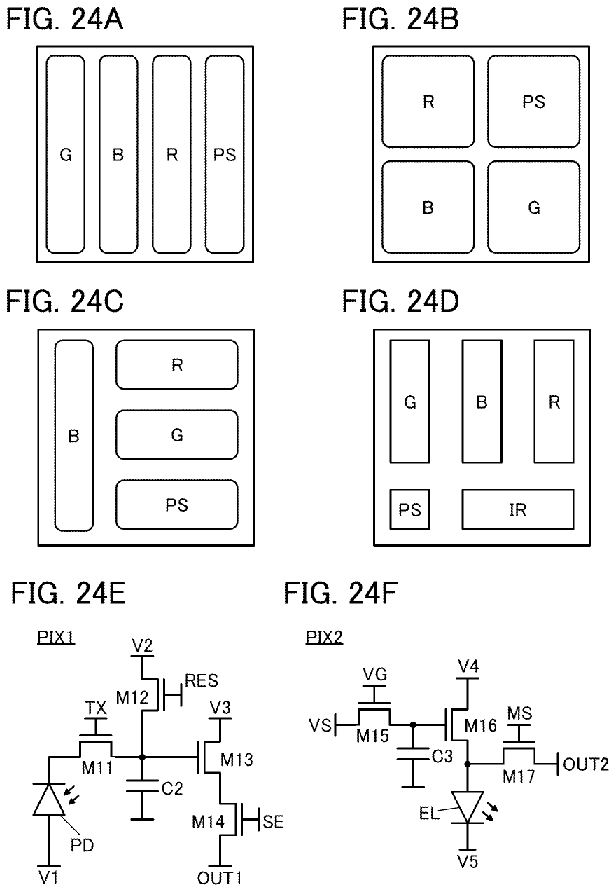

Pixels illustrated in FIG. 24A, FIG. 24B, and FIG. 24C each include a subpixel G, a subpixel B, a subpixel R, and a subpixel PS.

The pixel illustrated in FIG. 24A employs stripe arrangement. The pixel illustrated in FIG. 24B employs matrix arrangement.

The pixel arrangement illustrated in FIG. 24C has a structure in which three subpixels (the subpixel R, the subpixel G, and the subpixel S) are vertically arranged next to one subpixel (the subpixel B).

The pixel illustrated in FIG. 24D includes the subpixel G, the subpixel B, the subpixel R, a subpixel IR, and the subpixel PS.

FIG. 24D illustrates an example in which one pixel is provided in two rows. Three subpixels (the subpixel G, the subpixel B, and the subpixel R) are provided in the upper row (first row), and two subpixels (one subpixel PS and one subpixel IR) are provided in the lower row (second row).

Note that the layout of the subpixels is not limited to the structures illustrated in FIG. 24A to FIG. 24D.

The subpixel R includes a light-emitting device that emits red light. The subpixel G includes a light-emitting device that emits green light. The subpixel B includes a light-emitting device that emits blue light. The subpixel IR includes a light-emitting device that emits infrared light. The subpixel PS includes a light-receiving device. Although the wavelength of light detected by the subpixel PS is not particularly limited, the light-receiving device included in the subpixel PS preferably has sensitivity to light emitted from the light-emitting device included in the subpixel R, the subpixel G, the subpixel B, or the subpixel IR. For example, the light-receiving device preferably detects one or more of light in blue, violet, bluish violet, green, yellowish green, yellow, orange, red, and infrared wavelength ranges, for example.

The light-receiving area of the subpixel PS is smaller than the light-emitting area of each of the other subpixels. A smaller light-receiving area leads to a narrower image-capturing range, inhibits a blur in a captured image, and improves the definition. Thus, the use of the subpixel PS enables high-resolution or high-definition image capturing. For example, image capturing for personal authentication with the use of a fingerprint, a palm print, the iris, the shape of a blood vessel (including the shape of a vein and the shape of an artery), or a face is possible by using the subpixel PS.

Moreover, the subpixel PS can be used in a touch sensor (also referred to as a direct touch sensor) or a near touch sensor (also referred to as a hover sensor, a hover touch sensor, a contactless sensor, or a touchless sensor). For example, the subpixel PS preferably detects infrared light. Thus, a touch can be detected even in a dark place.

Here, the touch sensor or the near touch sensor can detect approach or contact of an object (e.g., a finger, a hand, or a pen). The touch sensor can detect an object when the display apparatus and the object come in direct contact with each other. The near touch sensor can detect an object even when the object is not in contact with the display apparatus. For example, the display apparatus is preferably capable of detecting an object positioned in the range of 0.1 mm to 300 mm inclusive, more preferably 3 mm to 50 mm inclusive from the display apparatus. This structure enables the display apparatus to be operated without direct contact of an object. In other words, the display apparatus can be operated in a contactless (touchless) manner. With the above-described structure, the display apparatus can have a reduced risk of being dirty or damaged, or can be operated without the object directly touching dirt (e.g., dust or a virus) attached to the display apparatus.

For high-resolution image capturing, the subpixel PS is preferably provided in all pixels included in the display apparatus. Meanwhile, in the case where the subpixel PS is used in a touch sensor or a near touch sensor, high accuracy is not required as compared to the case of capturing an image of a fingerprint or the like; accordingly, the subpixel PS is provided in some of the pixels in the display apparatus. When the number of subpixels PS included in the display apparatus is smaller than the number of subpixels R, higher detection speed can be achieved. FIG. 24E illustrates an example of the pixel circuit of the subpixel including a light-receiving device. FIG. 24F illustrates an example of the pixel circuit of the subpixel including a light-emitting device.

A pixel circuit PIX1 illustrated in FIG. 24E includes a light-receiving device PD, a transistor M11, a transistor M12, a transistor M13, a transistor M14, and a capacitor C2. Here, an example in which a photodiode is used as the light-receiving device PD is illustrated.

An anode of the light-receiving device PD is electrically connected to a wiring V1 and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain thereof is electrically connected to a wiring V2. One of a source and a drain of the transistor M13 is electrically connected to a wiring V3, and the other of the source and the drain thereof is electrically connected to one of a source and a drain of the transistor M14. A gate of the transistor M14 is electrically connected to a wiring SE, and the other of the source and the drain thereof is electrically connected to a wiring OUT1.

A constant potential is supplied to the wiring V1, the wiring V2, and the wiring V3. When the light-receiving device PD is driven with a reverse bias, a potential higher than the potential of the wiring V1 is supplied to the wiring V2. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device PD. The transistor M13 functions as an amplifier transistor for outputting a signal corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 24F includes a light-emitting device EL, a transistor M15, a transistor M16, a transistor M17, and a capacitor C3. Here, an example in which a light-emitting diode is used as the light-emitting device EL is illustrated. In particular, an organic EL device is preferably used as the light-emitting device EL.

A gate of the transistor M15 is electrically connected to a wiring VG, one of a source and a drain thereof is electrically connected to a wiring VS, and the other of the source and the drain thereof is electrically connected to one electrode of the capacitor C3 and a gate of the transistor M16. One of a source and a drain of the transistor M16 is electrically connected to a wiring V4, and the other of the source and the drain thereof is electrically connected to an anode of the light-emitting device EL and one of a source and a drain of the transistor M17. A gate of the transistor M17 is electrically connected to a wiring MS, and the other of the source and the drain thereof is electrically connected to a wiring OUT2. A cathode of the light-emitting device EL is electrically connected to a wiring V5.

A constant potential is supplied to the wiring V4 and the wiring V5. In the light-emitting device EL, the anode side can have a high potential and the cathode side can have a lower potential than the anode side. The transistor M15 is controlled by a signal supplied to the wiring VG and functions as a selection transistor for controlling a selection state of the pixel circuit PIX2. The transistor M16 functions as a driving transistor that controls current flowing through the light-emitting device EL, in accordance with a potential supplied to the gate. When the transistor M15 is in an on state, a potential supplied to the wiring VS is supplied to the gate of the transistor M16, and the emission luminance of the light-emitting device EL can be controlled in accordance with the potential. The transistor M17 is controlled by a signal supplied to the wiring MS and has a function of outputting a potential between the transistor M16 and the light-emitting device EL to the outside through the wiring OUT2.

Here, a transistor in which a metal oxide (an oxide semiconductor) is used in a semiconductor layer where a channel is formed is preferably used as each of the transistor M11, the transistor M12, the transistor M13, and the transistor M14 included in the pixel circuit PIX1 and the transistor M15, the transistor M16, and the transistor M17 included in the pixel circuit PIX2.

A transistor using a metal oxide having a wider band gap and a lower carrier density than silicon can achieve extremely low off-state current. Thus, such a low off-state current enables retention of charge accumulated in a capacitor that is connected in series with the transistor for a long time. For that reason, a transistor using an oxide semiconductor is preferably used particularly as the transistor M11, the transistor M12, and the transistor M15 each of which is connected in series with the capacitor C2 or the capacitor C3. Moreover, the use of transistors using an oxide semiconductor as the other transistors can reduce the manufacturing cost. Note that one embodiment of the present invention is not limited thereto. A transistor in which silicon is used in a semiconductor layer (hereinafter, also referred to as a Si transistor) may be used.

Note that the off-state current per micrometer of channel width of an OS transistor at room temperature can be lower than or equal to 1 aA (1×10⁻¹⁸A), lower than or equal to 1 zA (1×10⁻²¹A), or lower than or equal to 1 yA (1×10⁻²⁴A). Note that the off-state current value per micrometer of channel width of a Si transistor at room temperature is higher than or equal to 1 fA (1×10⁻¹⁵A) and lower than or equal to 1 pA (1×10⁻¹²A). In other words, the off-state current of the OS transistor is lower than that of the Si transistor by approximately ten orders of magnitude.

Note that the display apparatus of one embodiment of the present invention has a structure including the OS transistor and the light-emitting device having an MML (metal maskless) structure. This structure can significantly reduce the leakage current that might flow through the transistor and the leakage current that might flow between adjacent light-emitting devices (also referred to as a lateral leakage current or a side leakage current). In addition, with this structure, a viewer can notice any one or more of image crispness, image sharpness, and a high contrast ratio in an image displayed on the display apparatus. With the structure where the leakage current that might flow through the transistor and the lateral leakage current that might flow between light-emitting devices are extremely low, display with little leakage of light at the time of black display (such display is also referred to as deep black display) can be achieved.

To increase the emission luminance of the light-emitting device included in the pixel circuit, the amount of current flowing through the light-emitting device needs to be increased. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as the driving transistor included in the pixel circuit, a high voltage can be applied between a source and a drain of the OS transistor, so that the amount of current flowing through the light-emitting device can be increased and the emission luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Therefore, the emission luminance of the light-emitting device can be controlled minutely (the number of gray levels in the pixel circuit can be increased).

Regarding saturation characteristics of current flowing when transistors operate in a saturation region, even in the case where the source-drain voltage of an OS transistor increases gradually, a more stable constant current (saturation current) can be fed through the OS transistor than through a Si transistor. Thus, by using an OS transistor as the driving transistor, a stable constant current can be fed through light-emitting devices that contain an EL material even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, by using OS transistors as the driving transistors included in the pixel circuits, it is possible to inhibit black-level degradation, increase the luminance, increase the number of gray levels, and suppress variations in light-emitting devices, for example. Therefore, a display apparatus including the pixel circuit can display a clear and smooth image; as a result, any one or more of the image crispness, the image sharpness, and a high contrast ratio can be observed. When the driving transistor included in the pixel circuit has an extremely low off-state current, the display apparatus can perform black display with as little light leakage as possible (completely black display).

Alternatively, transistors using silicon as a semiconductor in which a channel is formed can be used as the transistor M11 to the transistor M17. In particular, silicon with high crystallinity, typified by single crystal silicon or polycrystalline silicon, is preferably used, in which case high field-effect mobility is achieved and higher-speed operation is possible.

Alternatively, a transistor containing an oxide semiconductor (an OS transistor) may be used as at least one of the transistor M11 to the transistor M17, and transistors containing silicon (Si transistors) may be used as the other transistors. Note that as the Si transistor, a transistor containing low-temperature polysilicon (LTPS) (hereinafter, referred to as an LTPS transistor) can be used. A structure in which an OS transistor and an LTPS transistor are combined is referred to as LTPO in some cases. By employing LTPO in which an LTPS transistor with a high mobility and an OS transistor with a low off-state current are used, a display panel with high display quality can be provided.

Note that although n-channel transistors are illustrated as the transistors in FIG. 24E and FIG. 24F, p-channel transistors can alternatively be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including the transistor and/or the capacitor are preferably provided to overlap with the light-receiving device PD or the light-emitting device EL. Thus, the effective area occupied by each pixel circuit can be reduced, and a high-resolution light-receiving portion or display portion can be achieved.

At least part of this embodiment can be implemented in combination with the other embodiments described in this specification as appropriate.

### Embodiment 10

In this embodiment, a metal oxide (also referred to as an oxide semiconductor) that can be used in the OS transistor described in the above embodiment will be described.

A metal oxide used in an OS transistor preferably contains at least indium or zinc, and further preferably contains indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, or an atomic layer deposition (ALD) method.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of crystal in the film or the substrate. In other words, the crystal structure of the film or the substrate cannot be regarded as an amorphous state unless it has a bilaterally symmetrical peak in the XRD spectrum.

In addition, the crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is presumed that the In—Ga—Zn oxide film formed at room temperature is in an intermediate state, which is neither a single crystal or polycrystalline state nor an amorphous state, and that it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of a surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layer-shaped structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind or composition of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement or a heptagonal lattice arrangement is included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, or an interatomic bond distance changed by substitution of a metal atom.

Note that a crystal structure in which a clear crystal grain boundary is observed is what is called polycrystal. It is highly probable that the grain boundary becomes a recombination center and traps carriers and thus decreases the on-state current and field-effect mobility of a transistor. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities or formation of defects, the CAAC-OS can be regarded as an oxide semiconductor that has small amounts of impurities and defects (oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, in some cases, the nc-OS cannot be distinguished from an a-like OS or an amorphous oxide semiconductor, depending on the analysis method. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-like OS]

The a-like OS is an oxide semiconductor having a structure between those of the nc-OS and the amorphous oxide semiconductor. The a-like OS contains a void or a low-density region. That is, the a-like OS has low crystallinity as compared with the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region has higher [In] and lower [Ga] than the second region. Moreover, the second region is a region having [Ga] higher than [Ga] in the first region and [In] lower than [In] in the first region.

Specifically, the first region includes indium oxide or indium zinc oxide as its main component. The second region includes gallium oxide or gallium zinc oxide as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is intentionally not heated, for example. Furthermore, in the case where the CAC-OS is formed by a sputtering method, any one or more selected from an inert gas (typically, argon), an oxygen gas, and a nitrogen gas is used as a deposition gas. The ratio of the flow rate of an oxygen gas to the total flow rate of the deposition gas during deposition is preferably as low as possible. For example, the flow-rate proportion of an oxygen gas in the total deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (u) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using the CAC-OS has high reliability. Thus, the CAC-OS is most suitable for a variety of semiconductor apparatuses such as a display apparatus.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Containing Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus also has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is a Group 14 element, is contained in an oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. Alternatively, when nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the oxide semiconductor is preferably reduced as much as possible. Specifically, the concentration of hydrogen in the oxide semiconductor, which is measured by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 11

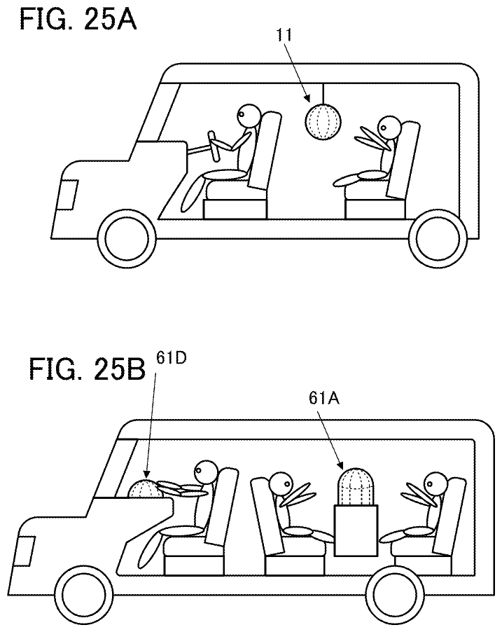

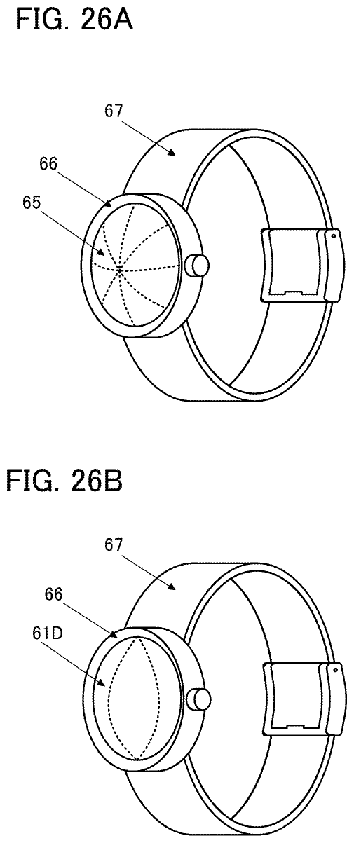

In this embodiment, electronic devices each including the display panel of one embodiment of the present invention will be described with reference to FIG. 25 and FIG. 26.

In this embodiment, an example in which the display apparatus described in Embodiment 1 is installed in a car will be described.

FIG. 25A illustrates the spherical display panel 11 that is suspended from the ceiling of a car by a wiring cord. The display panel 11 can function as an interior accessory as well as an interior light. Moreover, the display panel 11 can display television images. Furthermore, if the wiring cord is stretchable, a passenger can pick up and operate the display panel 11.

In the case where an omnidirectional camera is installed outside the car as an in-vehicle camera, images captured by the omnidirectional camera can be displayed on the display panel 11 at once in an easy-to-see matter for a user.

FIG. 25B illustrates another example. The light-emitting and light-receiving apparatus described in Embodiment 5 is suitably used in a light-emitting and light-receiving portion of a vehicle control apparatus. Half of the vehicle control apparatus with a spherical shape is inset into a concave portion so as to be fixed, and the spherical display panel 11 in Embodiment 1 is freely rotated on the concave portion.

A vehicle control apparatus may be formed using the hemispherical display panel 61 instead of the spherical display panel 11 in Embodiment 1.

FIG. 25B illustrates an example in which the display portion 61A that has a shape in which on one flat surface of a cylinder, a hemisphere with the same diameter as the cylinder is stacked is provided on the backseat side. The display portion 61A can be supplied with electric power or a video signal from the bottom. The display portion 61A can also be used as an interior light.

Note that the example illustrated in FIG. 25 is an electric vehicle but is not particularly limited as long as it is a vehicle. Agricultural machines, motorized bicycles including motor-assisted bicycles, motorcycles, electric wheelchairs, electric carts, boats and ships, submarines, and aircraft such as fixed-wing aircraft and rotary-wing aircraft may be provided with a display panel with a curved surface, typically a spherical shape or a hemispherical shape. Moreover, transport vehicles typified by buses, passenger airplanes, helicopters, and spacecraft can be provided with a display panel with a curved surface, typically a spherical shape or a hemispherical shape.

Furthermore, electronic devices typified by wristwatches and personal computers can be provided with a display panel with a curved surface, typically a spherical shape or a hemispherical shape. For example, the light-emitting and light-receiving apparatus described in Embodiment 5 can be provided as a small hemispherical or spherical member in the position of a mousepad of a notebook computer.

FIG. 26A illustrates an example of a wristwatch in which the display panel described in Embodiment 1 is fixed as a hemisphere to an electronic member 66 to be used as a dial. The wristwatch includes a belt 67 to fix the electronic member 66 to the arm. Moreover, a sphere instead of a hemisphere may be framed to form a wristwatch. The display panel equipped with a touch sensor or a near touch sensor can detect approach or touch of an object (a finger, a hand, or a pen) and control the display.

A hemispherical wristwatch dial allows a user to check the time without bothering to move the arm.

If a display panel is spherical, part of the display panel touches the user's arm; thus, when the display panel is equipped with a sensor, biological information can be obtained.

FIG. 26B illustrates an example of a wristwatch in which the display portion 61D described in Embodiment 2 is used in a dial. Since FIG. 26B is the same as FIG. 26A except for the assembling method, a detailed description is omitted here.

This embodiment can be freely combined with the other embodiments.

### Embodiment 12

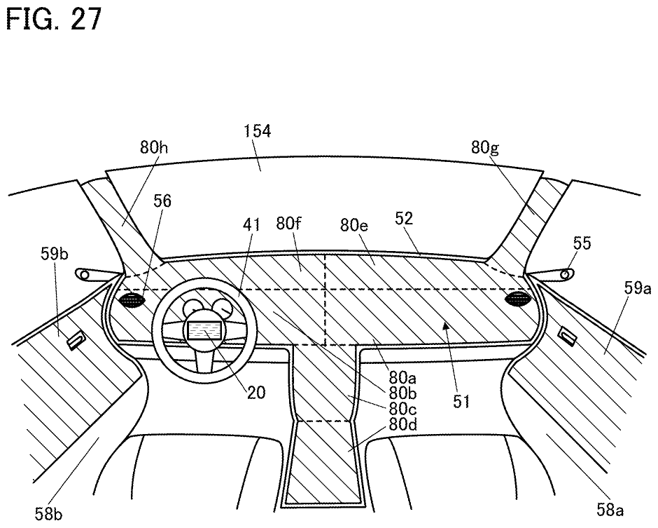

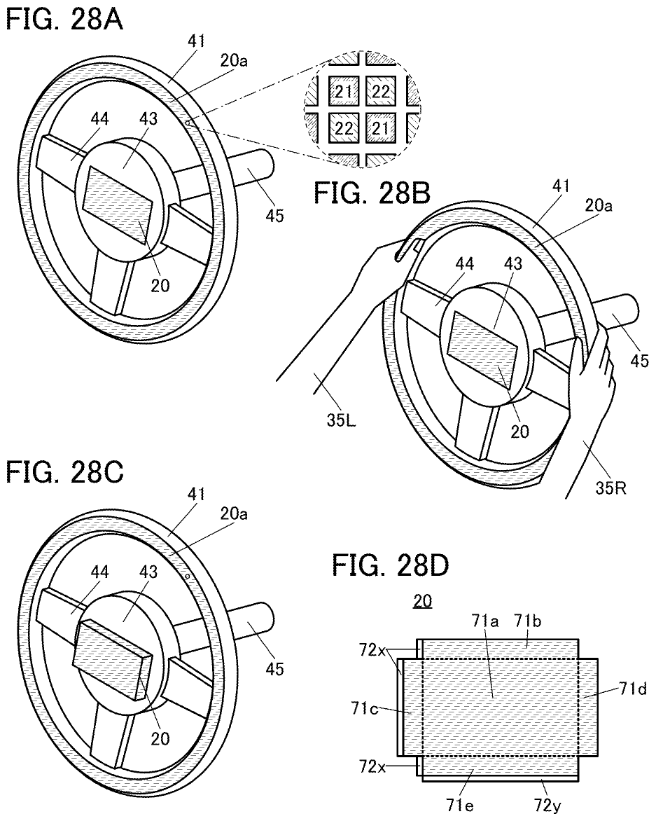

In this embodiment, a vehicle using the display panel of one embodiment of the present invention will be described with reference to FIG. 27 and FIG. 28.

In this embodiment, an example in which one or a combination of the display apparatuses described in any one of Embodiments 1 to 4 is installed in a car will be described.

FIG. 27 is a diagram illustrating a structure example of a vehicle. FIG. 27 illustrates a dashboard 52, a steering wheel including a rim 41, a windshield 154, cameras 55, an air outlet 56, a front-passenger-side door 58a, and a driver-side door 58b that are arranged around the driver's seat and the front passenger's seat. A display portion 51 is provided horizontally across the dashboard 52.

The display portion 51 is preferably provided with a touch sensor or a non-contact proximity sensor. Alternatively, the display portion 51 is preferably operated by gestures with use of a camera that is separately provided.

The steering wheel includes a light-emitting and light-receiving portion 20. The light-emitting and light-receiving portion 20 has a function of emitting light and a function of capturing an image. The light-emitting and light-receiving portion 20 enables biological information such as a fingerprint, a palmprint, or a vein of a driver to be obtained; the driver can be authenticated on the basis of the biological information. Therefore, only drivers registered in advance are allowed to start the vehicle, resulting in a vehicle with an extremely high security level.

A plurality of cameras 55 that capture images of the situations on the rear side may be provided outside the vehicle. Although the camera 55 is provided instead of a side mirror in the example in FIG. 27, both the side mirror and the camera may be provided. As the camera 55, a CCD camera or a CMOS camera can be used. In addition, an infrared camera may be used in combination with such a camera. The infrared camera, which has a higher output level with a higher temperature of an object, can sense or extract a living body such as a human or an animal.

An image captured by the camera 55 can be output to one or both of the display portion 51 and the light-emitting and light-receiving portion 20. The display portion 51 or the light-emitting and light-receiving portion 20 is mainly used to assist driving of the vehicle. An image of the situation on the rear side is captured at a wide angle of view by the camera 55, and the image is displayed on the display portion 51 or the light-emitting and light-receiving portion 20 so that the driver can see a blind area to avoid an accident.

Furthermore, a distance image sensor may be provided over a roof of the vehicle, and an image obtained by the distance image sensor may be displayed on the display portion 51. As the distance image sensor, an image sensor or LIDAR (Light Detection and Ranging) can be used. An image obtained by the image sensor and the image obtained by the distance image sensor are displayed on the display portion 51, whereby more information can be provided to the driver to assist driving.

The display portion 51 may also have a function of displaying map information, traffic information, television images, and DVD images. For example, map information can be displayed on a display panel 80a and a display panel 80b as a large display screen. Note that the number of display panels can be increased depending on the image to be displayed.

In FIG. 27, the display portion 51 is provided on the dashboard, a front console, and left and right pillars. In the example illustrated in FIG. 27, the display portion 51 includes eight display panels (the display panel 80a to a display panel 80h); however, the number of display panels is not limited thereto and may be seven or less or nine or more. A display panel 80c and a display panel 80d are provided in a position corresponding to the center console. The display panel 80d with a rectangular shape and the display panel 80c with a non-rectangular shape are combined. In the case where the display panel 80c and the display panel 80d are used as one panel, a resulting panel is a non-rectangular panel. A display panel 80e and a display panel 80f are provided on the far side of the dashboard from the driver. A display panel 80g and the display panel 80h are provided along the pillars. One or more of the display panel 80a to the display panel 80h are provided along a curved surface.

Images to be displayed on the display panel 80a to the display panel 80h can be freely set according to the driver's preference. For example, television images, DVD images, or online videos can be displayed on the display panel 80a and the display panel 80e on the left side; map information can be displayed on the display panel 80c at the center; meters such as a speedometer and a tachometer can be displayed on the display panel 80b and the display panel 80f on the driver side; and audio information can be displayed on the display panel 80d between the driver's seat and the front passenger's seat. External views in the driver's line of sight are displayed in real time on the display panel 80g and the display panel 80h provided on the pillars, which enables the vehicle to be a pseudo-pillarless vehicle and to have fewer blind spots, resulting in a highly safe vehicle.

Furthermore, in FIG. 27, a display portion 59a and a display portion 59b are provided along a surface of the front-passenger-side door 58a and a surface of the driver-side door 58b, respectively. Each of the display portion 59a and the display portion 59b can be formed using one or a plurality of display panels.

The display portion 59a and the display portion 59b are placed to face each other, and the display portion 51 is provided on the dashboard 52 so as to connect an end portion of the display portion 59a and an end portion of the display portion 59b. Accordingly, a driver and a passenger in the front passenger's seat are surrounded by the display portion 51, the display portion 59a, and the display portion 59b in the front and on both sides. For example, displaying one image across the display portion 59a, the display portion 51, and the display portion 59b enables the driver or the passenger to have an enhanced sense of immersion.

In addition, the plurality of cameras 55 that capture images of the situations on the rear side may be provided outside the vehicle. Although the camera 55 is provided instead of a side mirror in the example in FIG. 27, both the side mirror and the camera may be provided. As the camera 55, a CCD camera or a CMOS camera can be used.

As the camera 55, a CCD camera or a CMOS camera can be used. In addition, an infrared camera may be used in combination with such a camera. The infrared camera, which has a higher output level with a higher temperature of an object, can sense or extract a living body such as a human or an animal.

An image captured by the camera 55 can be output to any one or more of the display panels. The image displayed on the display portion 51 can be mainly used to assist driving of the vehicle. For example, an image of the situation on the rear side is captured at a wide angle of view by the camera 55, and the image is displayed on any one or more of the display panels so that the driver can see a blind area to avoid an accident.

In addition, the display portion 59a and the display portion 59b can display an image synchronized with the scenery from the window, which is obtained by synthesizing images obtained by the camera 55. That is, an image that the driver and the passenger can see through the door 58a and the door 58b can be displayed on the display portion 59a and the display portion 59b. This allows the driver and the passenger to experience the sensation of floating. A display panel having an image capturing function is preferably used as at least one of the display panel 80a to the display panel 80h. Furthermore, a display panel having an image capturing function can also be used as one or more of the display panels provided in the display portion 59a and the display portion 59b.

For example, when the driver touches the display panel, the vehicle can perform biometric authentication such as fingerprint authentication or palm print authentication. The vehicle may have a function of setting an environment to meet the driver's preference when the driver is authenticated by biometric authentication. For example, one or more of adjustment of the position of the seat, adjustment of the position of the handle, adjustment of the position of the camera 55, setting of brightness, setting of an air conditioner, setting of the speed (frequency) of wipers, volume setting of audio, and reading of the playlist of the audio are preferably performed after authentication.

A vehicle can be brought into a state where the vehicle can be driven, e.g., a state where an engine is started or a state where an electric vehicle can be started, after the driver is authenticated by biological authentication. This is preferable because a key, which is conventionally necessary, is unnecessary.

Although the display apparatus that surrounds the driver's seat and the front passenger's seat is described here, a display portion can be provided in the backseat to surround a passenger. For example, the display portion can be provided along the back of the driver's seat or the passenger's seat or along a side surface of a rear door.

Next, modification examples in which the display apparatus of one embodiment of the present invention is applied will be described with reference to FIG. 28A to FIG. 28D. FIG. 28A to FIG. 28C illustrate modification examples of the structure of the steering wheel illustrated in FIG. 27. FIG. 28D is an unfolded view of a display portion illustrated in FIG. 28C.

FIG. 28A illustrates an example in which a light-emitting and light-receiving portion 20a is provided along a surface of the rim 41 with a ring-like shape. The ring-like shape is also a non-rectangular shape. The rim 41 is processed such that a surface right in front of a driver is flat, and the light-emitting and light-receiving portion 20a is provided along the flat surface.

An enlarged view of part of the light-emitting and light-receiving portion 20a is illustrated on the right side in FIG. 28A. In the light-emitting and light-receiving portion 20a, light-emitting devices 21 and light-receiving devices 22 are alternately arranged in a matrix. Note that the arrangement method of the light-emitting device 21 and the light-receiving device 22 is not limited thereto, and a variety of arrangement methods can be employed. For example, like the light-emitting and light-receiving portion 20, the light-emitting and light-receiving portion 20a may include a plurality of kinds of light-emitting devices that emit visible light.

FIG. 28B illustrates a state where a driver holds the rim 41 with his/her left hand 35L and right hand 35R. In this case, the light-emitting device 21 emits light and the light-receiving device 22 receives the light, whereby an image of part of the palms of the driver's left hand 35L and right hand 35R can be captured. Since the light-emitting and light-receiving portion 20a has a ring-like top surface like the surface of the rim 41, image capturing can be constantly performed regardless of the position of the rim 41 held by the left hand 35L and the right hand 35R.

The light-emitting and light-receiving portion 20a is provided on a surface of the rim 41 on the driver's side, and thus is positioned in the driver's line of sight. In this case, the use of a light-emitting device that emits infrared light as the light-emitting device 21 enables image capturing without making the driver feel glare.

Note that a light-emitting device that emits visible light may be used as the light-emitting device 21, in which case it is important that the emission luminance during image capturing is reduced to a level at which the driver does not feel glare. For example, it is preferable to reduce the emission luminance of the light-emitting device 21 at night compared with the daytime.

FIG. 28C illustrates an example in which the light-emitting and light-receiving portion 20 has a three-dimensional structure. The light-emitting and light-receiving portion 20 preferably has a three-dimensional structure as illustrated in FIG. 28C, in which case a user can observe a display region by using both a front display region and a side display region, resulting in improved visibility of the user.

The light-emitting and light-receiving portion 20 can have a three-dimensional structure. FIG. 28D is an unfolded view of a display panel that can be used in the light-emitting and light-receiving portion 20 illustrated in FIG. 28C.

The display panel includes five regions: a display region 71a at the center and a display region 71b, a display region 71c, a display region 71d, and a display region 71e on the four sides. The display region 71a, the display region 71b, and the display region 71e are each provided with a driver circuit 72x. The display region 71e is further provided with a driver circuit 72y. Note that in FIG. 28D, the display region 71a, the display region 71b, the display region 71c, the display region 71d, and the display region 71e may be rectangular or non-rectangular.

As described above, the structure of one embodiment of the present invention can increase the degree of flexibility in design of a display apparatus and thus can improve the design of the display apparatus. The display apparatus of one embodiment of the present invention can be suitably installed in a vehicle.

At least part of this embodiment can be implemented in combination with the other embodiments described in this specification as appropriate.

### Embodiment 13

In this embodiment, an example in which a display portion having a curved display surface is provided in a steering wheel will be described.

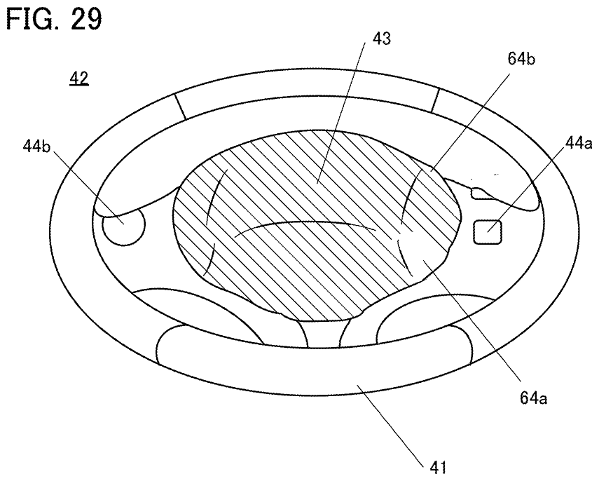

FIG. 29 is a perspective view of a steering wheel 42. The steering wheel 42 includes the rim 41, the display panel 43 having a curved surface, and operation buttons 44a and 44b. The display panel 43 includes a smoothly raised convex portion in the center part of the steering wheel; the display panel 43 that has what is called a curved surface is provided. Part of a display surface of the display panel 43 includes a rounded convex bulge. The display panel 43 has a curved outline in its end portion. Part of the display panel 43 is provided with a driver portion 64a for driving the display panel. The operation buttons 44a and 44b may be horn control buttons, power buttons for the display panel 43 having the curved surface, or buttons for controlling images on the display panel 43.

Furthermore, by being provided with a touch sensor, the display surface can be operated by touch of a driver's hand or finger. Therefore, a display apparatus that includes a touch sensor can also be referred to as a vehicle operating apparatus. In the case where a touch sensor is provided, the operation buttons 44a and 44b are not necessarily provided.

A plurality of pixel regions are formed in a matrix over a flexible substrate, and some of the pixel regions include driver circuits.

An example of a method for manufacturing a display apparatus will be described below. A plurality of pixels are arranged in a matrix over a flexible substrate. A flexible substrate including a plurality of pixels arranged in a matrix is also referred to as a flexible display. A method in which a transistor or a light-emitting device is directly formed on a flexible substrate may be employed, or a method in which a transistor or a light-emitting device is formed over a glass substrate, separated from the glass substrate, and then bonded to a flexible substrate with an adhesive layer may be employed. Although there are various kinds of separation methods or transfer methods, there is no particular limitation and a known technique is employed as appropriate.

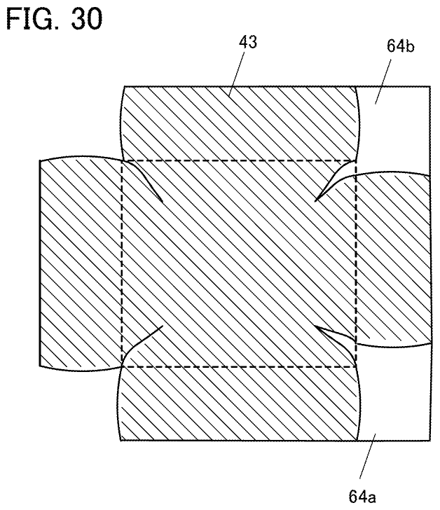

Then, the flexible substrate is processed into or cut into a non-rectangular shape illustrated in FIG. 30. After that, the flexible substrate is fixed to a member having a curved surface, specifically part of the steering wheel, with an adhesive layer. Before fixing the flexible substrate, an FPC for connection to an external terminal may be firmly attached to a terminal electrode provided over the flexible substrate.

To maintain the curved surface of the display panel, at least part of the curved surface of at least the display panel is fixed to a member (steering wheel) having a curved surface. An adhesive material or an adhesive tape is used for fixing.

FIG. 30 is an example of a plan view illustrating the case where the display apparatus illustrated in FIG. 29 is unfolded. Note that FIG. 30 illustrates an example in which one flexible non-rectangular substrate is processed and a cut is made therein as needed to form a bending surface or a curved surface, so that a display panel including a rounded quadrangular convex bulge at the center is manufactured. For easy bending, layout design may be employed in which a non-display region is provided in a gap between pixels and bending is performed at the non-display region. Note that although the plurality of pixel regions and the driver circuits are provided over part of the flexible substrate and other parts of the flexible substrate are the driver portions 64a and 64b serving as non-display regions in FIG. 29, one embodiment of the present invention is not particularly limited thereto. Another display panel may overlap with the portion of the driver circuit to form a display region.

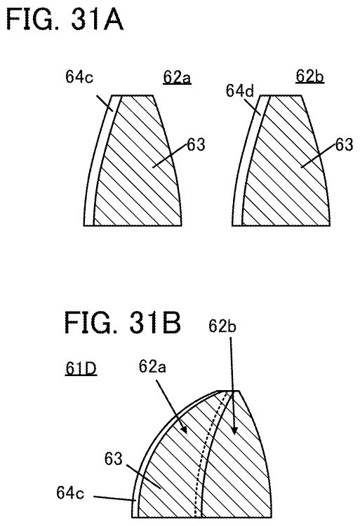

For example, a plurality of flexible non-rectangular substrates are preferably used. FIG. 31A illustrates an example in which a plurality of leaf-like display panels are bent and arranged adjacent to each other so that they partly overlap to form part of a spherical surface.

The display panel includes the display region 63 whose display surface is convex when part of the flexible non-rectangular substrate is bent. Pixel regions formed in a matrix are provided in the display region 63, and the driver circuits electrically connected to the pixel regions are provided in non-display regions 64c and 64d. Ideally, the display panel is preferably assembled so that the width of a seam (also referred to as a vertical stripe or a horizontal stripe) is as small as possible.

To make the seam less noticeable, a protective substrate that covers the flexible substrate is preferably provided, and the refractive index of the protective substrate and the refractive index of an adhesive layer positioned between the protective substrate and the flexible substrate are adjusted as appropriate. Note that “cover the flexible substrate” is used not to mean “cover a side surface of the substrate or a bottom surface of the substrate” but to mean “stack a protective substrate having a larger surface area than at least the flexible substrate.”

Before the plurality of display panels are assembled, the flexible substrates may be heated while being pressed against a sphere mold to be rounded.

In FIG. 31A, two fan-shaped members 62a and 62b are used to form part of a spherical surface illustrated in FIG. 31B (also referred to as a quarter spherical surface) as part of a display region. This part of the spherical surface and the three-dimensional shape illustrated in FIG. 29 may be combined to obtain a structure where the entire surface serves as a display region.

For the flexible substrate, an elastic material can be used.

A member having a three-dimensional surface is not limited to a steering wheel; a display panel member can be provided in a car interior part.

At least part of this embodiment can be implemented in combination with the other embodiments described in this specification as appropriate.

### Embodiment 14

In this embodiment, an example in which a display panel is provided not for a steering wheel but for a car interior part (including a ceiling) or a window will be described.

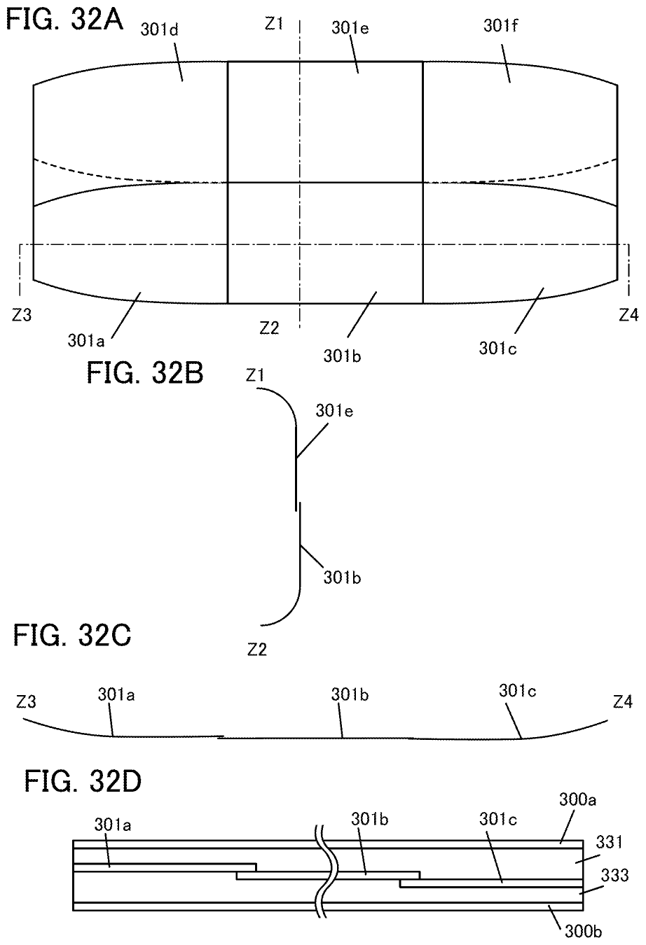

FIG. 32 illustrates an example of the case where six display panels 301a, 301b, 301c, 301d, 301e, and 301f are combined to form one display apparatus having a large display area.

FIG. 32A is a front view illustrating the case where the six display panels 301a, 301b, 301c, 301d, 301e, and 301f are arranged to form one screen. FIG. 32B is a schematic cross-sectional view taken along the chain line Z1Z2 in FIG. 32A. FIG. 32C is a schematic cross-sectional view taken along the chain line Z3Z4 in FIG. 32A.

In the case where end surfaces of the adjacent display panels are made to overlap with each other in this manner, a vertical stripe or a horizontal stripe might occur in the vicinity of the end surfaces.

For that reason, a cross-sectional structure illustrated in FIG. 32D is preferably employed to adjust a refractive index. FIG. 32D is an enlarged view of part of FIG. 32C.

As illustrated in FIG. 32D, a light-transmitting resin layer 331 may be provided to cover top surfaces of the display panel 301a and the display panel 301b. Specifically, in the cross section taken along the chain line Z3Z4, the resin layer 331 is preferably provided to cover a display region of each of the display panel 301a, the display panel 301b, and the display panel 301c, a region where the display panel 301a and the display panel 301b overlap with each other, and a region where the display panel 301b and the display panel 301c overlap with each other.

Providing the resin layer 331 over the display panels 301a, 301b, 301c, 301d, 301e, and 301f enables the mechanical strength of the display apparatus to be increased. In addition, the resin layer 331 is formed to have a flat surface, whereby the display quality of an image displayed on the display region can be increased. For example, using a coating apparatus typified by a slit coater, a curtain coater, a gravure coater, a roll coater, or a spin coater enables the resin layer 331 to have high flatness.

A difference in refractive index n between the resin layer 331 and a substrate on the display surface sides of the display panels 301a, 301b, 301c, 301d, 301e, and 301f is preferably less than or equal to 20%, further preferably less than or equal to 10%, still further preferably less than or equal to 5%. By using the resin layer 331 with such a refractive index, the refractive index difference between the resin and the display panels 301a, 301b, 301c, 301d, 301e, and 301f can be reduced and light can be efficiently extracted outside. In addition, the resin layer 331 with such a refractive index is provided to cover a step portion caused by the adjacent display panels, whereby the step portion is less likely to be noticed as a vertical stripe or a horizontal stripe, resulting in increased display quality of an image displayed on the display region of the display apparatus.

As a material used for the resin layer 331, a resin with a high light-transmitting property is preferable. For example, an organic resin film of an epoxy resin, an aramid resin, an acrylic resin, a polyimide resin, a polyamide resin, or a polyamide-imide resin can be used.

It is preferable that a protective substrate 300a be provided over the display panels 301a, 301b, 301c, 301d, 301e, and 301f with the resin layer 331 therebetween. The protective substrate 300a can increase the mechanical strength of the display apparatus as well as protecting a surface of the display apparatus. For the protective substrate 300a, a light-transmitting material is used at least in a region overlapping with the display region. The protective substrate 300a may have a light-blocking property so that a region other than the region overlapping with the display region is not perceived.

The protective substrate 300a may function as a touch panel. In the case where the display panels 301a, 301b, 301c, 301d, 301e, and 301f are flexible and can be bent, the protective substrate 300a is also preferably flexible.

A difference in refractive index n between the protective substrate 300a and the resin layer 331 or the substrate on the display surface sides of the display panels 301a, 301b, 301c, 301d, 301e, and 301f is less than or equal to 20%, preferably less than or equal to 10%, further preferably less than or equal to 5% with the interface used as a boundary interposed therebetween. Note that a refractive index refers to an average refractive index with respect to visible light, specifically, light with a wavelength in the range from 400 nm to 750 nm. The average refractive index is a value obtained by dividing, by the number of measurement points, the sum of measured refractive indexes with respect to light with wavelengths in the above range. Note that the refractive index of the air is 1.

As the protective substrate 300a, a film-like plastic substrate, for example, a plastic substrate made from polyimide (PI), aramid, polyethylene terephthalate (PET), polyethersulfone (PES), polyethylene naphthalate (PEN), polycarbonate (PC), nylon, polyetheretherketone (PEEK), polysulfone (PSF), polyetherimide (PEI), polyarylate (PAR), polybutylene terephthalate (PBT), or a silicone resin can be used. The protective substrate 300a is preferably flexible.

As illustrated in FIG. 32D, a resin layer 333 may be provided over a surface opposite to the display surfaces of the display panels 301a, 301b, 301c, 301d, 301e, and 301f, and a protective substrate 300b may be provided thereover with the resin layer 333 therebetween. The two protective substrates sandwich the display panels 301a, 301b, 301c, 301d, 301e, and 301f in this manner, whereby the mechanical strength of the display apparatus can be further increased. Furthermore, the thicknesses of the resin layer 331 and the resin layer 333 are substantially equal to each other and materials with the same thickness are used for the protective substrate 300a and the protective substrate 300b, whereby the plurality of display panels can be positioned at the center of the stack. For example, to bend the stack including the display panels, the display panels are positioned at the center in the thickness direction, whereby lateral stress applied to the display panels due to bending can be relieved, so that the display panels can be prevented from being damaged.

The display apparatus illustrated in FIG. 32A can be installed on a ceiling (also referred to as a roof portion) in a car or a rear window, a windshield, or a side window in a car.

This embodiment can be freely combined with the other embodiments.

### Embodiment 15

An example in which a region overlapping with an adjacent panel is bent will be described in this embodiment while the example in which a region overlapping with an adjacent panel is substantially flat is described in Embodiment 14. As the number of display panels increases, the size of a wiring board for supplying a signal to drive each display panel increases. Moreover, as the area of a display apparatus increases, a longer wiring is needed; thus, signal delay is likely to occur, which may adversely affect the display quality.

Thus, each of the plurality of display panels included in the display apparatus is preferably provided with a wireless module that supplies a signal to drive the display panels. By arranging the plurality of display panels to partly overlap with each other, a region where the display panels are arranged seamlessly can be obtained as one display region.

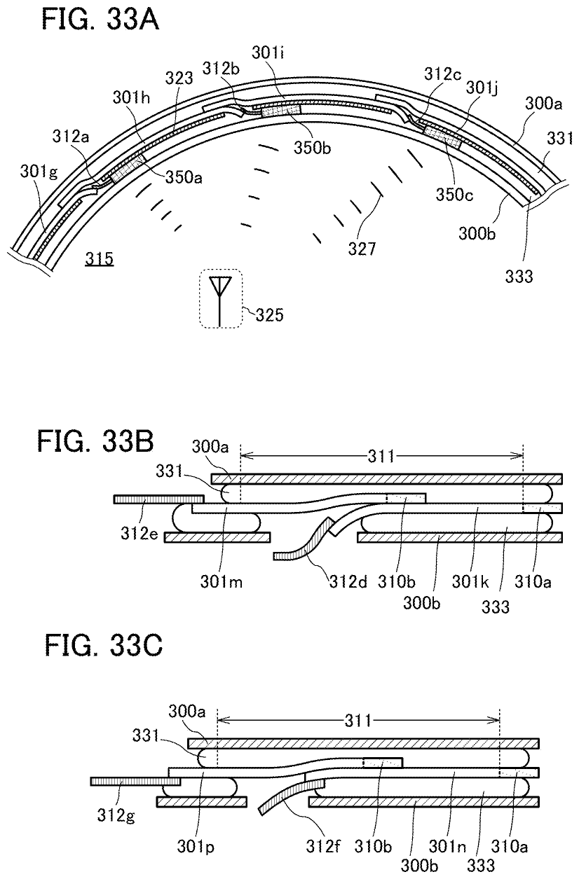

FIG. 33A illustrates an example of a cross section of the case where a plurality of display panels are combined and installed on a surface of a dashboard 315. A display apparatus including a plurality of display panels 301g, 301h, 301i, and 301j is positioned between the inner protective substrate 300b and the outer protective substrate 300a and is bent along the surface of the dashboard 315.

As the plurality of display panels 301g, 301h, 301i, and 301j, a top emission display panel (also referred to as a top emission panel), a bottom emission display panel (also referred to as a bottom emission panel), or a dual emission display panel (also referred to as a dual emission panel) is used.

One display panel 301h is electrically connected to a wireless module 350a through an FPC 312a. The display panel 301h is supported on the top surface side of a supporting member 323 provided between the inner protective substrate 300b and the outer protective substrate 300a, and the wireless module 350a is provided on the bottom surface side of the supporting member 323. The display panel 301h and the wireless module 350a are electrically connected to each other through the FPC 312a through an opening provided in the supporting member 323.

The wireless modules 350a, 350b, and 350c receive a wireless signal 327 transmitted from an antenna 325 provided inside or outside the dashboard 315. Furthermore, the wireless modules have a function of extracting a signal for driving the display panels from the wireless signal 327 and supplying the signal to the display panels. Examples of the signal for driving the display panels include a power supply potential, a synchronization signal (a clock signal) and an image signal.

For example, each of the wireless modules 350a, 350b, and 350c is assigned an identification number. The wireless signal 327 transmitted from the antenna 325 includes a signal that specifies the identification number and a signal for driving the display panels. When the identification number included in the wireless signal 327 corresponds to the identification number of each of the wireless modules 350a, 350b, and 350c, the wireless modules receive the signal for driving the display panels and supply the signal to the display panels through the FPCs 312a, 312b, and 312c, whereby different images can be displayed on the display panels.

Each of the wireless modules 350a, 350b, and 350c may be an active wireless module to which electric power is supplied from the wireless signal 327 or may be a passive wireless module in which a battery is incorporated. In the case of the passive wireless module, the incorporated battery can be charged by transmitting and receiving electric power (also referred to as contactless power transmission, non-contact power transmission, or wireless power feeding) using an electromagnetic induction method, a magnetic resonance method, or an electric wave method.

With such a structure, even in a large display apparatus, the signal for driving each of the display panel is not delayed even in a large display apparatus, resulting in improved display quality. Furthermore, the display apparatus is driven by the wireless signal 327; thus, when the display apparatus is installed in a car, construction for leading a wiring through a dashboard is unnecessary, so that the display apparatus can be easily installed anywhere in the car. For the same reason, the installation position of the display apparatus can be easily changed.

Note that one wireless module is connected to one display panel in the above-described structure; however, one wireless module may be connected to two or more display panels.

FIG. 33B and FIG. 33C illustrate modification examples. Here, a portion in which two display panels overlap with each other is selectively illustrated for simplicity.

In FIG. 33B, a display region 311 includes a display panel 301k and a display panel 301m. A region 310a is a non-display region and a region 310b is a region that transmits visible light. In FIG. 33B, a top emission display panel (also referred to as a top emission panel) is used as the display panel 301k and the display panel 301m. In the case where an FPC 312d is electrically connected to the display panel 301k that is a top emission display panel, an opening portion is preferably provided in the protective substrate 300b as illustrated in FIG. 33B. In that case, the resin layer 333 is provided to cover part of the FPC 312d, whereby the mechanical strength at a connection portion between the display panel 301k and the FPC 312d can be increased and a defect such as peeling of the FPC 312d can be inhibited. Similarly, the resin layer 333 is preferably provided to cover part of an FPC 312e.

For optical adjustment, the resin layer 331 and the protective substrate 300a are preferably provided. Adjustment of the refractive index of the resin layer 331 or the protective substrate 300a can make a vertical stripe or a horizontal stripe that might be generated in the vicinity of the boundary between the display panel 301k and the display panel 301m less noticeable.

As illustrated in FIG. 33B, the resin layer 333 may be provided over a surface opposite to the display surfaces of the display panel 301k and the display panel 301m, and the protective substrate 300b may be provided thereover with the resin layer 333 therebetween. The two protective substrates sandwich the display panel 301k and the display panel 301m in this manner, whereby the mechanical strength of the display apparatus can be further increased. Furthermore, the thicknesses of the resin layer 331 and the resin layer 333 are substantially equal to each other and materials with substantially equal thicknesses are used for the protective substrate 300a and the protective substrate 300b, whereby the display panel 301k and the display panel 301m can be positioned at the center of the stack. For example, to bend and fix the stack including the display panels, the display panels are positioned at the center in the thickness direction, whereby lateral stress applied to the display panels due to bending can be relieved, so that the display panels can be prevented from being damaged.

In FIG. 33C, a bottom emission display panel (also referred to as a bottom emission panel) is used as a display panel 301n and a display panel 301p.

As illustrated in FIG. 33C, an opening portion for extracting an FPC 312f is preferably provided in the resin layer 333 and the protective substrate 300b that are positioned on the rear surface sides of the display panel 301n and the display panel 301p. In that case, the resin layer 333 is provided to cover part of the FPC 312f, whereby the mechanical strength at a connection portion between the display panel 301n and the FPC 312f can be increased and a defect such as peeling of the FPC 312f can be inhibited. Similarly, the resin layer 333 is preferably provided to cover part of an FPC 312g.

Note that when the resin layer 333 and the resin layer 331, or the protective substrate 300a and the protective substrate 300b are formed using the same material, the manufacturing costs can be reduced.

This embodiment can be freely combined with the other embodiments.

### Embodiment 16

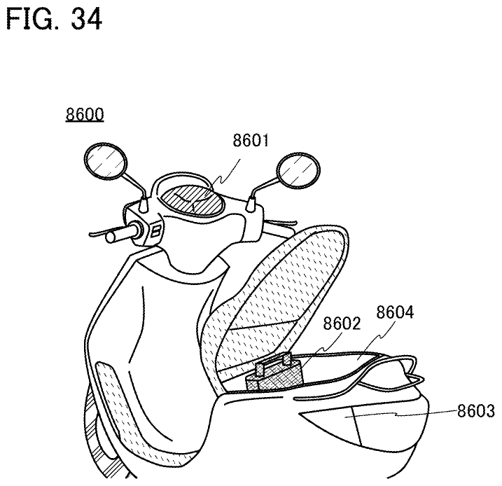

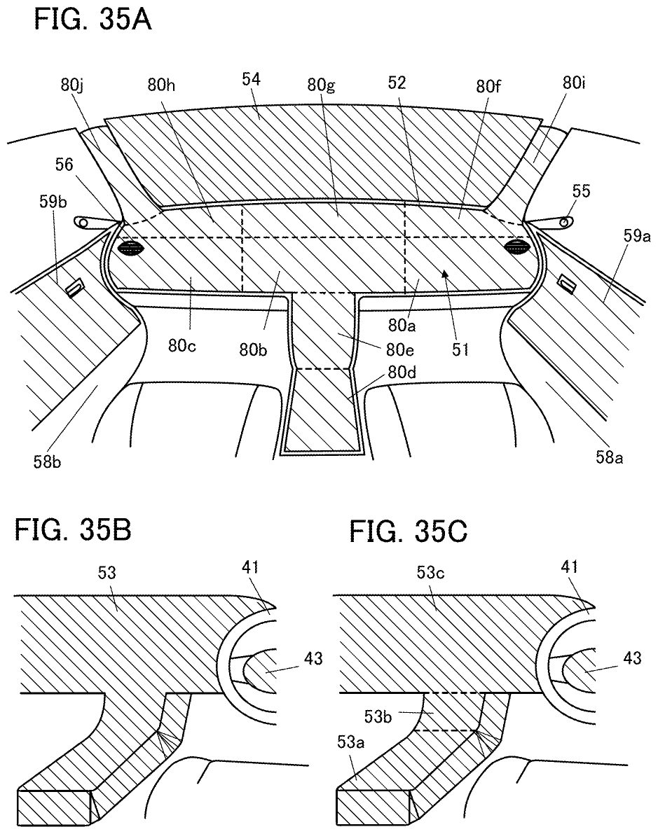

In this embodiment, electronic devices that use the display panel of one embodiment of the present invention will be described with reference to FIG. 34 and FIG. 35.

In this embodiment, an example in which the display apparatus described in Embodiment 13 is installed on a vehicle or inside the vehicle will be described.

FIG. 34 illustrates an example of an electric bicycle (motor scooter) that includes a secondary battery and uses the secondary battery as a main power source.

A motor scooter 8600 illustrated in FIG. 34 includes a display apparatus 8601, a power storage device 8602, side mirrors, and indicator lights 8603. The power storage device 8602 can supply electricity to the display apparatus 8601 or the indicator lights 8603. The display panel obtained in Embodiment 1 can be used in the display apparatus 8601 having a curved surface that is provided in a steering wheel, or the indicator lights 8603 having curved surfaces, so that a driver can be assisted in driving.

In the motor scooter 8600 illustrated in FIG. 34, the power storage device 8602 can be stored in an under-seat storage unit 8604. The power storage device 8602 can be stored in the under-seat storage unit 8604 even when the under-seat storage unit 8604 has a small size.

Vehicles that use the display panel of one embodiment of the present invention are described with reference to FIG. 35A, FIG. 35B, and FIG. 35C.

FIG. 35A is a diagram illustrating a structure example of a vehicle. FIG. 35A illustrates the dashboard 52, a display panel 54 fixed to a windshield, the cameras 55, the air outlet 56, the front-passenger-side door 58a, and the driver-side door 58b that are arranged around the driver's seat and the front passenger's seat. The display portion 51 is provided horizontally across the dashboard 52.

The display panel described in Embodiment 14 or Embodiment 15 can be used as the display panel 54 fixed to the windshield. Although one display panel is illustrated in FIG. 35A, a plurality of panels are preferably combined to form one display panel. Moreover, the display panel 54 may have a see-through structure including a light-transmitting region through which the outside can be seen.

The display portion 51 is preferably provided with a touch sensor or a non-contact proximity sensor. The display portion 51 is preferably operated by gestures with use of a separately provided camera.

Although FIG. 35A illustrates a self-driving vehicle without a steering wheel, one embodiment of the present invention is not particularly limited thereto; a steering wheel including the rim 41 may be provided as illustrated in FIG. 35B. The steering wheel illustrated in FIG. 35B is provided with the display panel 43, and the structure described in Embodiment 14 can be employed. FIG. 35B illustrates an example in which the display panel 53 having a curved surface is also provided on a side surface of a console, and a spherical surface can be formed by combining the display panel 53 and the display panel described in Embodiment 2. This enables the display panel in the console portion to be a three-dimensional display panel.

FIG. 35C illustrates an example in which three panels 53a, 53b, and 53c, the boundaries of which are indicated by dotted lines, are used. A protective substrate is provided over surfaces of the three panels so as to cover the three panels, and the refractive index of the protective substrate as well as an adhesive layer is adjusted as appropriate to make the boundaries (also referred to as horizontal stripes) less noticeable. One feature is as follows: the three panels 53a, 53b, and 53c are fixed at a convex or a concave of a dashboard or the console under the panels to make surfaces of the panels smooth along the convex or the concave. Accordingly, a surface of the protective substrate is positioned along the convex or the concave of the dashboard or the console, enabling sophisticated appearance.

A plurality of cameras 55 that capture images of the situations on the rear side may be provided outside the vehicle. Although the camera 55 is provided instead of a side mirror in the example in FIG. 35A, both the side mirror and the camera may be provided. As the camera 55, a CCD camera or a CMOS camera can be used. In addition, an infrared camera may be used in combination with such a camera. The infrared camera, which has a higher output level with a higher temperature of an object, can sense or extract a living body such as a human or an animal.

An image captured by the camera 55 can be output to one or both of the display portion 51 and the display panel 54. The display portion 51 or display panel 54 is mainly used to assist driving of the vehicle. An image of the situation on the rear side is captured at a wide angle of view by the camera 55, and the image is displayed on the display portion 51 or the display panel 54 so that the driver can see a blind area to avoid an accident.

Furthermore, a distance image sensor may be provided over a roof of the vehicle, and an image obtained by the distance image sensor may be displayed on the display portion 51. As the distance image sensor, an image sensor or LIDAR (Light Detection and Ranging) can be used. An image obtained by the image sensor and the image obtained by the distance image sensor are displayed on the display portion 51, whereby more information can be provided to the driver to assist driving.

In addition, a display panel having a curved surface can be provided inside a roof of the vehicle, that is, in a roof portion. In the case where the display panel having a curved surface is provided in the roof portion, the display panel described in Embodiment 14 or Embodiment 15 can be used.

The display portion 51 may also have a function of displaying map information, traffic information, television images, and DVD images. For example, map information can be displayed on the display panel 80a and the display panel 80b as a large display screen. Note that the number of display panels can be increased depending on the image to be displayed.

In FIG. 35A, the display portion 51 is provided on the dashboard, a front console, and left and right pillars. In the example illustrated in FIG. 35A, the display portion 51 includes eight display panels (the display panel 80a to a display panel 80j); however, the number of display panels is not limited thereto and may be seven or less or nine or more. The display panel 80e and the display panel 80d are provided in a position corresponding to the center console. The display panel 80e with a rectangular shape and the display panel 80b with a non-rectangular shape are combined. In the case where the display panel 80e and the display panel 80b are used as one panel, a resulting panel is a non-rectangular panel. The display panel 80f, the display panel 80g, and the display panel 80h are provided on the back side of the dashboard from the driver's point of view. A display panel 80i and the display panel 80j are provided along the pillars. One or more of the display panel 80a to the display panel 80j are provided along a curved surface.

Images to be displayed on the display panel 80a to the display panel 80j can be freely set according to the driver's preference. For example, television images, DVD images, or web videos can be displayed on the display panel 80c and the display panel 80h on the left, map information can be displayed on the display panel 80b at the center, meters including a speedometer and a tachometer can be displayed on the display panel 80a and the display panel 80f on the driver side, and audio information and the like can be displayed on the display panels 80d and 80e between the driver's seat and the front passenger's seat. External views in the driver's line of sight are displayed in real time on the display panel 80i and the display panel 80j that are provided along the pillars, which enables the vehicle to be a pseudo pillarless vehicle and to have fewer blind spots, resulting in a highly safe vehicle.

Furthermore, in FIG. 35A, a display portion 59a and a display portion 59b are provided along a surface of the front-passenger-side door 58a and a surface of the driver-side door 58b, respectively. Each of the display portion 59a and the display portion 59b can be formed using one or a plurality of display panels.

The display portion 59a and the display portion 59b are placed to face each other, and the display portion 51 is provided on the dashboard 52 so as to connect an end portion of the display portion 59a and an end portion of the display portion 59b. Accordingly, a driver and a passenger in the front passenger's seat are surrounded by the display portion 51, the display portion 59a, and the display portion 59b in the front and on both sides. For example, displaying one image across the display portion 59a, the display portion 51, and the display portion 59b enables the driver or the passenger to have an enhanced sense of immersion.

In addition, the plurality of cameras 55 that capture images of the situations on the rear side may be provided outside the vehicle. Although the camera 55 is provided instead of a side mirror in the example in FIG. 35A, both the side mirror and the camera may be provided. As the camera 55, a CCD camera or a CMOS camera can be used.

As the camera 55, a CCD camera or a CMOS camera can be used. In addition, an infrared camera may be used in combination with such a camera. The infrared camera, which has a higher output level with a higher temperature of an object, can sense or extract a human or an animal.

An image captured by the camera 55 can be output to any one or more of the display panels. The image displayed on the display portion 51 can be mainly used to assist driving of the vehicle. For example, an image of the situation on the rear side is captured at a wide angle of view by the camera 55, and the image is displayed on any one or more of the display panels so that the driver can see a blind area to avoid an accident.

In addition, the display portion 59a and the display portion 59b can display an image synchronized with the scenery from the window, which is obtained by synthesizing images obtained by the camera 55. That is, an image that the driver and the passenger can see through the door 58a and the door 58b can be displayed on the display portion 59a and the display portion 59b. This allows the driver and the passenger to experience the sensation of floating.

A display panel having an image capturing function is preferably used as at least one of the display panel 80a to the display panel 80h. Furthermore, a display panel having an image capturing function can also be used as one or more of the display panels provided in the display portion 59a and the display portion 59b.

For example, when the driver touches the display panel, the vehicle can perform biometric authentication (fingerprint authentication or palm print authentication). The vehicle may have a function of setting an environment to meet the driver's preference when the driver is authenticated by biometric authentication. For example, one or more of adjustment of the position of the seat, adjustment of the position of the handle, adjustment of the position of the camera 55, setting of brightness, setting of an air conditioner, setting of the speed (frequency) of wipers, volume setting of audio, and reading of the playlist of the audio are preferably performed after authentication.

A vehicle can be brought into a state where the vehicle can be driven, e.g., a state where an engine is started or a state where an electric vehicle can be started, after the driver is authenticated by biological authentication. This is preferable because a key, which is conventionally necessary, is unnecessary.

Although the display apparatus that surrounds the driver's seat and the front passenger's seat is described here, a display portion can be provided in the backseat to surround a passenger. For example, the display portion can be provided along the back of the driver's seat or the front passenger's seat or along a side surface of a rear door.

Although FIG. 35A illustrates a self-driving vehicle without a steering wheel, one embodiment of the present invention is not particularly limited thereto; a steering wheel including may be provided.

FIG. 35B and FIG. 35C are perspective views each illustrating a steering wheel and the vicinity thereof. FIG. 35B and FIG. 35C illustrate modification examples of the structure illustrated in FIG. 35A. In FIG. 35B, the display panel 53 with a non-rectangular shape is provided in a console portion and a dashboard.

The display panel described in Embodiment 1 may be provided in the steering wheel.

As described above, the structure of one embodiment of the present invention can increase the degree of flexibility in design of a display apparatus and thus can improve the design of the display apparatus. The display apparatus of one embodiment of the present invention can be suitably installed in a vehicle.

At least part of this embodiment can be implemented in combination with the other embodiments described in this specification as appropriate.

Note that the examples illustrated in FIG. 34, FIG. 35A, and FIG. 35B are electric vehicles but are not particularly limited as long as they are vehicles. Agricultural machines, motorized bicycles including motor-assisted bicycles, motorcycles, electric wheelchairs, electric carts, boats and ships, submarines, and aircraft such as fixed-wing aircraft and rotary-wing aircraft may be provided with a display panel with a curved surface, typically a spherical shape or a hemispherical shape. Moreover, transport vehicles typified by buses, passenger airplanes, helicopters, and spacecraft can be provided with a display panel with a curved surface, typically a spherical shape or a hemispherical shape.

Furthermore, electronic devices typified by wristwatches and personal computers can be provided with a display panel with a curved surface, typically a spherical shape or a hemispherical shape.

This embodiment can be freely combined with the other embodiments.

### Embodiment 17

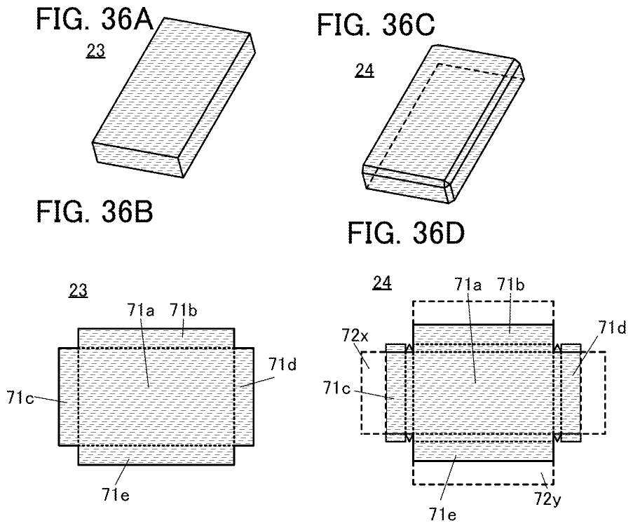

In this embodiment, modification examples of the display panel of one embodiment of the present invention will be described with reference to FIG. 36.

An example of a rectangular solid display panel like a display apparatus whose perspective view is FIG. 36A will be described in this embodiment while the example of the rounded display apparatus is described in Embodiment 13. The display apparatus illustrated in FIG. 36A is an example of a three-dimensional structure. The display apparatus 23 preferably has a three-dimensional structure as illustrated in FIG. 36A, in which case a user can observe a display region by using both a front display region and a side display region, resulting in improved visibility of the user.

FIG. 36B is an unfolded view of a display panel that can be used in the display apparatus 23 illustrated in FIG. 36A.

The display apparatus 23 includes five display regions in total: the display region 71a at the center and four regions of the display region 71b, the display region 71c, the display region 71d, and the display region 71e on the four sides. Note that in FIG. 36B, the display region 71a, the display region 71b, the display region 71c, the display region 71d, and the display region 71e are rectangular but may be non-rectangular.

FIG. 36C illustrates a display apparatus 24 in which a quadrangular top surface has slopes and side surfaces are provided in contact with the slopes.

FIG. 36D is an unfolded view of a display panel that can be used in the display apparatus 24 illustrated in FIG. 36C. The driver circuit 72x and the driver circuit 72y for driving may be provided in portions indicated by dotted lines in FIG. 36D.

As described above, the structure of one embodiment of the present invention can increase the degree of flexibility in design of a display apparatus and thus can improve the design of the display apparatus. The display apparatus of one embodiment of the present invention can be suitably installed in a vehicle.

At least part of this embodiment can be implemented in combination with the other embodiments described in this specification as appropriate.

### REFERENCE NUMERALS

11: display panel, 20: light-emitting and light-receiving portion, 20a: light-emitting and light-receiving portion, 21: light-emitting device, 22: light-receiving device, 35L: left hand, 35R: right hand, 41: rim, 42: steering wheel, 50: vehicle, 51: display portion, 52: dashboard, 54: windshield, 55: camera, 56: air outlet, 58a: door, 58b: door, 59a: display portion, 59b: display portion, 61: display panel, 61A: display portion, 61B: display portion, 61C: display portion, 61D: display portion, 62a: member, 62b: member, 62c: member, 62d: member, 62e: member, 63: display region, 64: non-display region, 66: electronic member, 67: belt, 70: display panel, 71a: display region, 71b: display region, 71c: display region, 71d: display region, 71e: display region, 72x: driver circuit, 72y: driver circuit, 80a: display panel, 80b: display panel, 80c: display panel, 80d: display panel, 80e: display panel, 80f: display panel, 80g: display panel, 80h: display panel, 90B: light-emitting device, 90G: light-emitting device, 90R: light-emitting device, 90S: light-receiving device, 100: display region, 101: layer, 110: pixel, 110a: subpixel, 110b: subpixel, 110c: subpixel, 111: pixel electrode, 111a: pixel electrode, 111b: pixel electrode, 111c: pixel electrode, 111C: connection electrode, 111G: pixel electrode, 111R: pixel electrode, 112B: organic layer, 112G: organic layer, 112R: organic layer, 112S: organic layer, 113: common electrode, 113a: organic layer, 113b: organic layer, 113c: organic layer, 114: organic layer, 115: common electrode, 120: substrate, 121: protective layer, 122: resin layer, 124a: pixel, 124b: pixel, 125: insulating layer, 126: resin layer, 127: insulating layer, 130: connection portion, 130a: light-emitting device, 130b: light-emitting device, 130c: light-emitting device, 131: insulating layer, 132: insulating layer, 140: connection portion, 200: display panel, 200A: display panel, 200B: display panel, 201: substrate, 202: substrate, 203: functional layer, 211: light-emitting device, 211B: light-emitting device, 211G: light-emitting device, 211IR: light-emitting device, 211R: light-emitting device, 211W: light-emitting device, 211X: light-emitting device, 212: light-receiving device, 213R: light-emitting and light-receiving device, 220: finger, 221: contact portion, 222: fingerprint, 223: image-capturing range, 225: stylus, 226: path, 242: connection layer, 252: transistor, 254: connection portion, 258: transistor, 259: transistor, 260: transistor, 261: insulating layer, 262: insulating layer, 264: insulating layer, 265: insulating layer, 268: insulating layer, 271: conductive layer, 272a: conductive layer, 272b: conductive layer, 273: conductive layer, 275: insulating layer, 278: connection portion, 281: semiconductor layer, 281i: channel formation region, 281n: low-resistance region, 292: connection layer, 400: display apparatus, 411a: conductive layer, 411b: conductive layer, 411c: conductive layer, 412G: EL layer, 412S: photoelectric conversion layer, 413: common electrode, 414: organic layer, 416: protective layer, 417: light-blocking layer, 421: insulating layer, 422: resin layer, 430b: light-emitting device, 440: light-receiving device, 442: adhesive layer, 451: substrate, 452: substrate, 453: substrate, 454: substrate, 455: adhesive layer, 462: display portion, 464: circuit, 465: wiring, 466: conductive layer, 472: FPC, 473: IC, 500: display panel, 500a: display panel, 500b: display panel, 500c: display panel, 500d: display panel, 501: display region, 501a: display region, 501b: display region, 501c: display region, 501d: display region, 510: region, 510b: region, 510c: region, 510d: region, 512: FPC, 512a: FPC, 520: region, 520b: region, 520c: region, 550: stacked-layer panel, 551: display region, 711: light-emitting layer, 712: light-emitting layer, 713: light-emitting layer, 720: layer, 720-1: layer, 720-2: layer, 730: layer, 730-1: layer, 730-2: layer, 750B: light-emitting device, 750G: light-emitting device, 750R: light-emitting device, 751: layer, 752: layer, 753B: light-emitting layer, 753G: light-emitting layer, 753R: light-emitting layer, 754: layer, 755: layer, 760: light-receiving device, 761: layer, 762: layer, 763: layer, 775: layer, 785: coloring layer, 790: EL layer, 790a: EL layer, 790b: EL layer, 791: lower electrode, 791B: pixel electrode, 791G: pixel electrode, 791PD: pixel electrode, 791R: pixel electrode, 792: upper electrode

1. A display apparatus comprising:
a display surface;
a flexible non-rectangular substrate over which part of the display surface is formed; and
a light-emitting apparatus formed over the flexible substrate,
wherein the light-emitting apparatus comprises pixel regions formed in a matrix, and
wherein the display surface comprises a convex or concave region when part of the flexible non-rectangular substrate is bent.

2. (canceled)

3. A display apparatus comprising:
a display surface;
a plurality of flexible non-rectangular substrates over which part of the display surface is formed; and
light-emitting apparatuses formed over the respective flexible substrates,
wherein each of the light-emitting apparatuses comprises pixel regions formed in a matrix,
wherein the pixel regions have convex or concave regions when some of the plurality of flexible non-rectangular substrates are bent, and
wherein the plurality of flexible non-rectangular substrates comprise regions where the substrates are connected to each other.

4. The display apparatus according to claim 3, further comprising:
a driver circuit electrically connected to the pixel regions.

5. The display apparatus according to claim 3,
wherein the display surface comprises a curved surface.

6. The display apparatus according to claim 3,
wherein the display surface comprises a spherical surface, a substantially spherical surface, a hemispherical surface, or a substantially hemispherical surface.

7. The display apparatus according to claim 4,
wherein the driver circuit is provided on a rear side of the pixel regions.

8. A display apparatus comprising:
a display surface;
a flexible non-rectangular substrate over which part of the display surface is formed; and
a light-emitting apparatus formed over the flexible substrate,
wherein the light-emitting apparatus comprises pixel regions formed in a matrix,
wherein the light-emitting apparatus comprises a first light-emitting device and a second light-emitting device positioned adjacent to the first light-emitting device, and
wherein the display surface comprises a convex or concave region when part of the flexible non-rectangular substrate is bent.

9. (canceled)

10. The display apparatus according to claim 8,
wherein each of the first light-emitting device and the second light-emitting device comprises a lower electrode, a first functional layer over the lower electrode, a light-emitting layer over the first functional layer, a second functional layer over the light-emitting layer, and an upper electrode over the second functional layer.

11. The display apparatus according to claim 8,
wherein each of the first light-emitting device and the second light-emitting device comprises a lower electrode, a first functional layer over the lower electrode, a first light-emitting layer over the first functional layer, a common layer over the first light-emitting layer, a second light-emitting layer over the common layer, a second functional layer over the second light-emitting layer, and an upper electrode over the second functional layer.

12. The display apparatus according to claim 10,
wherein the first functional layer comprises one or both of a hole-injection layer and a hole-transport layer, and
wherein the second functional layer comprises one or both of an electron-transport layer and an electron-injection layer.

13. The display apparatus according to claim 10,
wherein a side surface of the first functional layer and a side surface of the light-emitting layer are aligned or substantially aligned in a cross-sectional view.

14. The display apparatus according to claim 11,
wherein a side surface of the first functional layer, a side surface of the first light-emitting layer, and a side surface of the second light-emitting layer are aligned or substantially aligned in a cross-sectional view.

15. The display apparatus according to claim 8,
wherein light emitted from the first light-emitting device and light emitted from the second light-emitting device have the same color.

16. The display apparatus according to claim 8,
wherein the first light-emitting device comprises a first lower electrode, a first functional layer over the first lower electrode, a first light-emitting layer over the first functional layer, a second functional layer over the first light-emitting layer, and an upper electrode over the second functional layer, and
wherein the second light-emitting device comprises a second lower electrode, a third functional layer over the second lower electrode, a second light-emitting layer over the third functional layer, and a fourth functional layer over the second light-emitting layer.

17. The display apparatus according to claim 8,
wherein the first light-emitting device comprises a first lower electrode, a first functional layer over the first lower electrode, a third light-emitting layer over the first functional layer, a first common layer over the third light-emitting layer, a fourth light-emitting layer over the first common layer, a second functional layer over the fourth light-emitting layer, and an upper electrode over the second functional layer, and
wherein the second light-emitting device comprises a second lower electrode, a third functional layer over the second lower electrode, a fifth light-emitting layer over the third functional layer, a third common layer over the fifth light-emitting layer, a sixth light-emitting layer over the third common layer, a fourth functional layer over the sixth light-emitting layer, and the upper electrode over the fourth functional layer.

18. The display apparatus according to claim 16,
wherein each of the first functional layer and the third functional layer comprises one or both of a hole-injection layer and a hole-transport layer, and
wherein each of the second functional layer and the fourth functional layer comprises one or both of an electron-transport layer and an electron-injection layer.

19. The display apparatus according to claim 16,
wherein light emitted from the first light-emitting device and light emitted from the second light-emitting device have different colors.

20. The display apparatus according to claim 10,
comprising a region with a distance between a side surface of the first light-emitting device and a side surface of the second light-emitting device of less than or equal to 1 μm.

21. The display apparatus according to claim 10,
comprising a region with a distance between a side surface of the first light-emitting device and a side surface of the second light-emitting device of less than or equal to 100 nm.

22. The display apparatus according to claim 13,
comprising a region with a distance between a side surface of the first light-emitting device and a side surface of the second light-emitting device of less than or equal to 1 μm.

23. The display apparatus according to claim 14,
comprising a region with a distance between a side surface of the first light-emitting device and a side surface of the second light-emitting device of less than or equal to 1 μm.
